(19) United States
(12) Patent Application Publication
(10) Pub. No.: US 2013/0214371 A1
(43) Pub. Date: Aug. 22, 2013

(54) SOLID-STATE IMAGING DEVICE, IMAGE SENSOR, METHOD OF MANUFACTURING IMAGE SENSOR, AND ELECTRONIC APPARATUS

(71) Applicant: SONY CORPORATION, (US)

(72) Inventors: Tomohiko Asatsuma, Kanagawa (JP); Jun Okuno, Kanagawa (JP); Ando Atsuhiro, Kanagawa (JP); Masashi Nakazawa, Kanagawa (JP); Iwao Sugiura, Kanagawa (JP); Ikue Mitsuhashi, Kanagawa (JP)

(73) Assignee: SONY CORPORATION, Tokyo (JP)

(21) Appl. No.: 13/763,056

(22) Filed: Feb. 8, 2013

(30) Foreign Application Priority Data
Feb. 16, 2012 (JP) 2012-031518
Mar. 27, 2012 (JP) 2012-070767
Jun. 5, 2012 (JP) 2012-127668

(51) Int. Cl. H01L 31/0232

(52) U.S. Cl. CPC H01L 31/02325
USPC 257/432; 438/69

(57) ABSTRACT

There is provided a solid-state imaging device including a pixel array unit in which a plurality of unit pixels each having a photoelectric converting unit to generate and store photocharges according to an amount of received light and a charge storage unit to store the photocharges are arranged on a semiconductor substrate. The charge storage unit is formed on a path along which light is incident on the photoelectric converting unit.

### BACKGROUND

The present disclosure relates to a solid-state imaging device, an image sensor, a method of manufacturing an image sensor, and an electronic apparatus and more particularly, to a solid-state imaging device that includes a charge storage unit in a unit pixel and an electronic apparatus.

In a slide-state imaging device, for example, a CMOS image sensor that is a type of a solid-state imaging device of an X-Y address system, an operation for sequentially scanning photocharges generated and stored by a photoelectric converting unit for each pixel or each row and reading the photocharges is executed. In the case of the sequential scanning, that is, in the case in which a rolling shutter is adopted as an electronic shutter, a start time and an end time of exposure to store the photocharges may not be matched in all pixels. For this reason, in the case of the sequential scanning, distortion occurs in an imaging image when a moving object is imaged.

For the purpose of realizing imaging of an object moving at a high speed in which such kind of image distortion may not allowed or sensing in which synchronism of an imaging image is necessary, a global shutter that executes an exposure start and an exposure end at the same timing with respect to all pixels in a pixel array unit is adopted as an electronic shutter. In order to realize the global shutter, as a region to store photocharges separately from a photodiode to be a photoelectric converting unit, that is, a charge storage unit, an embedded MOS capacitor is provided (for example, refer to Japanese Patent No. 3874135).

However, in order to receive all photocharges generated by photoelectric conversion and stored in the photodiode by the embedded MOS capacitor when a global shutter function is executed, a saturation charge amount that is equal to or more than a saturation charge amount of the photodiode is necessary in the embedded MOS capacitor. In other words, from a viewpoint of the same unit pixel size, the embedded MOS capacitor exists in a unit pixel, so that an area of the photodiode greatly decreases. For this reason, the saturation charge amount of the photodiode decreases.

As a measure to resolve the above-described problem, technology for storing photocharges generated by photoelectric conversion in the photodiode in both the photodiode and the embedded MOS capacitor has been suggested (for example, refer to Japanese Patent Application Laid-Open (JP-A) No. 2009-268083). According to this technology, the saturation charge amount becomes a sum of the saturation charge amount of the photodiode and the saturation charge amount of the embedded MOS transistor.

However, even in the technology described in Japanese Patent Application Laid-Open (JP-A) No. 2009-268083, the saturation charge amount may decrease, as compared with a CMOS image sensor no having a global shutter function. This is because it is necessary to provide a transistor as well as a charge storage unit (embedded MOS capacitor in the related art) in a unit pixel to realize global exposure. As a result, a dynamic range of an image may be narrowed.

Meanwhile, different from the related art in which the global exposure is realized, a method that uses a capacitor having a large capacity value per unit area, not the embedded MOS capacitor, as the charge storage unit to increase the saturation charge amount and extend the dynamic range is also considered.

If a part of light incident on a first pixel unit of a plurality of pixel units leaks as leak light from the first pixel unit and is incident on a second pixel unit adjacent to the first pixel unit, noise such as smear may occur in pixel data of the second pixel unit.

Therefore, light shielding methods that shield leak light from a first pixel unit by a metal layer in an image sensor to suppress the leak light from the first pixel unit from being incident on a second pixel unit have been known (for example, refer to Japanese Patent Application Laid-Open (JP-A) Nos. 2009-181980, 2001-267544, 2008-251713, and 2009-099626).

### SUMMARY

However, even though the capacitor having the large capacity value per unit area is used, it is necessary to increase an occupied area to secure a sufficiently large capacity value. As a result, an area of the photodiode may decrease.

In the light shielding methods described above, because the leak light from the first pixel unit can be suppressed from being incident on the second pixel unit, the noise such as the smear that occurs in the pixel data can be decreased. However, in the light shielding methods, condensing efficiency of light with respect to each pixel unit is not considered.

It is desirable to enable noise of an image obtained by imaging to be suppressed without decreasing an area of a photoelectric converting unit such as a photodiode, condensing efficiency at the time of the imaging to be improved, and a charge storage unit to be provided in a unit pixel.

According to a first embodiment of the present technology, there is provided a solid-state imaging device including a pixel array unit in which a plurality of unit pixels each having a photoelectric converting unit to generate and store photocharges according to an amount of received light and a charge storage unit to store the photocharges are arranged on a semiconductor substrate. The charge storage unit is formed on a path along which light is incident on the photoelectric converting unit.

At least a part of a first electrode of the charge storage unit may be formed along at least a part of a sidewall of a waveguide to guide light to the photoelectric converting unit.

Further, at least a part of a second electrode facing the first electrode and at least a part of a capacity film provided between the first electrode and the second electrode may be formed along at least the part of the sidewall of the waveguide.

Each of the first and second electrodes may be formed of a transparent electrode material.

The waveguide may be embedded by the first electrode, the second electrode, and the capacity film.

A second electrode facing the first electrode may be formed to surround at least a part of a peripheral portion of a light reception surface of the photoelectric converting unit and at least the part of the sidewall of the waveguide, and an interlayer film between the first electrode and the second electrode may be formed as a capacity film of the charge storage unit.

The first electrode may be formed of a transparent electrode material.

The charge storage unit stores may charge overflown from the photoelectric converting unit during an exposure period.

Each of the unit pixels may further include a charge storage unit composed of an embedded MOS capacitor, and collective exposure of the plurality of unit pixels may be enabled and the charges stored in the photoelectric converting unit during the exposure period may be stored in the two charge storage units after the exposure period.

According to a second embodiment of the present technology, there is provided an electronic apparatus including a solid-state imaging device that includes a pixel array unit in which a plurality of unit pixels each having a photoelectric converting unit to generate and store photocharges according to an amount of received light and a charge storage unit to store the photocharges are arranged on a semiconductor substrate, the charge storage unit being formed on a path along which light is incident on the photoelectric converting unit, and a signal processing unit that executes signal processing with respect to a signal output from each of the unit pixels.

At least a part of a first electrode of the charge storage unit may be formed along at least a part of a sidewall of a waveguide to guide light to the photoelectric converting unit.

According to the embodiments of the present disclosure described above, a charge storage unit can be provided in a unit pixel without decreasing an area of a photoelectric converting unit.

### BRIEF DESCRIPTION OF THE DRAWINGS

FIG. 1 is a system structural diagram illustrating a schematic structure of a CMOS image sensor to which the present disclosure is applied;

FIG. 2 is a (first) system structural diagram illustrating another system structure of a CMOS image sensor to which the present disclosure is applied;

FIG. 3 is a (second) system structural diagram illustrating another system structure of a CMOS image sensor to which the present disclosure is applied;

FIGS. 4A and 4B are diagrams illustrating an embedded MOS capacitor and a surface-type MOS capacitor; respectively,

FIGS. 5A and 5B are diagrams illustrating a combination of a plurality of capacitor structures;

FIGS. 6A and 6B are (first) cross-sectional views illustrating another structure example of a second charge storage unit;

FIGS. 7A and 7B are (second) cross-sectional views illustrating another structure example of a second charge storage unit;

FIG. 8 is a circuit diagram illustrating a circuit structure of a unit pixel;

FIG. 9 is a schematic diagram illustrating a pixel structure of a unit pixel;

FIG. 10 is a timing chart illustrating a circuit operation of a unit pixel;

FIG. 11 is a (first) potential diagram illustrating a circuit operation of a unit pixel;

FIG. 12 is a (second) potential diagram illustrating a circuit operation of a unit pixel;

FIG. 13 is a (third) potential diagram illustrating a circuit operation of a unit pixel;

FIG. 14 is a (fourth) potential diagram illustrating a circuit operation of a unit pixel;

FIG. 15 is a (fifth) potential diagram illustrating a circuit operation of a unit pixel;

FIG. 16 is a (sixth) potential diagram illustrating a circuit operation of a unit pixel;

FIG. 17 is a (seventh) potential diagram illustrating a circuit operation of a unit pixel;

FIG. 18 is an (eighth) potential diagram illustrating a circuit operation of a unit pixel;

FIG. 19 is a circuit diagram illustrating a circuit structure of a first modification of a unit pixel;

FIG. 20 is a circuit diagram illustrating a circuit structure of a second modification of a unit pixel;

FIG. 21 is a timing chart illustrating a circuit operation of the second modification of the unit pixel;

FIG. 22 is a circuit diagram illustrating a circuit structure according to a first specific example of pixel sharing;

FIG. 23 is a circuit diagram illustrating a circuit structure according to a second specific example of pixel sharing;

FIG. 24 is a potential diagram of a substrate depth direction illustrating conditions to pin a substrate surface and couple potentials of an FD unit, a first charge storage unit, and a second charge storage unit;

FIG. 25 is a timing chart illustrating signal processing in a case of a first processing example and a case of a second processing example, in a signal processing unit;

FIG. 26 is a (first) characteristic diagram of an incident light amount/output illustrating signal processing in the case of a third processing example;

FIGS. 27A and 27B are (second) characteristic diagrams of an incident light amount/output illustrating signal processing in the case of the third processing example;

FIG. 28 is a timing chart illustrating a circuit operation of a unit pixel according to a modification;

FIG. 29 is a (first) cross-sectional view illustrating a structure example of a second charge storage unit;

FIG. 30 is a (second) cross-sectional view illustrating a structure example of a second charge storage unit;

FIG. 31 is a (third) cross-sectional view illustrating a structure example of a second charge storage unit;

FIG. 32 is a (fourth) cross-sectional view illustrating a structure example of a second charge storage unit;

FIG. 33 is a (fifth) cross-sectional view illustrating a structure example of a second charge storage unit;

FIG. 34 is a diagram illustrating a cross-sectional structure example of an image sensor;

FIG. 35 is a flowchart illustrating a method of manufacturing an image sensor;

FIG. 36 is a cross-sectional view illustrating a peripheral portion of an opening in a metal shielding film;

FIG. 37 is a diagram illustrating a distribution of optical energy in an optical waveguide;

FIG. 38 is a diagram illustrating a relation of an interval in an opening portion of a metal light shielding film and strength of light;

FIG. 39 is a diagram illustrating a modification of an optical waveguide;

FIG. 40 is a perspective view of an image sensor in the present disclosure;

FIGS. 41A and 41B are diagrams illustrating improvement of light reception sensitivity and reduction of smear;

FIG. 42 is a cross-sectional view of an image sensor according to a first embodiment;

FIGS. 43A, 43B, 43C, 43D, 43E, and 43F are diagrams illustrating a method of forming a light shielding wall of FIG. 42;

FIG. 44 is a flowchart illustrating manufacturing processing for manufacturing an image sensor of FIG. 42;

FIG. 45 is a cross-sectional view of an image sensor according to a second embodiment;

FIGS. 46A, 46B, 46C, 46D, 46E, and 46F are diagrams illustrating a method of forming a light shielding wall of FIG. 45;

FIG. 47 is a cross-sectional view of an image sensor according to a third embodiment;

FIG. 48 is a diagram illustrating removing processing for removing a metal diffusion prevention film;

FIG. 49 is a diagram illustrating an operation of a unit pixel according to a reference example;

FIGS. 50A and 50B are diagrams illustrating an operation of a unit pixel according to a modification;

FIG. 51 is a schematic diagram illustrating an example of the case in which a charge storage unit according to the present disclosure is adopted in a unit pixel of a solid-state image sensor having adopted a rolling shutter function; and

FIG. 52 is a block diagram illustrating an example of a structure of an electronic apparatus according to the present disclosure, for example, an imaging apparatus.

### DETAILED DESCRIPTION OF THE EMBODIMENT(S)

Hereinafter, preferred embodiments of the present disclosure will be described in detail with reference to the appended drawings. Note that, in this specification and the appended drawings, structural elements that have substantially the same function and structure are denoted with the same reference numerals, and repeated explanation of these structural elements is omitted.

### 1. Solid-State Imaging Device to which Present Disclosure is Applied

### 1-1. Basic System Structure

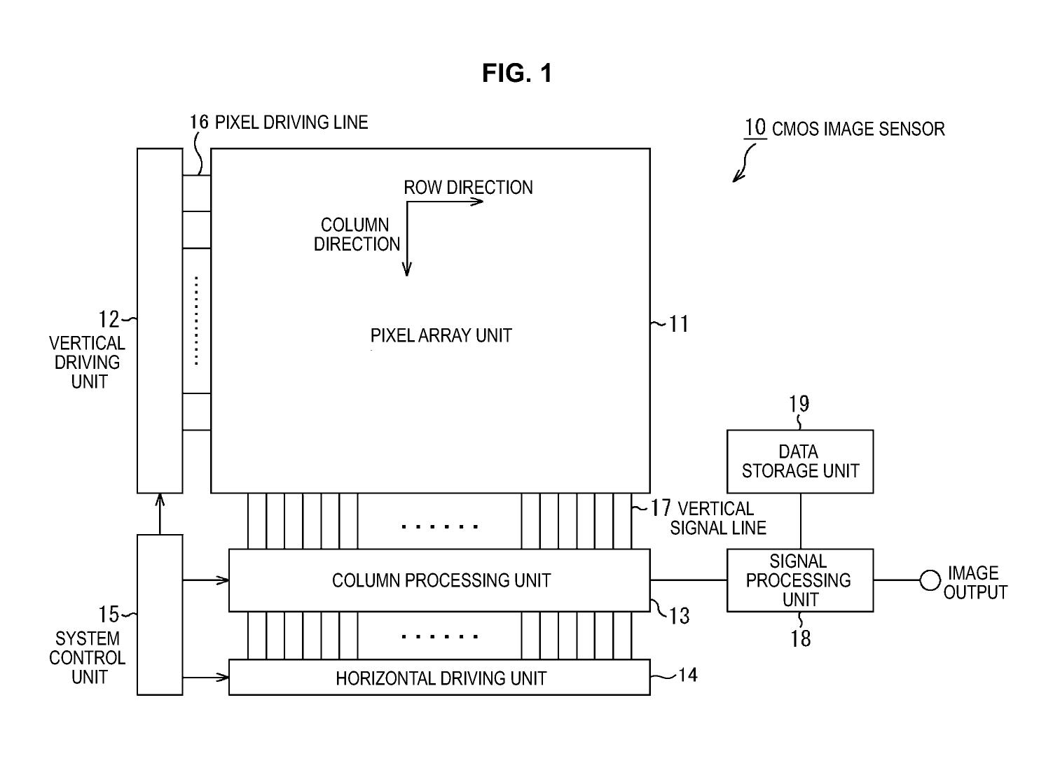

FIG. 1 is a system structure diagram illustrating a schematic structure of a CMOS image sensor that is a type of a solid-state imaging device to which the present disclosure is applied, for example, a solid-state imaging device of an X-Y address system. In this case, the CMOS image sensor is an image sensor that is made by applying or partially using a CMOS process.

A CMOS image sensor 10 according to this application example includes a pixel array unit 11 that is formed on a semiconductor substrate (chip) not illustrated in the drawings and a peripheral circuit unit that is integrated on the same semiconductor substrate as the pixel array unit 11. The peripheral circuit unit includes a vertical driving unit 12, a column processing unit 13, a horizontal driving unit 14, and a system control unit 15.

The CMOS image sensor 10 further includes a signal processing unit 18 and a data storage unit 19. The signal processing unit 18 and the data storage unit 19 may be mounted on the same substrate as the CMOS image sensor 10 or may be arranged on a substrate different from the substrate on which the CMOS image sensor 10 is arranged. Each processing of the signal processing unit 18 and the data storage unit 19 may be processing that is executed by an external signal processing unit provided on a substrate different from the substrate on which the CMOS image sensor 10 is arranged, for example, a digital signal processor (DSP) circuit or software.

The pixel array unit 11 has a structure in which unit pixels (hereinafter, they may be simply referred to “pixels”) each having a photoelectric converting unit to generate photocharges according to an amount of received light and store the photocharges are arranged two-dimensionally in a row direction and a column direction, that is, a matrix. In this case, the row direction means an arrangement direction (that is, horizontal direction) of pixels of pixel rows and the column direction means an arrangement direction (that is, vertical direction) of pixels of pixel columns. A specific circuit structure and a pixel structure of a unit pixel will be described in detail below.

In the pixel array unit 11, a pixel driving line 16 is provided along the row direction for each pixel row and a vertical signal line 17 is provided along the column direction for each pixel column, with respect to a pixel arrangement of the matrix. The pixel driving line 16 transmits a driving signal to perform driving, when a signal is read from the pixel. In FIG. 1, the pixel driving line 16 is illustrated as one wiring line. However, the number of pixel driving lines 16 is not limited to one. One end of the pixel driving line 16 is connected to an output terminal of the vertical driving unit 12 corresponding to each row.

The vertical driving unit 12 is configured using a shift register or an address decoder and drives each pixel of the pixel array unit 11 simultaneously with respect to all pixels or in a row unit. That is, the vertical driving unit 12 forms a driving unit to drive each pixel of the pixel array unit 11, together with the system control unit 15 to control the vertical driving unit 12. A specific structure of the vertical driving unit 12 is not illustrated in the drawings. However, the vertical driving unit 12 generally has two scanning systems of a read scanning system and a sweeping scanning system.

The read scanning system selects and scans the unit pixels of the pixel array unit 11 sequentially in a row unit to read signals from the unit pixels. The signal that is read from the unit pixel is an analog signal. The sweeping scanning system performs sweeping scanning with respect to a read row, on which read scanning is performed by the read scanning system, ahead of the read scanning by a time of a shutter speed.

Unnecessary charges are swept from the photoelectric converting unit of the unit pixel of the read row by the sweeping scanning performed by the sweeping scanning system and the photoelectric converting unit is reset. By sweeping the unnecessary charges (performing resetting) by the sweeping scanning system, a so-called electronic shutter operation is executed. In this case, the electronic shutter operation means an operation for abandoning the photocharges of the photoelectric converting unit and starting new exposure (starting to store the photocharges).

The signal that is read by the read operation executed by the read scanning system corresponds to an amount of light received after the immediately previous operation or the electronic shutter operation. In addition, a period from read timing of the immediately previous read operation or sweeping timing of the electronic shutter operation to read timing of a this-time read operation becomes an exposure period of the photocharges in the unit pixel.

The signal that is output from each unit pixel of the pixel row selected and scanned by the vertical driving unit 12 is input to the column processing unit 13 through each vertical signal line 17 for each pixel column. The column processing unit 13 executes predetermined signal processing with respect to the signal output from each pixel of a selected row through the vertical signal line 17 and temporarily stores a pixel signal after signal processing, for each pixel column of the pixel array unit 11.

Specifically, the column processing unit 13 executes at least noise removing processing, for example, correlated double sampling (CDS) processing as the signal processing. By the CDS processing executed by the column processing unit 13, reset noise or fixed pattern noise unique to the pixel such as a threshold value change of an amplification transistor in the pixel is removed. The column processing unit 13 can be configured to have an analog/digital (A/D) conversion function in addition to a noise removing processing function and convert an analog pixel signal into a digital pixel signal and output the digital pixel signal.

The horizontal driving unit 14 is configured using a shift register or an address decoder and sequentially selects unit circuits of the column processing unit 13 corresponding to the pixel columns. By the selection scanning executed by the horizontal driving unit 14, pixel signals that have been subjected to signal processing for each unit circuit in the column processing unit 13 are sequentially output.

The system control unit 15 is configured using a timing generator to generate various timing signals ad controls driving of the vertical driving unit 12, the column processing unit 13, and the horizontal driving unit 14, on the basis of the various timings generated by the timing generator.

The signal processing unit 18 has at least an operation processing function and executes a variety of signal processing such as operation processing with respect to pixel signal output from the column processing unit 13. The data storage unit 19 temporarily stores data necessary for the signal processing in the signal processing unit 18.

The CMOS image sensor 10 that has the above structure adopts global exposure to execute an exposure start and an exposure end at the same timing with respect to all pixels of the pixel array unit 11. That is, in the CMOS image sensor 10, collective exposure of all of the pixels is enabled. The global exposure is executed under driving performed by the driving unit including the vertical driving unit 12 and the system control unit 15. A global shutter function of realizing the global exposure is a shutter operation that is suitable for imaging of an object moving at a high speed or sensing in which synchronism of an imaging image is necessary.

### 1-2. Other System Structures

The system structure of the CMOS image sensor 10 to which the present disclosure is applied is not limited to the system structure described above. As other system structures, the following system structures may be exemplified.

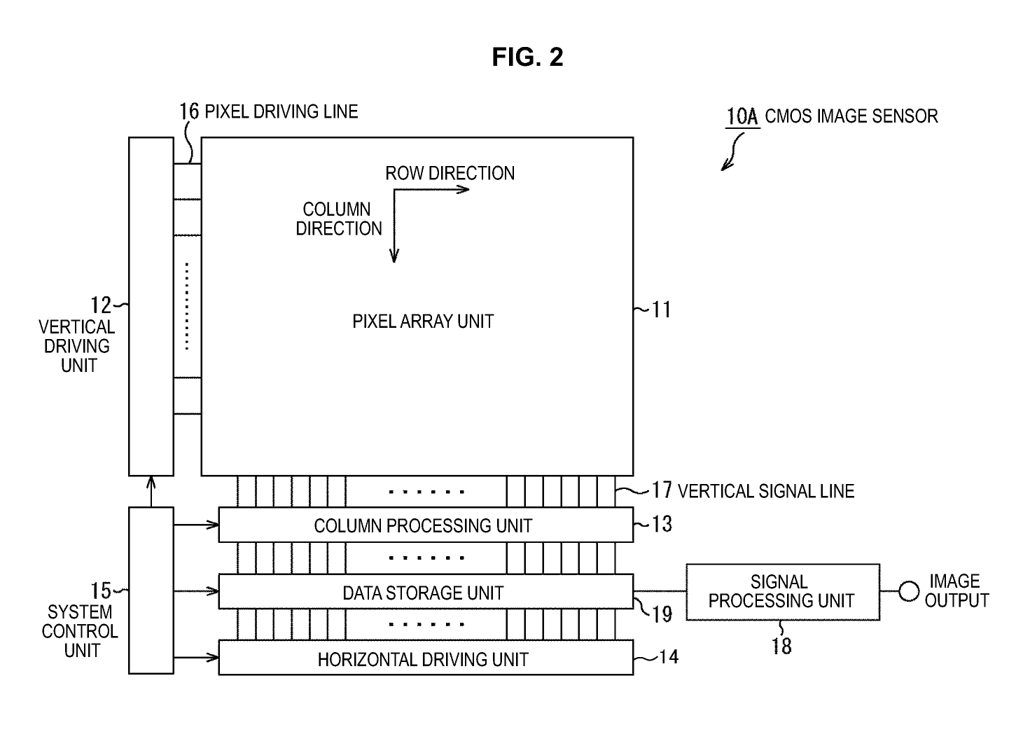

As illustrated in FIG. 2, a CMOS image sensor 10A that has a system structure in which a data storage unit 19 is arranged at a rear step of a column processing unit 13 and a pixel signal output from the column processing unit 13 is supplied to a signal processing unit 18 through the data storage unit 19 may be exemplified.

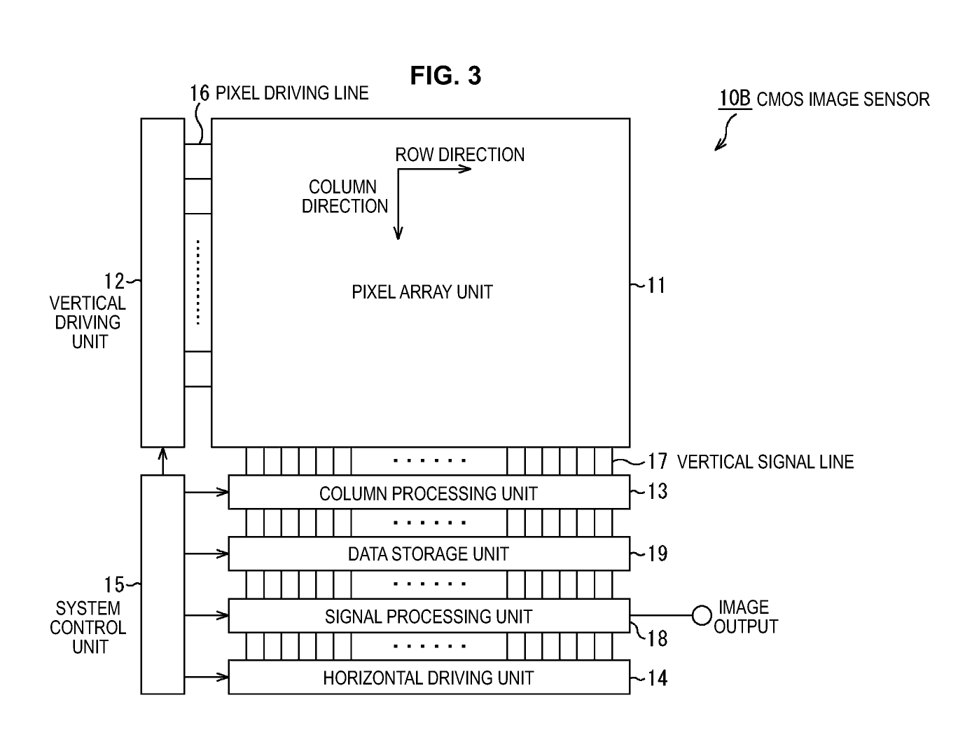

As illustrated in FIG. 3, a CMOS image sensor 10B that has a system structure in which an AD conversion function of performing AD conversion for each column or a plurality of columns of a pixel array unit 11 is provided in a column processing unit 13 and a data storage unit 19 and a signal processing unit 18 are provided in parallel to the column processing unit 13 may be exemplified.

### 2. Explanation of Embodiment

As compared with the related art in which the global exposure is realized, a solid-state imaging device (for example, CMOS image sensor) according to an embodiment has two charge storage units of first and second charge storage units in a unit pixel to secure more saturation charge amount without deteriorating quality of an imaging image at dark and low illuminance, when the global exposure is realized.

An embedded MOS capacitor is used as the first charge storage unit and a capacitor having a larger capacity value per unit area than the first charge storage unit is used as the second charge storage unit.

Preferably, with respect to the first charge storage unit and the second charge storage unit, a magnitude relation of the saturation charge amounts may be set as follows. That is, the saturation charge amount that is smaller than the saturation charge amount of the photoelectric converting unit is preferably set to the first charge storage unit.

When the saturation charge amount of the first charge storage unit is smaller than the saturation charge amount of the photoelectric converting unit, a shortage of the first charge storage unit is compensated by the second charge storage unit. Therefore, the second charge storage unit should have the saturation charge amount, such that a sum of the saturation charge amount of the first charge storage unit and the saturation charge amount of the second charge storage unit becomes equal to or more than the saturation charge amount of the photoelectric converting unit.

As described above, the two charge storage units of the first and second charge storage units are provided in the unit pixel, the embedded MOS capacitor is used as the first charge storage unit, and the capacitor having the larger capacity value per unit area than the first charge storage unit is used as the second charge storage unit. As a result, the following functions and effects can be obtained.

That is, as compared with the case in which the embedded MOS capacitor is formed with respect to the same area as a total area of the first charge storage unit and the second charge storage unit, a capacity value of a capacitor that can store the photocharges can be greatly increased, that is, more saturation charge amount can be secured. The embedded MOS capacitor is used with respect to a signal at low illuminance, an influence of an interface level or a defect is small, and properties at dark are not deteriorated as compared with the related art in which the global exposure is realized. Therefore, quality of an imaging image at low illuminance is not deteriorated.

As a result, with respect to the CMOS image sensor that has the same unit pixel size and does not have a global shutter function, a CMOS image sensor that has a global shutter function showing the same characteristic can be realized. In addition, with respect to the CMOS image sensor according to the related art that has the same unit pixel size and has the global shutter function, a CMOS image sensor in which a dynamic range is greatly extended can be realized.

### [2-1. Reason why Total Capacity Value of Charge Storage Units can be Increased by Dividing Charge Storage Unit]

As such, the embedded MOS capacitor is used as the first charge storage unit, and the capacitor having the larger capacity value per unit area than the first charge storage unit is used as the second charge storage unit, so that a total capacity value of the charge storage units can be increased. In this case, the reason why the total capacity value of the charge storage units can be increased will be described using one numerical value example.

For example, the case in which a capacitor having an area of 1 μm² is formed is considered. If a capacity value of the first charge storage unit per unit area is defined as 1 fF/μm², a capacity value of the second charge storage unit per unit area is defined as 10 fF/μm², and an entire capacitor having an area of 1 μm² is formed using the first charge storage unit, the capacity value of the capacitor having an area of 1 μm² becomes 1 fF.

At this time, if ½ of the area of 1 μm² is formed using the second charge storage unit, the capacity value of the capacitor having an area of 1 μm² becomes 5.5 fF (5.5 fF (=½ μm²×1 fF+½ μm²×10 fF). That is, if ½ of the area of 1 μm² is formed using the second charge storage unit, the capacity value of the capacitor having an area of 1 μm² becomes 5.5 times of the capacity value in the case in which ½ of the area of 1 μm² is not formed using the second charge storage unit.

If ¾ of the area of 1 μm² is formed using the second charge storage unit, the capacity value of the capacitor having an area of 1 μm² becomes 7.75 fF and becomes 7.75 times of the capacity value in the case in which ¾ of the area of 1 μm² is not formed using the second charge storage unit. When ½ of the area of 1 μm² is formed using the second charge storage unit, if the capacity value of the second charge storage unit per unit area is defined as 20 fF/μm², the capacity value of the capacitor having an area of 1 μm² becomes 10.5 fF and becomes 10.5 times of the capacity value in the case in which ½ of the area of 1 μm² is not formed using the second charge storage unit.

Meanwhile, a leak current is generally large in the capacitor having the large capacitance value per unit area and deterioration of properties at dark such as a dark current and a white spot becomes remarkable in the second charge storage unit. Therefore, when photocharges are transmitted simultaneously from the photoelectric converting unit to all pixels, the photocharges at low illuminance are stored in the first charge storage unit. In this case, the “photocharges at low illuminance” mean photocharges of an amount that is equal to or less than the saturation charge amount of the first charge storage unit. Because the first charge storage unit is configured using the embedded capacitor, an influence of an interface level or a defect is small and properties at dark are superior as compared with the second charge storage unit.

The photocharges at high illuminance are stored in both the first charge storage unit and the second charge storage unit. In this case, the “photocharges at high illuminance” mean photocharges of an amount more than the saturation charge amount of the first charge storage unit. At high illuminance when a handled charge amount is large, because a high S/N ratio can be secured, an influence of properties at dark such as a dark current and a white spot is small. Therefore, even when the photocharges at high illuminance are stored in the second charge storage unit having the large leak current, this rarely affects image quality.

As be clear from the above description, the embedded MOS capacitor is used as the first charge storage unit, and the capacitor having the larger capacity value per unit area than the first charge storage unit is used as the second charge storage unit, so that more saturation charge amount can be secured. In contrast, if the saturation charge amount is equal, the unit pixel size can be decreased by an amount corresponding to space saving.

When all pixels are read simultaneously, the photocharges at low illuminance are stored in the first charge storage unit that is superior in properties at dark such as a dark current and a white spot and the photocharges at high illuminance are stored in the second charge storage unit that is inferior in properties at dark. As a result, quality of an imaging image at dark and low illuminance is not deteriorated as compared with the related art in which the global exposure is realized.

As the capacitor having the larger capacity value per unit area than the first charge storage unit, that is, the capacitor having the larger capacity value per unit area than the embedded MOS capacitor, a surface-type MOS capacitor may be exemplified.

### [2-2. Explanation of Capacitor Having Large Capacity Value Per Unit Area]

In this case, a difference of the embedded MOS capacitor forming the first charge storage unit and the surface-type MOS capacitor forming the second charge storage unit will be described.

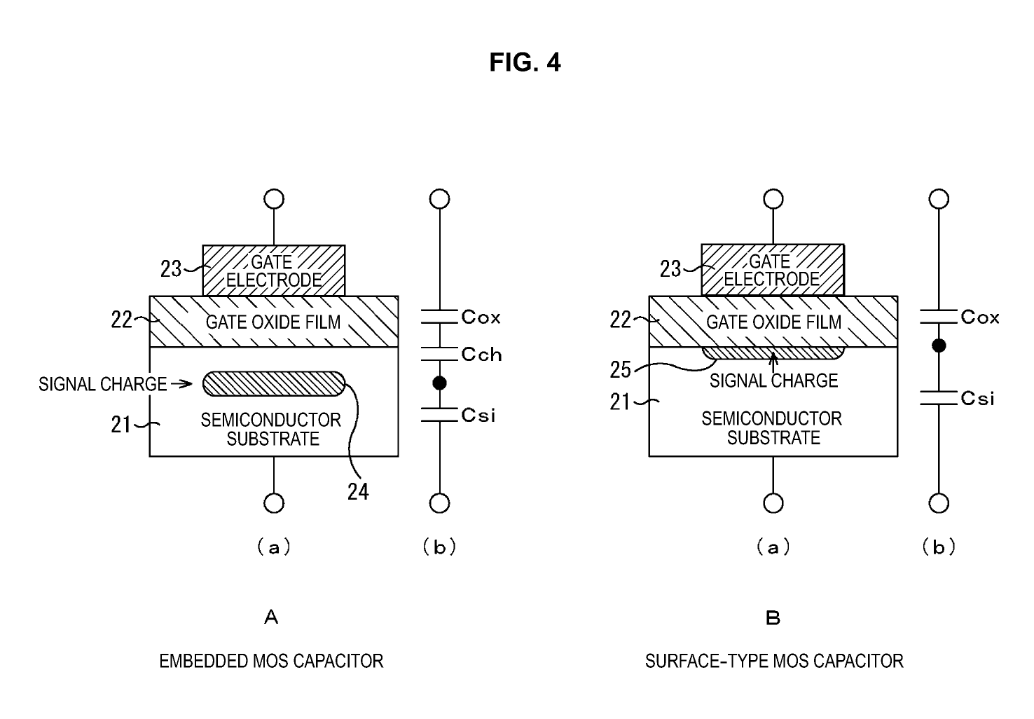

FIGS. 4A and 4B illustrate the embedded MOS capacitor and the surface-type MOS capacitor, respectively. In FIGS. 4A and 4B, (a) illustrates a cross-sectional structure of each MOS capacitor and (b) illustrates an equivalent circuit.

As illustrated in FIGS. 4A and 4B, in the embedded MOS capacitor and the surface-type MOS capacitor, a gate electrode 23 is disposed on a semiconductor substrate 21 with a gate oxide film 22 therebetween. In the case of the embedded MOS capacitor (refer to FIG. 4A), a charge storage region 24 to store signal charges is formed in a depth portion of the semiconductor substrate 21 and in the case of the surface-type MOS capacitor (refer to FIG. 4B), a charge storage region 25 is formed on a substrate surface of the semiconductor substrate 21.

In (b) of each of FIGS. 4A and 4B, Cox shows a capacity value of the gate oxide film 22, Cch shows a capacity value between the substrate surface and the charge storage region, and Csi shows a capacity value between the charge storage region and the substrate.

### (Case of Embedded Capacitor)

If a capacity value of the charge storage region 24 per unit area is defined as Cb, the capacity value Cb is represented by the following expression 1.

$$\begin{matrix}Cb = Cox \cdot Cch / ( Cox + Cch ) + Csi \\ = Cox \cdot \{ 1 / ( 1 + Cox / Cch ) \} + Csi\end{matrix} \qquad [ Expression 1 ]$$

In this case, if the capacity value Csi between the charge storage region and the substrate is sufficiently small, the expression 1 can be approximated by the following expression 2.

Ch≈Cox·{1/(1+Cox/Cch)} [Expression 2]

### (Case of Surface-Type Capacitor)

If the capacity value of the charge storage region per unit area is defined as Cs, the capacity value Cs is represented by the following expression (3).

Cs=Cox+Csi [Expression 3]

In this case, if the capacity value Csi between the charge storage region and the substrate is sufficiently small, the capacity value can be approximated by a capacity Cox of the gate oxide film 22, as represented by the following expression 4.

Cs≈Cox [Expression 4]

That is, a magnitude relation of the capacity value Cb of the charge storage region 24 per unit area and the capacity value Cs of the charge storage region 25 per unit area becomes Cb<Cs. The charge storage region is embedded from the surface of the substrate to an inner portion of the substrate, so that the capacity value decreases. In other words, the charge storage region moves from the inner portion of the substrate to the surface of the substrate, so that the capacity value increases.

### (Explanation of Method of Increasing Capacity Value Per Unit Area Materially)

The capacity value Cox of the gate oxide film 22 per unit area is represented by the following expression 5.

Cox=∈ox/tox [Expression 5]

In this case, ∈ox shows permittivity of the gate oxide film 22 and tox shows a film thickness of the gate oxide film 22.

The film thickness tox of the gate oxide film 22 is important in terms of withstanding pressure or a leak amount. By using a material having high permittivity at the same film thickness, the capacity value Cox per unit area can be increased. As the material having the high permittivity, the following materials may be exemplified.

Si₃N₄: relative permittivity of 7
Ta₂O₅: relative permittivity of 26
HfO₂: relative permittivity of 25
ZrO₂: relative permittivity of 25

The product of the permittivity and the relative permittivity of the vacuum becomes the permittivity of each material. For this reason, if a ratio of the relative permittivity with SiO₂ (relative permittivity of 3.9) is considered, an increase in the capacity value per unit area can be estimated. For example, if the surface-type MOS capacitor is assumed and Si₃N₄ having the same film thickness as SiO₂ is used, instead of SiO₂, the capacity value per unit area becomes 1.8 times of the existing capacity value. If Ta₂O₅ is used, the capacity value per unit area becomes 6.7 times of the existing capacity value.

### (Explanation of Method of Increasing Capacity Value Per Unit Area Structurally)

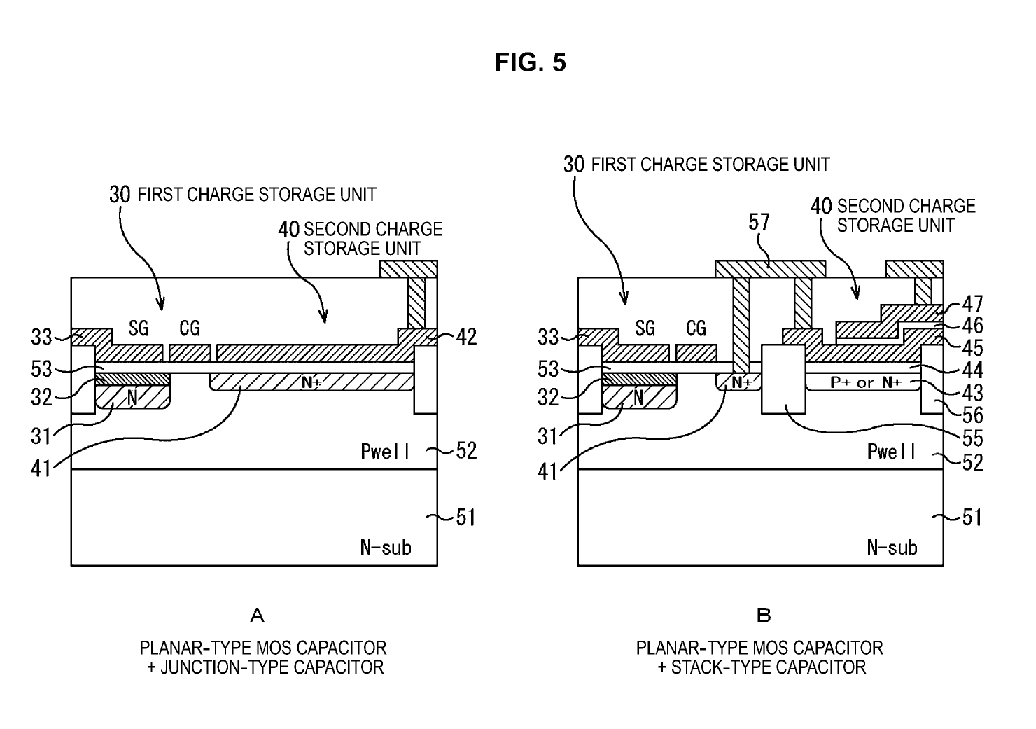

The capacity value per unit area can be increased by combining a plurality of capacitor structures, structurally. As the combination structures, structures illustrated in FIGS. 5A and 5B, that is, a structure (refer to FIG. 5A) obtained by combining a planar-type MOS capacitor and a junction-type capacitor and a structure (refer to FIG. B) obtained by combining a planar-type MOS capacitor and a stack-type capacitor may be exemplified.

First, the combination structure illustrated in FIG. 5A will be described. For example, a P-type well 52 is formed on an N-type semiconductor substrate 51. An N⁺-type semiconductor region 41 that becomes an intermediate electrode is formed in a surface layer of the P-type well 52 and a junction-type MOS capacitor is formed between the N⁺-type semiconductor region 41 and the P-type well 52 becoming a lower electrode. An upper electrode 42 is disposed on the surface of the substrate with an insulating film 53 therebetween, so that a planar-type MOS capacitor is formed in parallel to the junction-type MOS capacitor. That is, the second charge storage unit 40 is formed by connecting the planar-type MOS capacitor and the junction-type capacitor in parallel.

Next, the combination structure illustrated in FIG. 5B will be described. With respect to the first charge storage unit 30, the same planar-type MOS capacitor as that in the case of the combination structure illustrated in FIG. 5A is formed. With respect to the second charge storage unit 40, a planar-type MOS capacitor is formed in a region divided by element separation insulating films 55 and 56 and a stack-type capacitor is formed on the planar-type MOS capacitor by parallel connection.

Specifically, a P⁺-type (or N⁺-type) semiconductor region 43 that becomes a lower electrode is formed in a surface layer of the P-type well 52 and an intermediate electrode 45 is formed on the semiconductor region 43 with a capacity insulating film 44 therebetween. This structure is a structure of the planar-type MOS capacitor. An upper electrode 47 is formed on the intermediate electrode 45 with a capacity insulating film 46 therebetween. This structure is a structure of the stack-type capacitor. The intermediate electrode 45 is electrically connected to the Ni⁺-type semiconductor region 41 by a wiring line 57.

According to the combination structure illustrated in FIG. 5B, that is, the combination structure of the planar-type MOS capacitor and the stack-type capacitor, a capacitor that has a large capacity value per unit area can be formed.

### Other Structure Examples of Second Charge Storage Unit

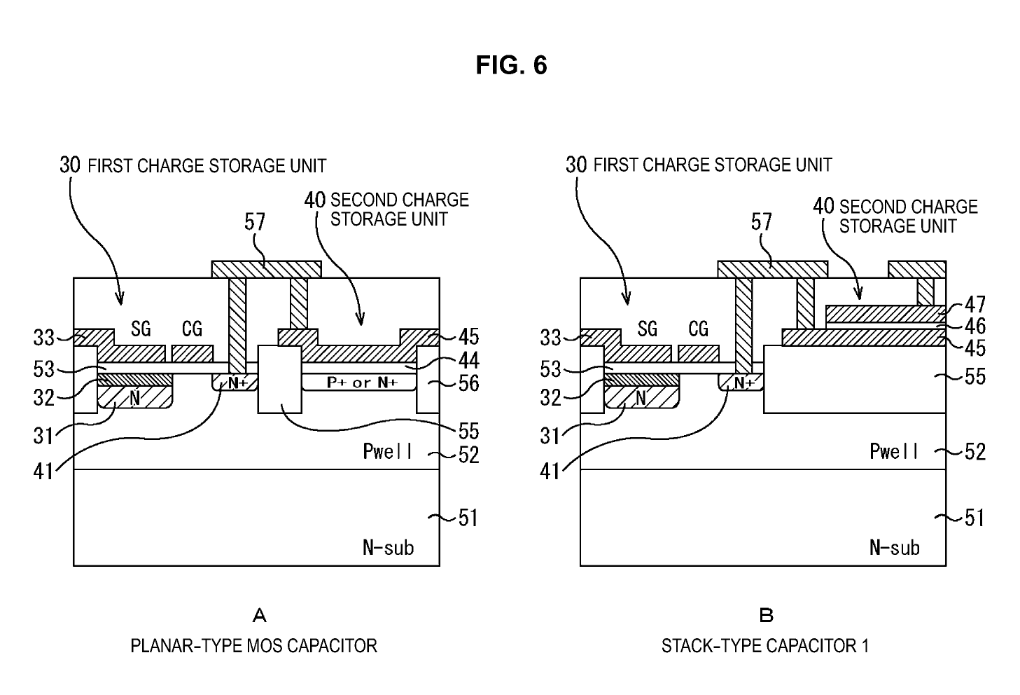

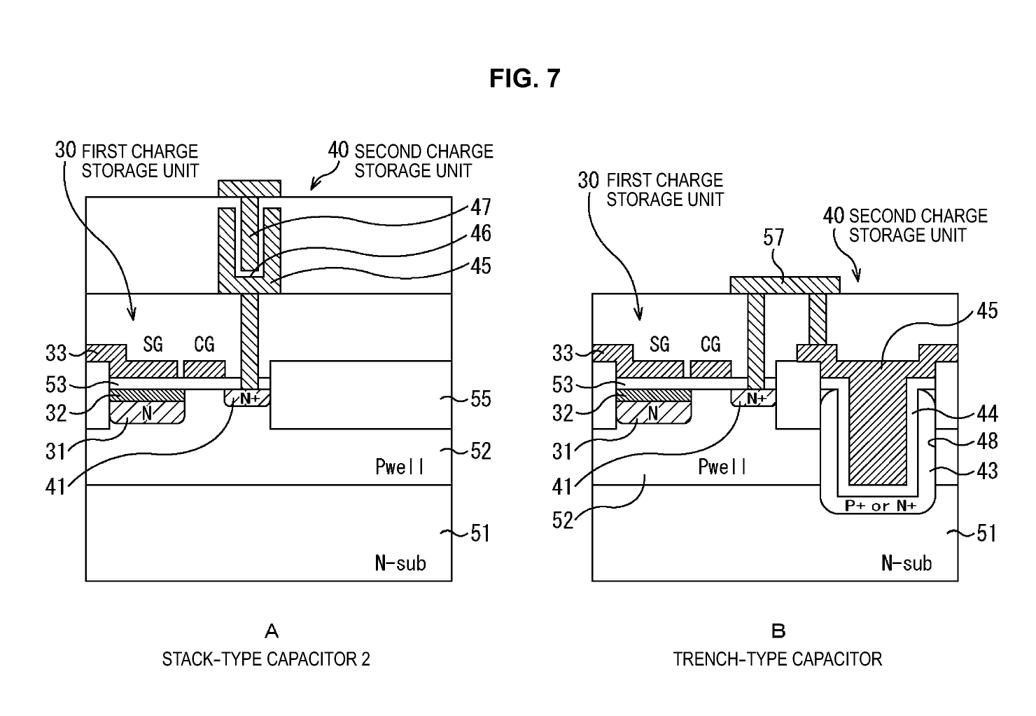

FIGS. 6A to 7B illustrate other structure examples of the second charge storage unit 40. In FIGS. 6A to 7B, the same structural elements as those in FIGS. 5A and 5B are denoted with the same reference numerals.

FIG. 6A is a cross-sectional view illustrating a structure of a planar-type MOS capacitor. The planar-type MOS capacitor that forms a second charge storage unit 40 has a structure in which a P⁺-type (or N⁺-type) semiconductor region 43 becoming a lower electrode is formed in a surface layer of a P-type well 52 and an upper electrode 45 is formed on the semiconductor region 43 with a capacity insulating film 44 therebetween

FIG. 6B is a cross-sectional view illustrating a structure of a stack-type capacitor 1. The stack-type capacitor 1 that forms the second charge storage unit 40 has a structure in which a lower electrode 45 is formed on an element separation insulating film 55 and an upper electrode 47 is formed on the lower electrode 45 with a capacity insulating film 46 therebetween.

FIG. 7A is a cross-sectional view illustrating a structure of a stack-type capacitor 2. The stack-type capacitor 2 that forms the second charge storage unit 40 has a structure in which a lower electrode 45 having a cross-sectional shape of an U shape is electrically connected to an N⁺-type semiconductor region 41 and an upper electrode 47 is inserted into the inner side of the lower electrode 45 with a capacity insulating film 46 therebetween.

In the case of the structure of the stack-type capacitor 2, a power-supply voltage is applied to the upper electrode 47 or the upper electrode 47 is connected to a ground. According to the stack-type capacitor 2 that includes the lower electrode 45 having the cross-sectional shape of the U shape and the upper electrode 47 embedded in the inner side of the lower electrode 45, a facing area that contributes to capacitance can be further increased as compared with a normal stack-type capacitor, for example, the stack-type capacitor 1.

FIG. 7B is a cross-sectional view illustrating a structure of a trench-type capacitor. The trench-type capacitor that forms the second charge storage unit 40 has a structure in which a trench 48 is formed to penetrate a P-type well 52 and reach a substrate 51 and a capacitor is formed in the trench 48.

Specifically, an N⁺-type (or P⁺-type) semiconductor region 43 becoming a lower electrode is formed in an inner wall of the trench 48, an inner wall of the semiconductor region 43 is coated with a capacity insulating film 44, and an upper electrode 45 is embedded with the capacity insulating film 44 therebetween.

The second charge storage unit 40 is configured using a planar-type MOS capacitor, a junction-type capacitor, a stack-type capacitor, a trench-type capacitor, or a combination thereof, in which a capacity insulating film is partially or entirely formed of materials having higher permittivity than a silicon oxide film. As the materials having the higher permittivity than the silicon oxide film (SiO₂), Si₃N₄, Ta₂O₅, HfO₂, and ZrO₂ may be exemplified.

The examples of the structure of the second charge storage unit 40 have been described on the basis of FIGS. 6A to 7B. However, the structure of the second charge storage unit 40 is not limited to the examples described above. Various methods that have been developed to increase a capacity in a memory capacity of a DRAM may be adopted.

### 3. Embodiment

Hereinafter, a specific embodiment of a unit pixel that has a first charge storage unit 30 and a second charge storage unit 40 therein will be described.

### (Circuit Structure of Unit Pixel 60A)

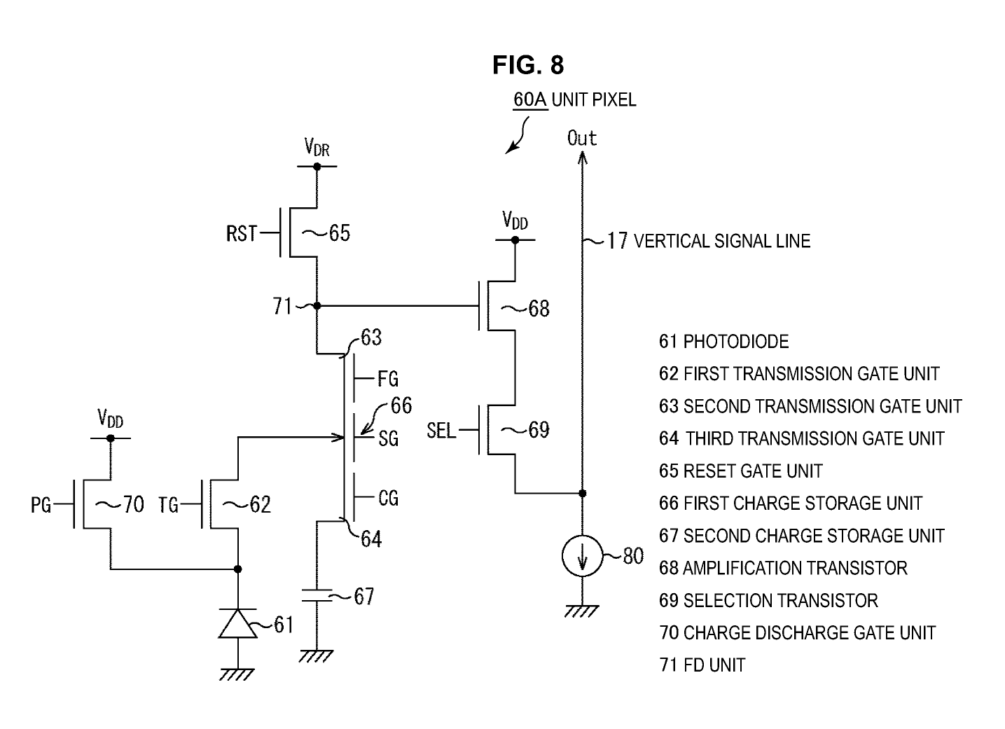

FIG. 8 is a circuit diagram illustrating a circuit structure of a unit pixel 60A to which the present disclosure is applied. As illustrated in FIG. 8, the unit pixel 60A has a photodiode 61 of a PN junction as a photoelectric converting unit to receive light and generate and store photocharges. The photodiode 61 generates photocharges according to an amount of received light and stores the photocharges.

The unit pixel 60A further has a first transmission gate unit 62, a second transmission gate unit 63, a third transmission gate unit 64, a reset gate unit 65, a first charge storage unit 66, a second charge storage unit 67, an amplification transistor 68, a selection transistor 69, and a charge discharge gate unit 70.

In the unit pixel 60A that has the structure described above, the first and second charge storage units 66 and 67 correspond to the first and second charge storage units described above. That is, the first charge storage unit 66 is provided as the embedded MOS capacitor between the first transmission gate unit 62 and the second transmission gate unit 63, in terms of a circuit. A driving signal SG (hereinafter, also referred to as a transmission signal SG) is applied to a gate electrode of the first charge storage unit 66. The second charge storage unit 67 is configured using a capacitor having a larger capacity value per unit area than the first charge storage unit 66. The layouts or the cross-sectional structures of the first and second charge storage units 66 and 67 will be described in detail below.

With respect to the unit pixels 60A, a plurality of driving lines that correspond to the pixel driving lines 16 of FIG. 1 are provided for every pixel row. In addition, various driving signals TG, SG, FG, CG, RST, SEL, and PG are supplied from the vertical driving unit 12 of FIG. 1 through the plurality of driving lines of the pixel driving lines 16. Because each transistor is an NMOS transistor in the structure described above, the driving signals TG, SG, FG, CG, RST, SEL, and PG are pulse signals in which a state of a high level (for example, power-supply voltage V_{DD}) becomes an active state and a state of a low level (for example, negative potential) becomes an inactive state.

The driving signal TG is applied as a transmission signal to the gate electrode of the first transmission gate unit 62. The first transmission gate unit 62 is connected between the photodiode 61 and the first charge storage unit 66, in terms of a circuit. The first transmission gate unit 62 enters a conductive state in response to when the driving signal TG (hereinafter, also referred to as a transmission signal TG) enters an active state and transmits photocharges stored in the photodiode 61 to the first charge storage unit 66. The photocharges that are transmitted by the first transmission gate unit 62 are stored temporarily in the first charge storage unit 66.

The driving signal FG is applied as a transmission signal to a gate electrode of the second transmission gate unit 63. The second transmission gate unit 63 is connected between the first charge storage unit 66 and a floating diffusion unit (hereafter, referred to as an “FD unit”) 71 to which a gate electrode of the amplification transistor 68 is connected, in terms of a circuit. The FD unit 71 converts photocharges into an electric signal, for example, a voltage signal and outputs the electric signal. The second transmission gate unit 63 enters a conductive state in response to when the driving signal FG (hereinafter, also referred to as a transmission signal FG) enters an active state and transmits the photocharges stored in the first charge storage unit 66 to the FD unit 71.

The driving signal CG is applied as a transmission signal to a gate electrode of the third transmission gate unit 64. The third transmission gate unit 64 is connected between the first charge storage unit 66 and the second charge storage unit 67, in terms of a circuit. The third transmission gate unit 64 enters a conductive state in response to when the driving signal CG (hereinafter, also referred to as a transmission signal CG) enters an active state and couples potentials of the first charge storage unit 66 and the second charge storage unit 67.

The driving signal RST is applied as a reset signal to a gate electrode of the reset gate unit 65. In the reset gate unit 65, one source/drain region is connected to a reset voltage V_{DR} and the other source/drain region is connected to the FD unit 71, in terms of a circuit. The reset gate unit 65 enters a conductive state in response to when the driving signal RST (hereinafter, also referred to as a reset signal RST) enters an active state and resets a level of the potential of the FD unit 71 to a level of the reset voltage V_{DR}.

The amplification transistor 68 has a gate electrode connected to the FD unit 71 and a drain electrode connected to a power-supply voltage V_{DD} and becomes an input unit of a read circuit reading photocharges obtained by photoelectric conversion in the photodiode 61, that is, a so-called source follower circuit, in terms of a circuit. That is, the amplification transistor 68 has a source electrode connected to the vertical signal line 17 through the selection transistor 69 and forms the source follower circuit with a constant current source 80 that is connected to one end of the vertical signal line 17.

The driving signal SEL is applied as a selection signal to a gate electrode of the selection transistor 69. The selection transistor 69 is connected between the source electrode of the amplification transistor 68 and the vertical signal line 17, in terms of a circuit. The selection transistor 69 enters a conductive state in response to when the driving signal SEL (hereinafter, also referred to as a selection signal SEL) enters an active state. The selection transistor 69 makes a state of the unit pixel 60A become a selection state and connects a pixel signal output from the amplification transistor 68 to the vertical signal line 17.

The driving signal PG is applied as a charge discharge control signal to a gate electrode of the charge discharge gate unit 70. The charge discharge gate unit 70 is connected between the photodiode 61 and a charge discharge unit (for example, power-supply voltage V_{DD}), in terms of a circuit. The charge discharge gate unit 70 enters a conductive state in response to when the driving signal PG (hereinafter, also referred to as a charge discharge control signal PG) enters an active state. The charge discharge gate unit 70 selectively discharges a predetermined amount of photocharges or all photocharges stored in the photodiode 61 to the charge discharge unit.

The charge discharge gate unit 70 is provided for the following purpose. That is, the charge discharge gate unit 70 is provided to prevent occurrence of the case in which the charge discharge gate unit 70 enters a conductive state during a period in which the photocharges are not stored, the photodiode 61 is saturated with the photocharges, and charges of an amount more than the saturation charge amount overflow to the first and second charge storage units 66 and 67 or peripheral pixels.

### (Pixel Structure of Unit Pixel 60A)

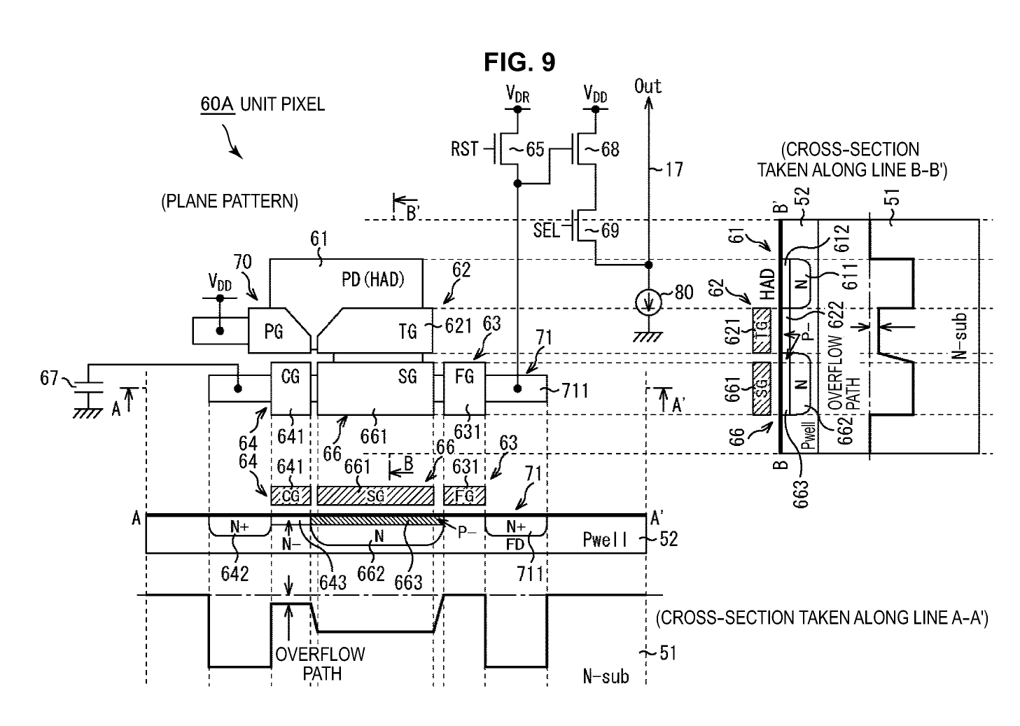

FIG. 9 is a schematic diagram illustrating a pixel structure of a unit pixel 60A. In FIG. 9, the same structural elements as those in FIG. 8 are denoted with the same reference numerals. FIG. 9 illustrates a plane pattern showing a pixel layout, a cross-sectional view taken along the line A-A′ in the plane pattern, and a cross-sectional view taken along the line B-B′.

In FIG. 9, as be clear from the cross-sectional view taken along the line B-B′, the photodiode (PD) 61 has a diode structure of a PN junction that is obtained by forming an N-type semiconductor region 611 in a P-type well 51 on a semiconductor substrate 51. The photodiode 61 becomes an embedded photodiode (a so-called hole accumulation diode (HAD) sensor structure) in which a depletion end is separated from an interface by forming a P-type semiconductor region 612 on a surface layer.

The first transmission gate unit 62 has a structure in which a gate electrode 621 is disposed on a surface of a substrate with a gate insulating film (not illustrated in the drawings) therebetween and a P⁻-type semiconductor region 622 is formed in a surface layer of the substrate. The P⁻-type semiconductor region 622 slightly deepens a potential under the gate electrode 621 as compared with the case in which the P⁻-type semiconductor region 622 is not formed. Thereby, as be clear from the cross-sectional view taken along the line B-B′, the P⁻-type semiconductor region 622 forms an overflow path to transmit photocharges of a predetermined amount or more overflown from the photodiode 61, specifically, photocharges of an amount more than a saturation charge amount of the photodiode 61 to the first charge storage unit 66.

The first charge storage unit 66 has a gate electrode 661 disposed on the surface of the substrate with a gate insulating film (not illustrated in the drawings) therebetween and is formed as an embedded MOS capacitor under the gate electrode 661. That is, the first charge storage unit 66 is configured using the embedded MOS capacitor that includes an N-type semiconductor region 662 formed in a P-type well 52 under the gate electrode 661 and a P⁻-type semiconductor region 663 formed on a surface layer of the N-type semiconductor region 662.

The second transmission gate unit 63 has a gate electrode 631 that is disposed on the surface of the substrate with a gate insulating film (not illustrated in the drawings) therebetween. In the second transmission gate unit 63, the N-type semiconductor region 662 of the first charge storage unit 66 is used as one source/drain region and an N⁺-type semiconductor region 711 becoming the FD unit 71 is used as the other source/drain region.

Therefore, the unit pixel 60A has a pixel structure in which the first charge storage unit 66 is formed as an embedded MOS capacitor under the gate electrode 661 formed adjacent to the first and second transmission gate units 62 and 63.

The third transmission gate unit 64 has a gate electrode 641 that is disposed on the surface of the substrate with a gate insulating film (not illustrated in the drawings) therebetween. In the third transmission gate unit 64, the N-type semiconductor region 662 of the first charge storage unit 66 is used as one source/drain region and an N⁺-type semiconductor region 642 formed in the surface layer of the substrate is used as the other source/drain region.

One end of the second charge storage unit 67 is electrically connected to the N⁺-type semiconductor region 642 of the third transmission gate unit 64. The other end of the second charge storage unit 67 is connected to a negative-side power supply (for example, ground).

The second transmission gate unit 63, the gate electrode 661 of the first charge storage unit 66, and the third transmission gate unit 64 perform an operation for coupling or dividing potentials of the FD unit 71, the first charge storage unit 66, and the second charge storage unit 67.

The third transmission gate unit 64 has a structure in which an N⁻-type semiconductor region 643 is formed in a surface layer of a channel unit. The N⁻-type semiconductor region 643 slightly deepens a potential under the gate electrode 641 as compared with the case in which the N⁻-type semiconductor region 643 is formed. Thereby, as be clear from the cross-sectional view taken along the line A-A′, the N⁻-type semiconductor region 643 forms an overflow path to transmit photocharges of an amount more than a saturation charge amount of the first charge storage unit 66 to the second charge storage unit 67.

In this case, it is important to form an overflow path formed under the first and third transmission gate units 62 and 64, such that the photocharges stored in the first charge storage unit 66 are transmitted to the second charge storage unit 67 without leaking into the photodiode 61.

As such, in the unit pixel 60A, the overflow pass is formed under the gate electrode 641 of the third transmission gate unit 64, so that the photocharges overflown from the photodiode 61 at high illuminance can be stored in the second charge storage unit 67. Specifically, even in a non-conductive state of the third transmission gate unit 64, the photocharges of the predetermined amount or more overflown from the first charge storage unit 66 can be transmitted to the second charge storage unit 67 and can be stored in the second charge storage unit 67. Thereby, the saturation charge amount of the first charge storage unit can be set to be smaller than the saturation charge amount of the photodiode 61.

### (Circuit Operation of Unit Pixel 60A)

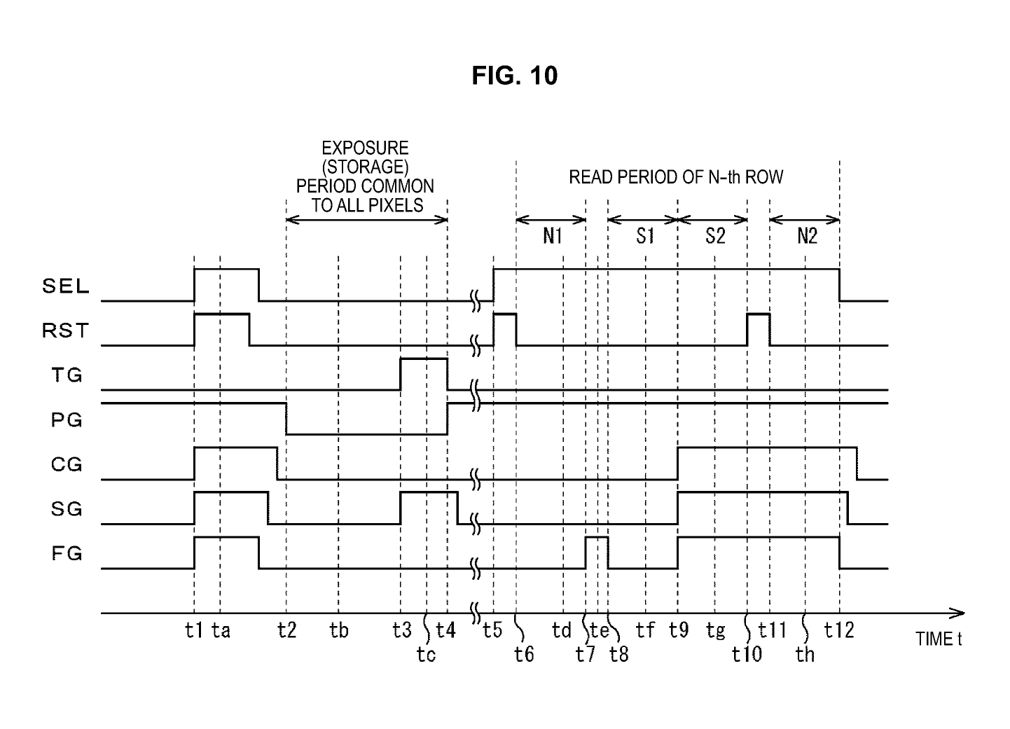

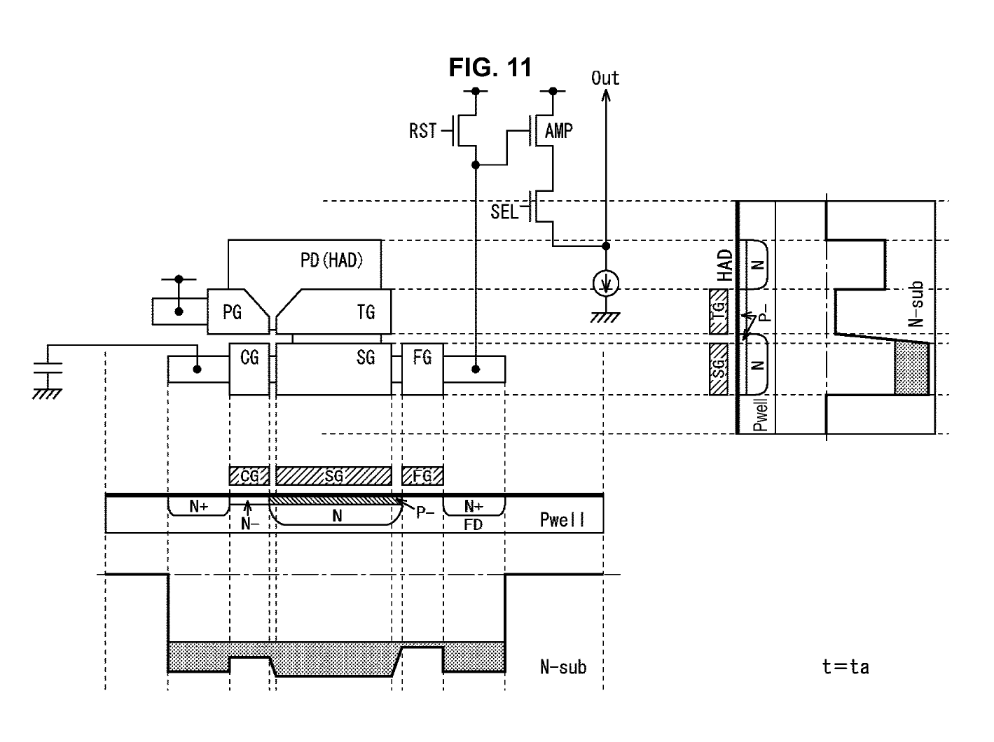

Next, a circuit operation of the unit pixel 60A will be described with reference to a timing chart of FIG. 10 and potential diagrams of FIGS. 11 to 18.

FIG. 10 illustrates a timing chart of a selection signal SEL, a reset signal RST, a transmission signal TG, a charge discharge control signal PG, a transmission signal CG a transmission signal SG, and a transmission signal FG of the unit pixel 60A. FIGS. 11 to 18 illustrate a state of a potential of a unit pixel 60A of an N-th row at times ta to th of the timing chart of FIG. 10.

First, at the time t1, the selection signal SEL, the reset signal RST, the transmission signal CG, the transmission signal SG, and the transmission signal FG enter an active state simultaneously with respect to all pixels, in a state in which the charge discharge control signal PG becomes active. Thereby, the selection transistor 69, the reset gate unit 65, the third transmission gate unit 64, the gate electrode 661 of the first charge storage unit 66, the second transmission gate unit 63, and the charge discharge gate unit 70 enter a conductive state.

FIG. 11 illustrates a state of a potential of the unit pixel 60A at the time to between the time t1 and the time t2. As such, the potentials of the FD unit 71, the first charge storage unit 66, and the second charge storage unit 67 are coupled and a coupled region is reset.

Then, the reset signal RST, the selection signal SEL and the transmission signal FG, the transmission signal SG, and the transmission signal CG enter an inactive state simultaneously with respect to all pixels in this order. At the time t2, the charge discharge control signal PG enters an inactive state simultaneously with respect to all pixels. Thereby, an exposure period that is common to all pixels starts.

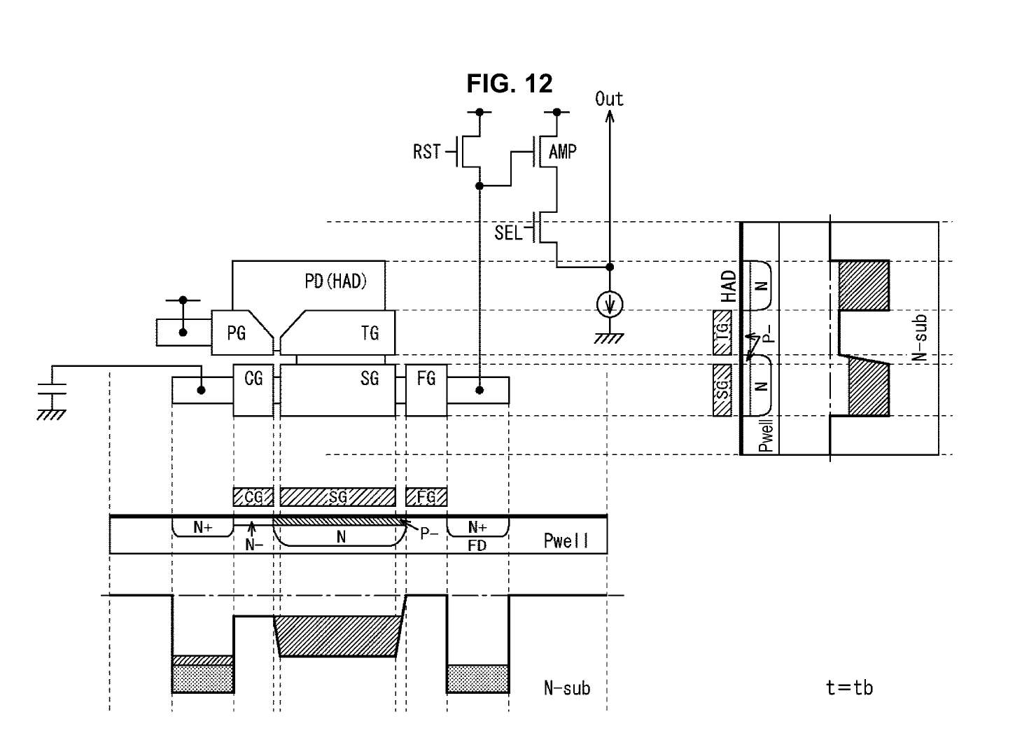

FIG. 12 illustrates a state of a potential of the unit pixel 60A at the time tb between the time t2 and the time t3. As such, the photocharges are stored in the photodiode 61. At high illuminance, the photocharges overflown from the photodiode 61 are stored in the first charge storage unit 66 through the overflow path of the first transmission gate unit 62. When the first charge storage unit 66 is saturated, the photocharges overflown from the first charge storage unit 66 are stored in the second charge storage unit 67 through the overflow path of the third transmission gate unit 64. At low illuminance, the photocharges are stored in only the photodiode 61.

Next, at the time t3, the transmission signal TG and the transmission signal SG enter an active state and the first transmission gate unit 62 and the gate electrode 661 of the first charge storage unit 66 enter a conductive state.

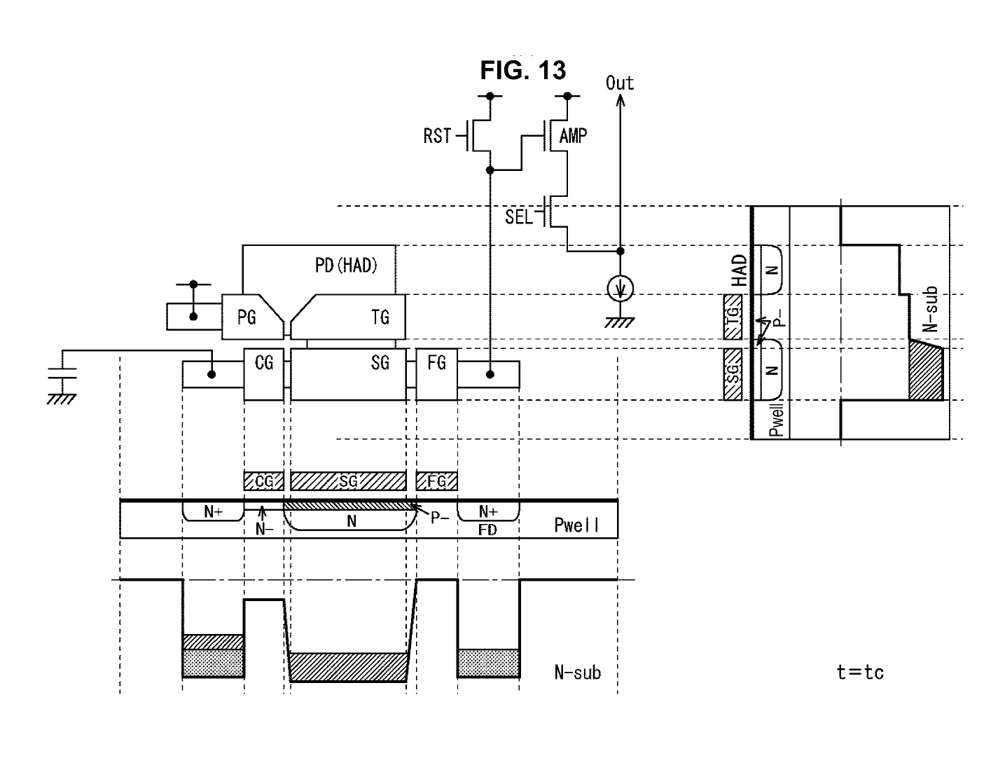

FIG. 13 illustrates a state of a potential of the unit pixel 60A at the time tc between the time t3 and the time t4. As such, the photocharges stored in the photodiode 61 are transmitted to the first charge storage unit 66 and are stored in the first charge storage unit 66.

Next, at the time t4, the charge discharge control signal PG enters an active state at the same time as when the transmission signal TG enters an inactive state simultaneously with respect to all pixels. The charge discharge gate unit 70 enters a conductive state at the same time as when the first transmission gate unit 62 enters a non-conductive state. Thereby, the exposure period that is common to all pixels ends.

Then, the transmission signal SG also enters an inactive state, the gate electrode 661 of the first charge storage unit 66 enters a non-conductive state, and the potential of the first charge storage unit 66 returns to the original potential. At this time, when the stored charge amount of the first charge storage unit 66 is more than the saturation charge amount, the photocharges overflown from the first charge storage unit 66 are transmitted to the second charge storage unit 67 through the overflow path of the third transmission gate unit 64.

After the exposure period common to all pixels ends, a read operation of the photocharges that are stored sequentially for each row is performed.

Specifically, at the time t5, the selection signal SEL of the N-th row enters an active state, the selection transistor 69 of the N-th row enters a conductive state, and the unit pixel 60A of the N-th row enters a selection state. At the same time, the reset signal RST enters an active state, the reset gate unit 65 enters a conductive state, and the FD unit 71 is reset. At the time t6, the reset signal RST enters an inactive state.

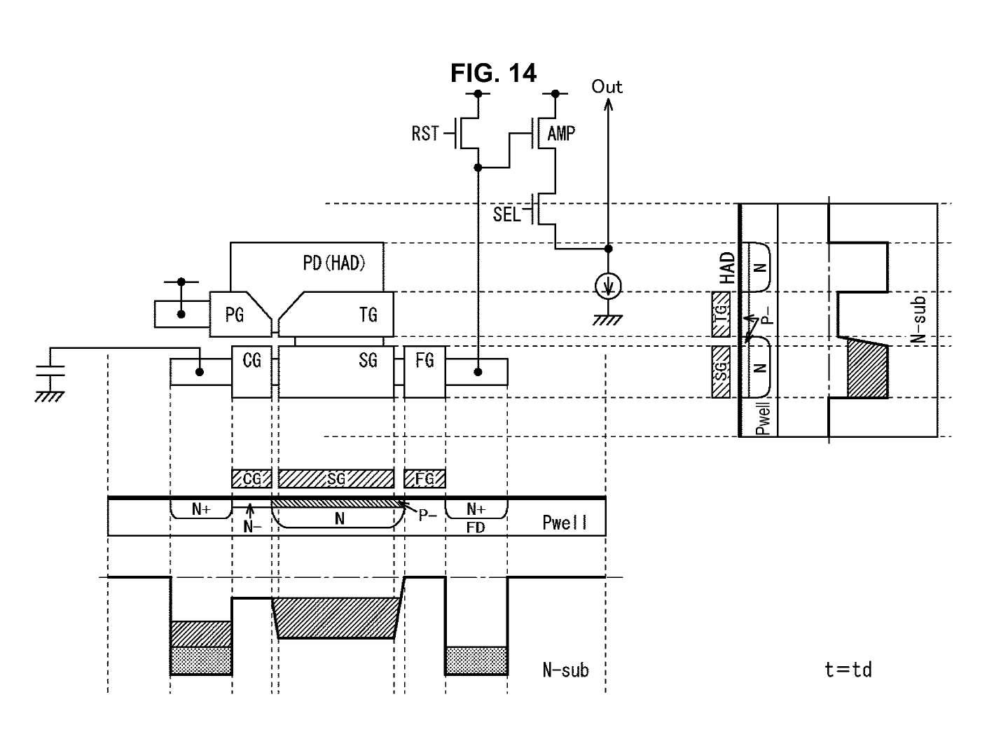

FIG. 14 illustrates a state of a potential of the unit pixel 60A at the time td between the time t6 and the time t7. In this state, the potential of the FD unit 71 is output as a first reset level N1 to the vertical signal line 17 through the amplification transistor 68 and the selection transistor 69.

Next, at the time t7, the transmission signal FG enters an active state, so that the second transmission gate unit 63 enters a conductive state.

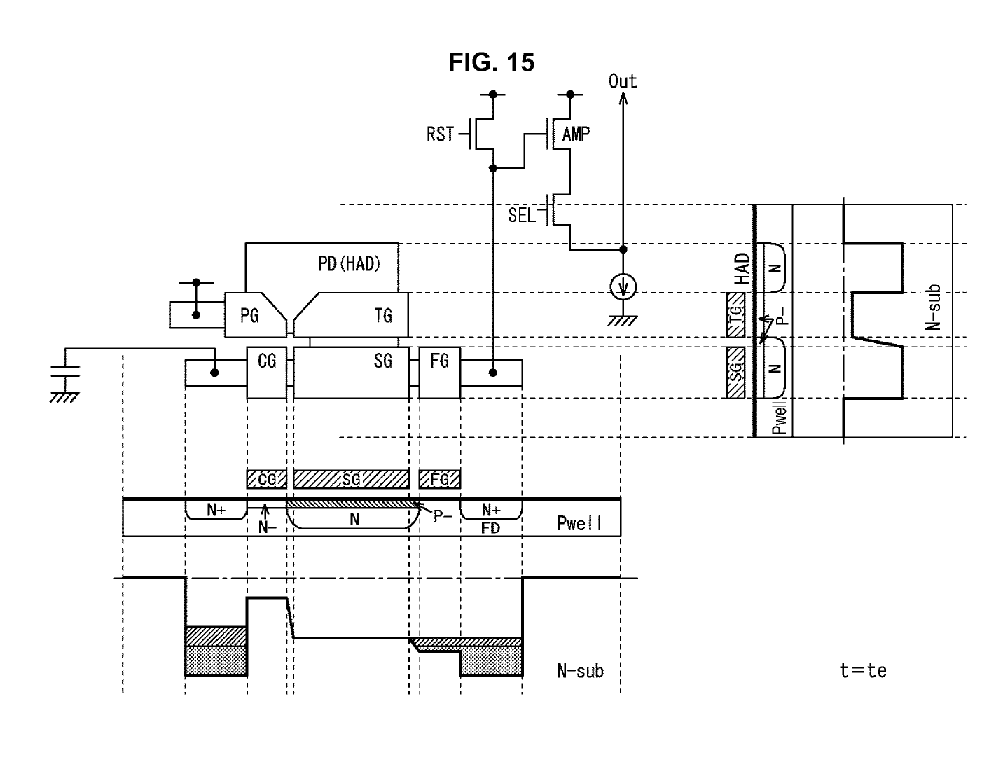

FIG. 15 illustrates a state of a potential of the unit pixel 60A at the time to between the time t7 and the time t8. As such, the photocharges that are stored in the first charge storage unit 66 are transmitted to the FD unit 71.

Next, at the time t8, the transmission signal FG enters an inactive state and the second transmission gate unit 63 enters a non-conductive state.

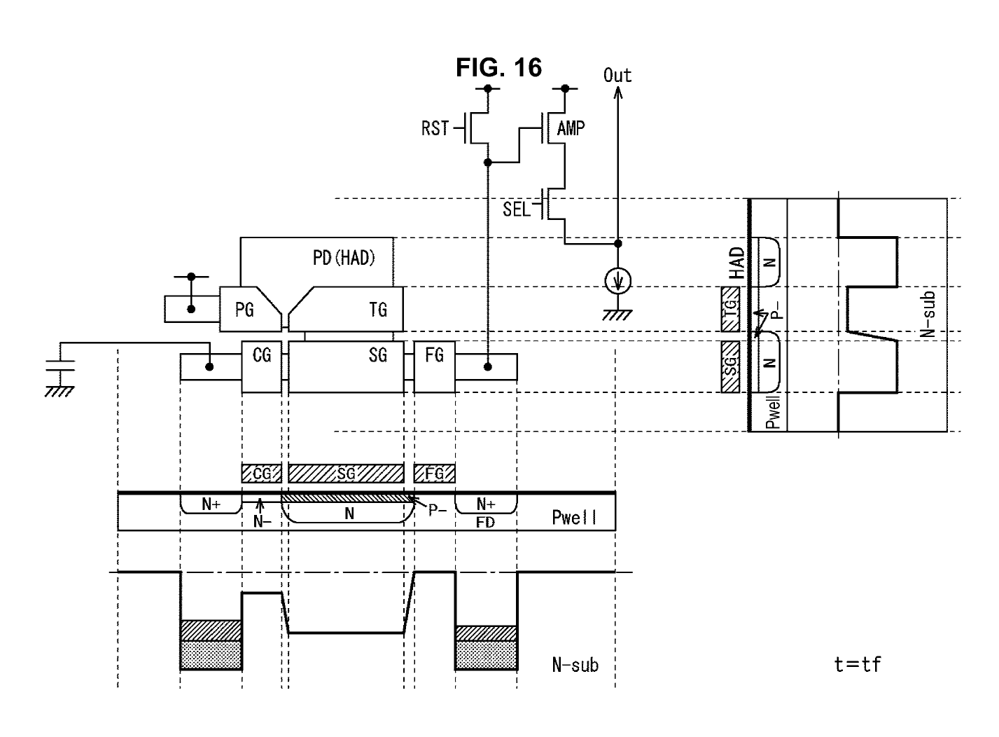

FIG. 16 illustrates a state of a potential of the unit pixel 60A at the time tf between the time t8 and the time t9. In this state, the potential of the FD unit 71 is output as a first signal level S1 according to the stored charge amount of the first charge storage unit 66 to the vertical signal line 17 through the amplification transistor 68 and the selection transistor 69.

Next, at the time t9, the transmission signals CG and SG, and FG enter an active state at the same time and the third transmission gate unit 64, the gate electrode 661 of the first charge storage unit 66, and the second transmission gate unit 63 enter a conductive state together.

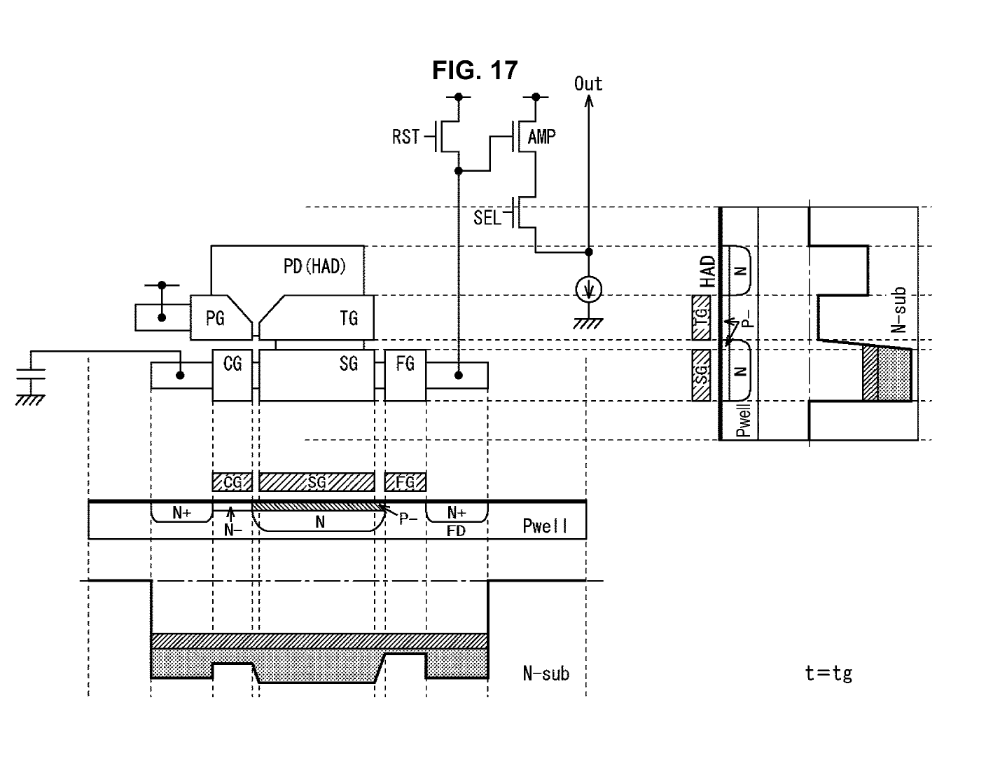

FIG. 17 illustrates a state of a potential of the unit pixel 60A at the time tg between the time t9 and the time t10. As such, the potentials of the FD unit 71, the first charge storage unit 66, and the second charge storage unit 67 are coupled and the photocharges are stored over an entire coupled region. The photocharges are output as a second signal level S2 to the vertical signal line 17 through the amplification transistor 68 and the selection transistor 69.

Next, at the time t10, the reset signal RST enters an active state and the reset gate unit 65 enters a conductive state. Thereby, a coupled region of the potentials of the FD unit 71, the first charge storage unit 66, and the second charge storage unit 67 is reset.

Next, at the time t11, the reset signal enters an inactive state and the reset gate unit 65 enters a non-conductive state.

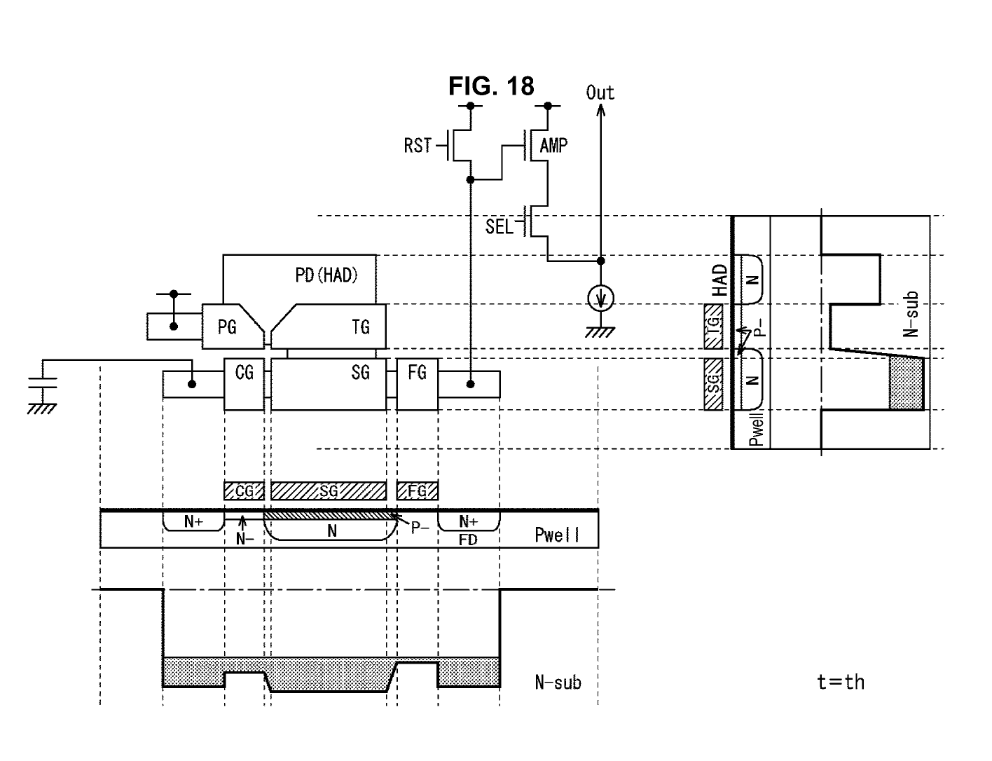

FIG. 18 illustrates a state of a potential of the unit pixel 60A at the time th between the time t11 and the time t12. In this state, the potential of the region where the potentials are coupled is output as a second reset level N2 to the vertical signal line 17 through the amplification transistor 68 and the selection transistor 69.

Next, at the time t12, the selection signal SEL of the N-th row enters an inactive state, the selection transistor 69 of the N-th row enters a non-active state, and the unit pixel 60A of the N-th row enters a non-selection state.

Then, the transmission signal FG, the transmission signal SG, and the transmission signal CG enter an inactive state in this order and the second transmission gate unit 63, the gate electrode 661 of the first charge storage unit 66, and the third transmission gate unit 64 enter a non-conductive state.

The reason why the transmission signal FG, the transmission signal SG, and the transmission signal CG enter an inactive state in this order are to store channel charges stored on the surface of the substrate in a state in which the gate electrode 661 of the first charge storage unit 66 becomes conductive, in the second charge storage unit 67. Different from the FD unit 71, because resetting is not made by only the second charge storage unit 67, an offset can be prevented from occurring in a pixel signal due to resetting of the channel charges.

By the series of circuit operations described above, the first reset level N1, the first signal level S1, the second signal level S2, and the second reset level N2 are output sequentially from the unit pixel 60A to the vertical signal line 17. By a signal processing unit of a rear step, predetermined signal processing is executed with respect to the first reset level N1, the first signal level S1, the second signal level S2, and the second reset level N2 output sequentially as described above. The signal processing will be described in detail below.

As described above, according to the unit pixel 60A, the embedded MOS capacitor is used as the first charge storage unit 66 and the capacitor having the larger capacity value per unit area than the first charge storage unit 66 is used as the second charge storage unit 67, so that more saturation charge amount can be secured. In contrast, if the saturation charge amount is equal, the unit pixel size can be decreased by an amount corresponding to space saving.

When all pixels are read simultaneously, the photocharges at low illuminance are stored in the first charge storage unit 66 that is superior in properties at dark and the photocharges at high illuminance are stored in the second charge storage unit 67 that is inferior in properties at dark. Therefore, quality of an imaging image at dark and low illuminance is not deteriorated as compared with the related art in which the global exposure is realized.

### First Modification

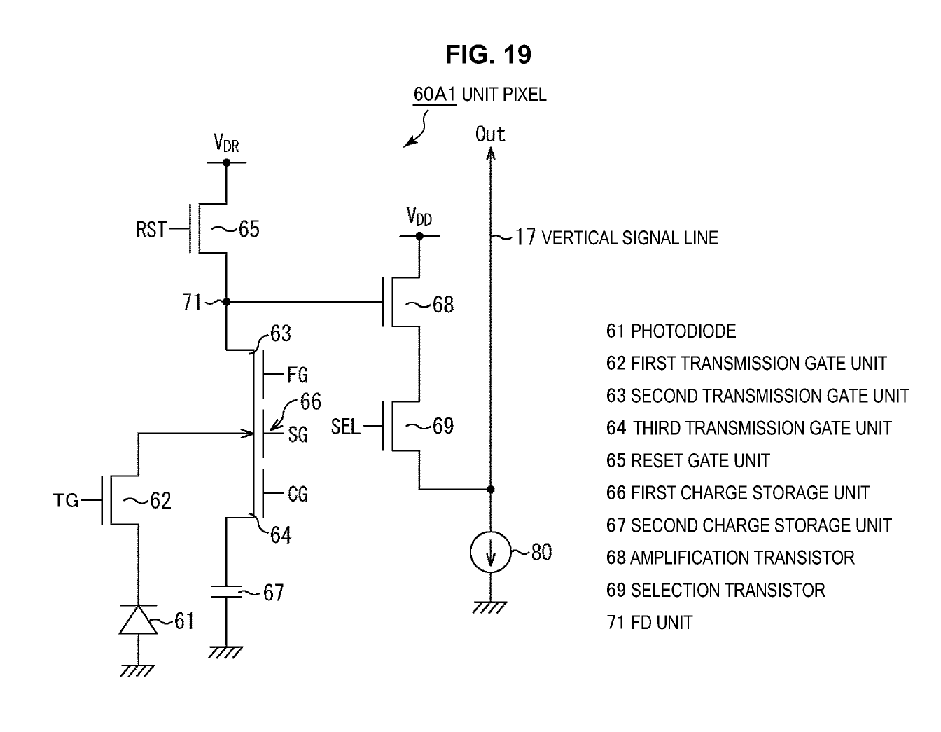

FIG. 19 is a circuit diagram illustrating a circuit structure of a unit pixel 60A1 according to a first modification of the unit pixel 60A. In FIG. 19, the same structural elements as those in FIG. 8 are denoted with the same reference numerals.

The unit pixel 60A1 according to the first modification is different from the unit pixel 60A in that the charge discharge gate unit 70 is omitted.

For example, during a period in which the photocharges are not stored, when the saturation of the photodiode 61 is prevented by another method or when the photodiode 61 is not saturated by the photocharges, the charge discharge gate unit 70 may be omitted.

### Second Modification

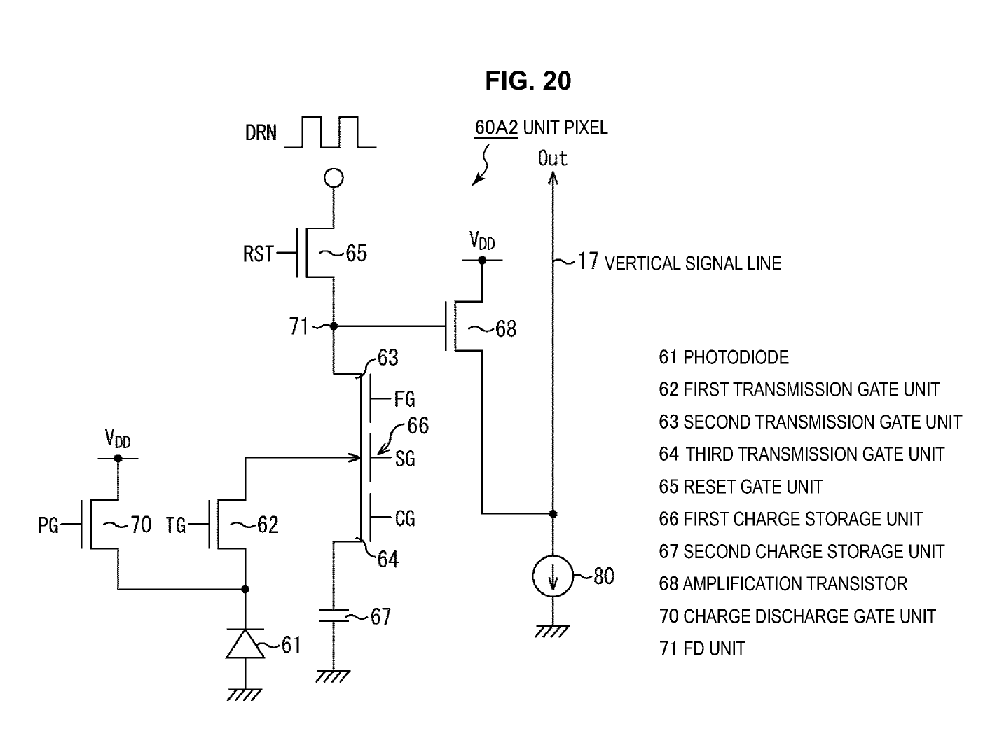

FIG. 20 is a circuit diagram illustrating a circuit structure of a unit pixel 60A2 according to a second modification of the unit pixel 60A. In FIG. 20, the same structural elements as those in FIG. 8 are denoted with the same reference numerals.

The unit pixel 60A2 according to the second modification is different from the unit pixel 60A in that the selection transistor 69 is omitted. In the unit pixel 60A2, a function of selecting a pixel by the selection transistor 69 is realized by varying a drain voltage DRN applied to a drain electrode of the reset gate unit 65.

Specifically, a high voltage corresponding to the drain voltage DRN is applied to the drain electrode of the reset gate unit 65, so that the amplification transistor 68 enters an active state and executes an output operation of a signal. That is, the amplification transistor 68 executes a function as the selection transistor with a switching operation of the drain voltage DRN. By omitting the selection transistor 69, the number of circuit elements forming the unit pixel 60 can be decreased by 1, for each pixel.

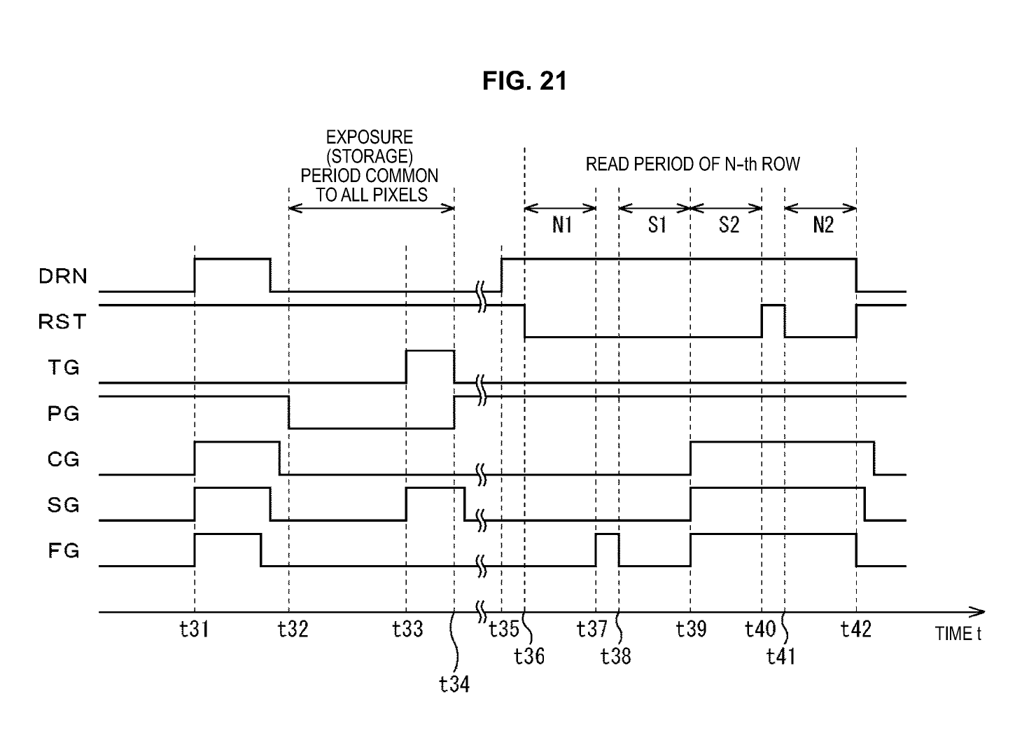

FIG. 21 is a timing chart illustrating a state of each signal, with respect to a circuit operation of the unit pixel 60A2, similar to FIG. 10.

The circuit operation of the unit pixel 60A2 is basically the same as the circuit operation of the unit pixel 60A, except for timing of the reset signal RST.

### (Pixel Sharing)

In the unit pixels 60A, 60A1, and 60A2, the circuit elements forming the pixel can be shared between the plurality of pixels.

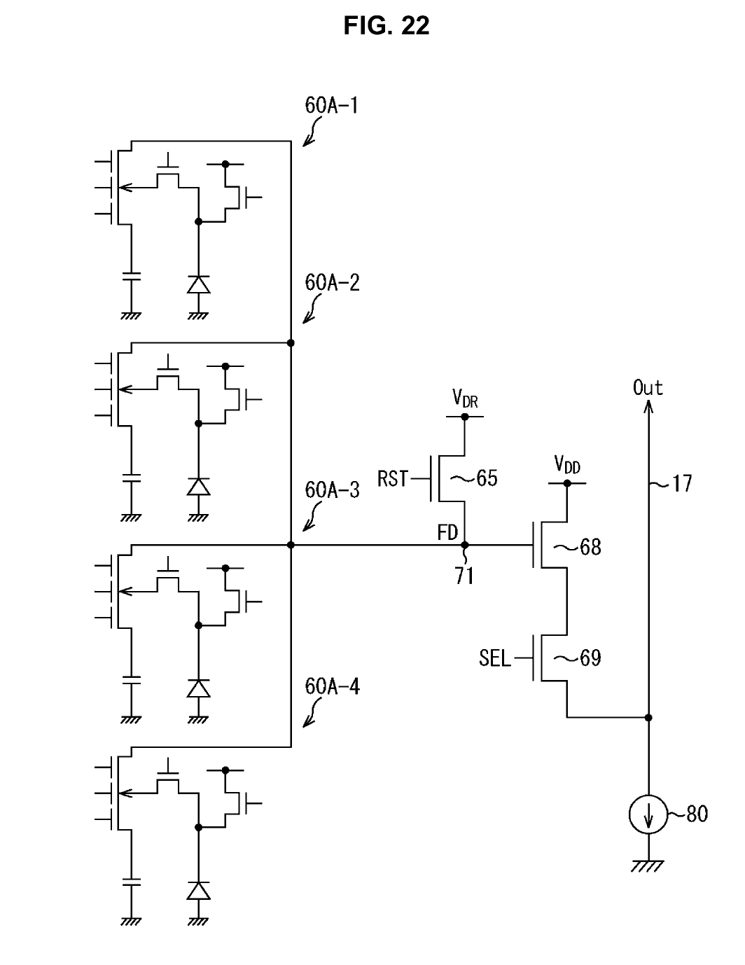

FIG. 22 is a circuit diagram illustrating a circuit structure according to a first specific example of pixel sharing. In the first specific example, the case in which four pixels 60A-1 to 60A-4 adjacent to each other share a part of pixel forming elements is exemplified. However, the number of pixels sharing the part of the pixel forming elements is not limited to four. As a relation of the four pixels 60A-1 to 60A-4 adjacent to each other, the part of the pixel forming elements may be shared between four pixels of two pixels in a row direction and two pixels in a column direction or may be shared between four pixels in the column direction.

In the first specific example, pixel sharing in the case of the pixel structure of the unit pixel 60A is exemplified. The circuit elements after the FD unit 71, including the reset gate unit 65, that is, the three circuit elements of the reset gate unit 65, the amplification transistor 68, and the selection transistor 69 are shared between the four pixels.

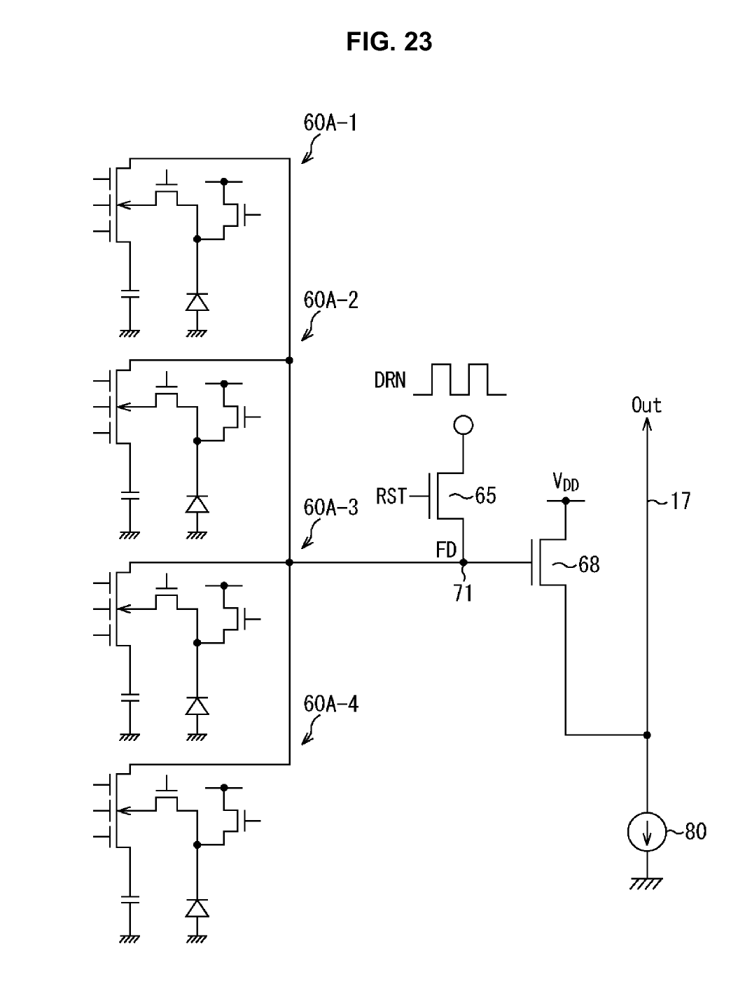

FIG. 23 is a circuit diagram illustrating a circuit structure according to a second specific example of the pixel sharing. In the second specific example, the case in which four pixels 60A-1 to 60A-4 adjacent to each other share a part of pixel forming elements is exemplified. However, the number of pixels sharing the part of the pixel forming elements is not limited to four. As a relation of the four pixels 60A-1 to 60A-4 adjacent to each other, the part of the pixel forming elements may be shared between four pixels of two pixels in a row direction and two pixels in a column direction or may be shared between four pixels in the column direction.

In the second specific example, pixel sharing in the case of the pixel structure of the unit pixel 60A2 according to the second modification is exemplified. The circuit elements after the FD unit 71, including the reset gate unit 65, that is, the two circuit elements of the reset gate unit 65 and the amplification transistor 68 are shared between the four pixels.

As such, technology for sharing the circuit elements between the plurality of pixels is used together, so that the same function and effect as the unit pixel 60A can be obtained, and a unit pixel size can be decreased and a space can be saved. In addition, more saturation charge amount can be secured by space saving. In contrast, if the saturation charge amount is equal, the unit pixel size can be decreased by an amount corresponding to space saving.

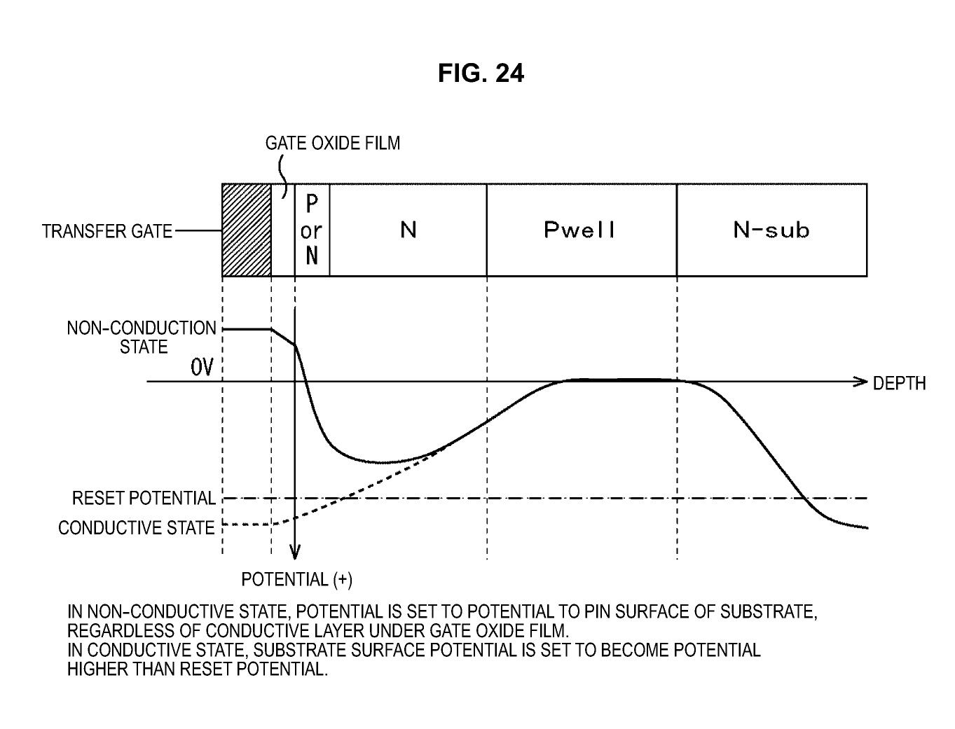

In this case, each potential of the first to third transmission gate units 62 to 64 and the gate electrode 661 of the first charge storage unit 66 will be described. FIG. 24 is a potential diagram of a substrate depth direction illustrating conditions to pin the surface of the substrate and couple potentials of the FD unit 71, the first charge storage unit 66, and the second charge storage unit 67.

The potentials of the first to third transmission gate units 62 to 64 and the gate electrode 661 of the first charge storage unit 66 in a non-conductive state are set to the potential (for example, negative potential) to pin the surface of the substrate, regardless of a conductive layer under the gate oxide film. In this way, the surface of the substrate is pinned and an improvement effect of properties at dark such as a dark current and a white spot can be obtained.

The substrate surface potentials of the second and third transmission gate units 63 and 64 and the gate electrode 661 of the first charge storage unit 66 in a conductive state are set to a potential higher than a reset voltage V_{DR}, that is, a potential applied to a drain of the reset gate unit 65. In this way, the potentials of the FD unit 71, the first charge storage unit 66, and the second charge storage unit 67 can be coupled.

### 4. Explanation of Noise Removing Processing and Operation Processing

From the unit pixel 60A and the unit pixels according to the modifications thereof, the signals are output to the vertical signal line 17 in order of the first reset level N1, the first signal level S1, the second signal level S2, and the second reset level N2. In the signal processing units of the rear step, for example, the column processing unit 13 and the signal processing unit 18 illustrated in FIGS. 1 to 3, the predetermined noise removing processing and the predetermined signal processing are executed with respect to the first reset level N1, the first signal level S1, the second signal level S2, and the second reset level N2. Hereinafter, the noise removing processing in the column processing unit 13 of the rear step and the operation processing in the signal processing unit 18 of the rear step will be described.

First, processing in a CDS circuit that is embedded in the column processing unit 13 and functions as a noise removing unit will be described. As the CDS circuit, any CDS circuit that has a known circuit structure may be used.

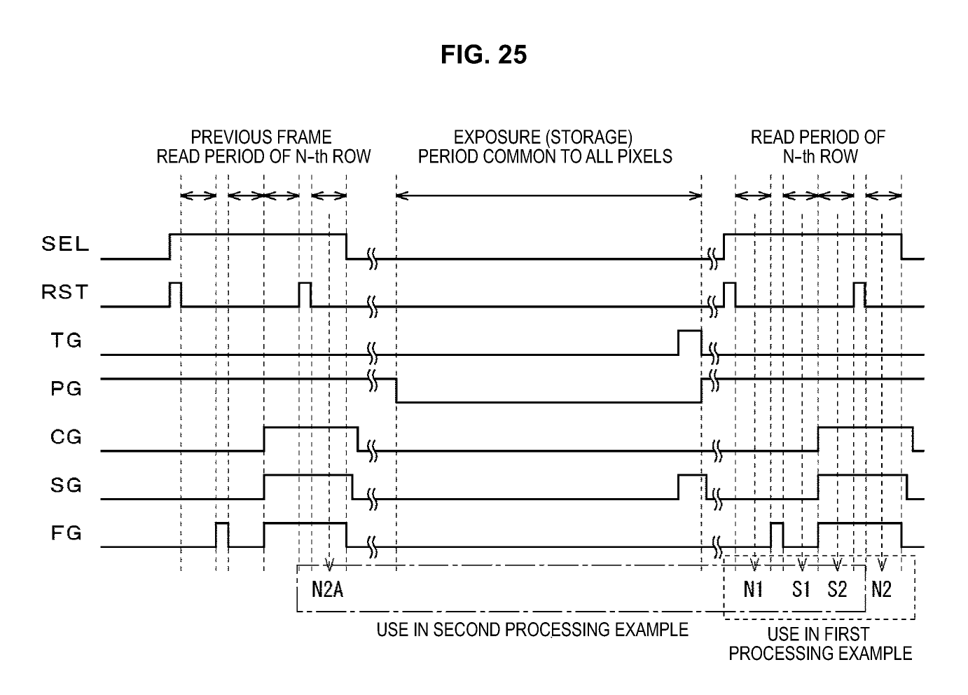

FIG. 25 is a timing chart illustrating noise removing processing in a case of a first processing example and a case of a second processing example, in the column processing unit 13.

### First Processing Example

First, a difference of a voltage signal S1 based on photocharges transmitted to the FD unit 71 when a signal is read and a voltage signal N1 based on a reset level before the photocharges are transmitted to the FD unit 71 is calculated. Next, a difference of a voltage signal S2 based on photocharges stored in the FD unit 71, the first charge storage unit 66, and the second charge storage unit 67 and a voltage signal N2 based on a reset level after the FD unit 71, the first charge storage unit 66, and the second charge storage unit 67 are reset is calculated. If the first difference is defined as SN1 and the second difference is defined as SN2, SN1=S1−N1 and SN2=S2−N2 are satisfied.

As such, in the first processing example, CDS processing by which reset noise or fixed pattern noise unique to the pixel such as a threshold value change of an amplification transistor in the pixel is removed is executed with respect to the signals S1 and S2 output earlier. CDS processing by which the fixed pattern noise unique to the pixel such as the threshold value change of the amplification transistor in the pixel is removed, but the reset noise is not removed is executed with respect to the signals S2 and N2 output later. However, because the operation processing is operation processing in which it is not necessary to use a frame memory, a circuit structure can be simplified and a cost can be decreased.

### Second Processing Example

In the second processing example, a storage unit, for example, a frame memory is necessary to use information of a previous frame. Therefore, operation processing according to the second processing example is executed by using the data storage unit 19 as a storage unit in the signal processing unit 18 or using a frame memory in an external DSP circuit.

Specifically, first, a difference of a voltage signal S1 based on photocharges transmitted to the FD unit 71 when a signal is read and a voltage signal N1 based on a reset level before the photocharges are transmitted to the FD unit 71 is calculated. Next, a difference of a voltage signal S2 based on photocharges stored in the FD unit 71, the first charge storage unit 66, and the second charge storage unit 67 and a voltage signal N2A in a previous frame is calculated. The voltage signal N2A is a signal based on a reset level after the photocharges stored in the FD unit 71, the first charge storage unit 66, and the second charge storage unit 67 in the previous frame are reset. If the first difference is defined as SN1 and the second difference is defined as SN2, SN1=S1−N1 and SN2=S2−N2A are satisfied.

As such, in the second processing example, the CDS processing by which the reset noise or the fixed pattern noise unique to the pixel such as the threshold value change of the amplification transistor in the pixel is removed is executed with respect to the signals S2 and N2 output later. In the case of the second processing example, the storage unit such as the frame memory is necessary. However, the reset noise can be greatly suppressed as compared with the first processing example.

### Third Processing Example

Next, operation processing in the signal processing unit 18 will be described. First, when the first difference is within a predetermined range, a ratio of the first difference and the second difference is calculated as gain for each pixel, a plurality of pixels, each color, each specific pixel in a sharing pixel unit, or all pixels and a gain table is generated. The product of the second difference and the gain table is calculated as an operation value of the second difference.

In this case, if the first difference is defined as SN1, the second difference is defined as SN2, the gain is defined as G, and the operation value of the second difference SN2 is defined as SN2′, the gain G and the operation value SN2′ of the second difference SN2 can be calculated on the basis of the following expressions 6 and 7.

$$\begin{matrix}\begin{matrix}G = SN 1 / SN 2 \\ = ( Cfd + Cgs + Ccap ) / Cfd\end{matrix} & [ Expression 6 ] \\ SN {2}^{′} = G \times SN 2 & [ Expression 7 ]\end{matrix}$$

In this case, Cfd shows a capacity value of the FD unit 71, Cgs shows a capacity value of the first charge storage unit 66, and Ccap shows a capacity value of the second charge storage unit 67. The gain G is equivalent to a capacity ratio.

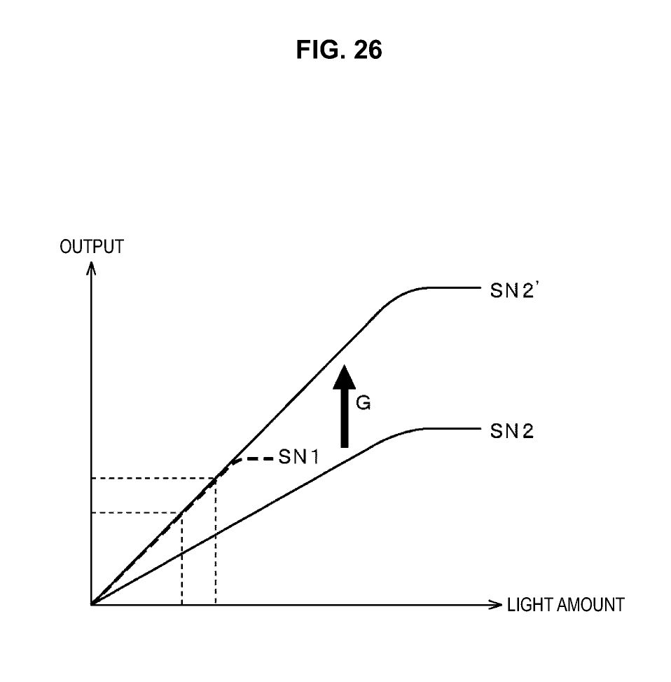

A relation of the first difference SN1, the second difference SN2, and the operation value SN2′ of the second difference SN2 with respect to an amount of incident light is illustrated in FIG. 26.

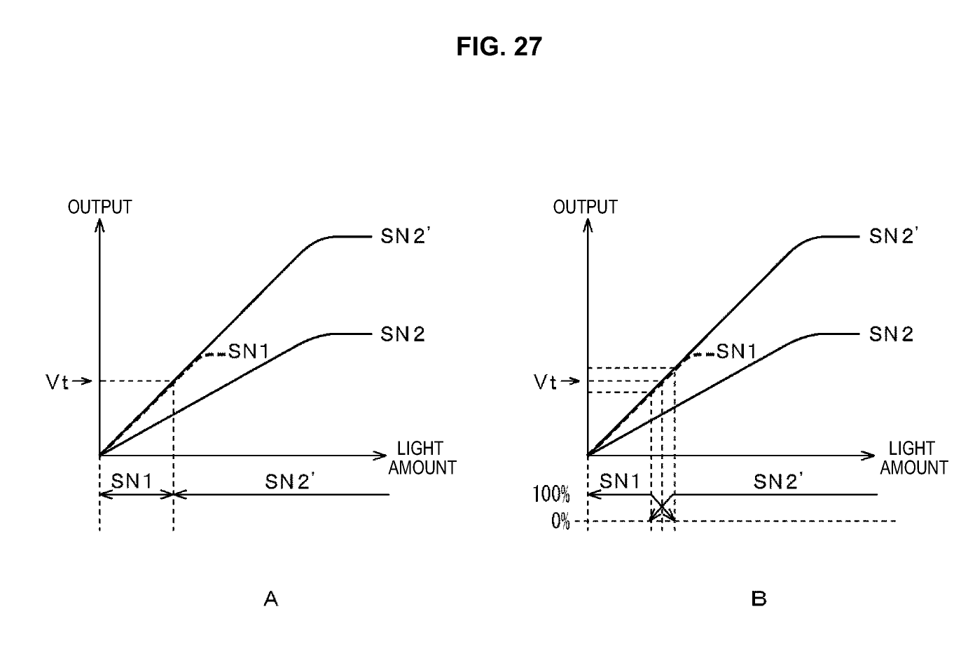

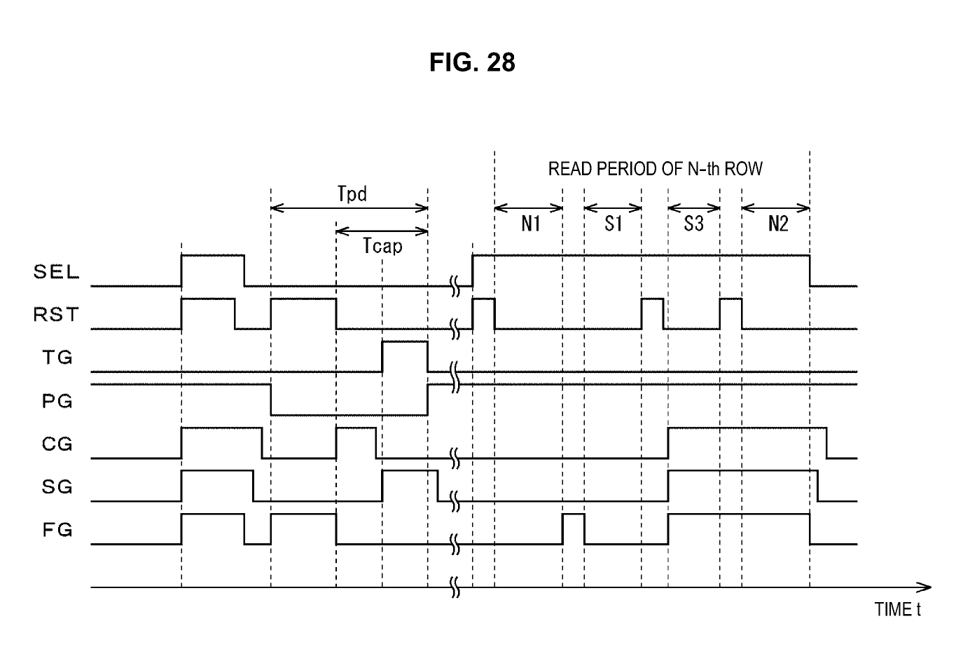

Next, as illustrated in FIG. 27A, a predetermined threshold value Vt that is set in advance is used. The predetermined threshold value Vt is set in advance in a state in which the first difference SN1 is not yet saturated in a photoresponsive characteristic and the photoresponsive characteristic is in a linear area.

When the first difference SN1 is not more than the predetermined threshold value Vt, the first difference SN1 is output as a pixel signal SN of a processing object pixel. That is, in the case of SN1<Vt, SN=SN1 (SN1 is substituted for SN) is satisfied. When the first difference SN1 is more than the predetermined threshold value Vt, the operation value SN2′ of the second difference SN2 is output as the pixel signal SN of the processing object pixel. That is, in the case of Vt≦SN1, SN=SN2′ (SN2′ is substituted for SN) is satisfied.

### Fourth Processing Example

In next operation processing, as illustrated in FIG. 27B, in a state in which the first difference SN1 is within a predetermined range, the value of the first difference SN1 and the operation value SN2′ of the second difference SN2 are synthesized with a preset ratio and a synthesis result is output as the pixel signal SN.

For example, in a range of values similar to the predetermined threshold value Vt, a synthesis ratio of the first difference SN1 and the operation value SN2′ of the second difference SN2 are changed in a stepwise manner, as described below. The predetermined threshold value Vt is set in advance in a state in which the first difference SN1 is not yet saturated in the photoresponsive characteristic and the photoresponsive characteristic is in the linear area, as described above.

In the case of SN1<SN1×0.90, SN=SN1

In the case of Vt×0.90≦SN1<Vt×0.94, SN=0.9×SN1+0.1×SN2′

In the case of Vt×0.94≦SN1<Vt×0.98, SN=0.7×SN1+0.3×SN2′

In the case of Vt×0.98≦SN1<Vt×1.02, SN=0.5×SN1+0.5×SN2′

In the case of Vt×1.02≦SN1<Vt×1.06, SN=0.3×SN1+0.7×SN2′

In the case of Vt×1.06≦SN1<Vt×1.10, SN=0.1×SN1+0.9×SN2′

In the case of Vt×1.10≦SN1, SN=SN2′

By executing the operation processing described above, the signal can be smoothly switched from the signal at the low illuminance to the signal at the high illuminance.

### 5. Structure Example of Second Charge Storage Unit 67

### First Embodiment

Some structure examples of the second charge storage unit 67 have been described with reference to FIGS. 5A to 7B. Hereinafter, a method of providing the second charge storage unit 67 in a unit pixel without decreasing an area of the photodiode 61 will be described.

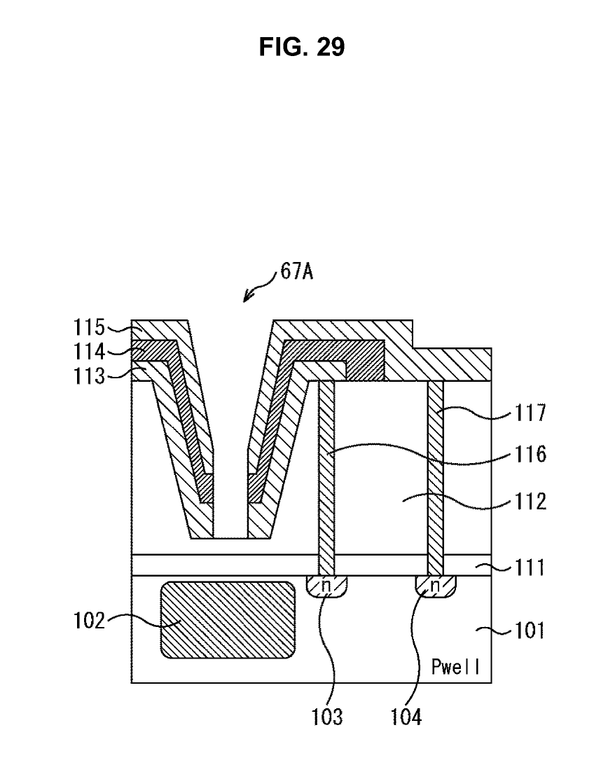

FIG. 29 is a schematic diagram illustrating an example of a cross-sectional structure of the second charge storage unit 67.

On a surface layer of a P-type semiconductor region 101 corresponding to the P-type well 52 of FIG. 5, a photoelectric conversion layer 102 corresponding to the photodiode 61 of FIGS. 8 and 9 and N-type semiconductor regions 103 and 104 are formed. A reflection prevention film 111 is formed on a surface of the P-type semiconductor region 101. An interlayer film 112 is formed on the reflection prevention film 111. The interlayer film 112 is formed by using a low dielectric film (Low-k) such as SiLK or various oxide films.

Above the photoelectric conversion layer 102, a groove having a shape in which a truncated cone is reversed is formed as a waveguide to guide light to the photoelectric conversion layer 102 in the interlayer film 112. A capacitor (second charge storage unit 67A) including a lower electrode 113, a capacity film 114, and an upper electrode 115 is formed along a sidewall of the waveguide. Openings that have almost the same shapes as an upper end and a lower end of the waveguide are formed in an upper end and a lower end of the second charge storage unit 67A and a peripheral portion of the opening of the upper end expands in a flange shape on the interlayer film 112.

The lower electrode 113 and the upper electrode 115 are formed of metal films made of W, Al, Ti, and TiN or a stacked film thereof. The capacity film 114 is formed of a high dielectric film (High-k) including titanium oxide, hafnium oxide, aluminum oxide, and zirconium oxide, a Si oxide film, a Si nitride film, and a stacked film thereof.

The lower electrode 113 is connected to the N-type semiconductor region 103 through a wiring line 116 and the upper electrode 115 is connected to the N-type semiconductor region 104 through a wiring line 117. One of the N-type semiconductor region 103 and the N-type semiconductor region 104 is connected to a power supply (not illustrated in the drawings) and the other is connected to a ground (not illustrated in the drawings).

As such, the second charge storage unit 67A is formed on a path along which light is incident on the photoelectric conversion layer 102, so that an area of the photoelectric conversion layer 102 can be increased. As a result, a dynamic range can be suppressed from being narrowed due to provision of the second charge storage unit 67A.

The second charge storage unit 67A is formed along the sidewall of the waveguide so that the second charge storage unit 67A (upper electrode 115) functions as the waveguide. As a result, light that is incident on the opening of the upper portion of the second charge storage unit 67A can be surely incident on the photoelectric conversion layer 102 and light reception sensitivity can be improved. In addition, optical noise components such as stray light and a mixed color can be suppressed.

It is not necessary to form the second charge storage unit 67A to cover the entire sidewall of the waveguide and the second charge storage unit 67A may be formed to cover a part of the sidewall. For example, in a sidewall portion of the waveguide, it is not necessary to form the lower electrode 113, the capacity film 114, and the upper electrode 115 in a cylindrical shape and the lower electrode 113, the capacity film 114, and the upper electrode 115 may be formed in a shape in which a part of a cylinder is notched.

A transparent electrode material such as indium tin oxide (ITO) or zinc oxide (ZnO) may be used in the lower electrode 113 and the upper electrode 115. In this case, it is preferable to set refractive indexes of formation materials of the interlayer film 112, the lower electrode 113, the capacity film 114, and the upper electrode 115, such that light incident on the opening of the upper portion of the second charge storage unit 67A is surely incident on the photoelectric conversion layer 102. For example, it is necessary to set the refractive index of the lower electrode 113 to be higher than the refractive index of the interlayer film 112. In addition, it is preferable to set the refractive index of the upper electrode 115 to be higher than a refractive index of an embedding material (not illustrated in the drawings) of a waveguide structure of the upper layer of the upper electrode 115.

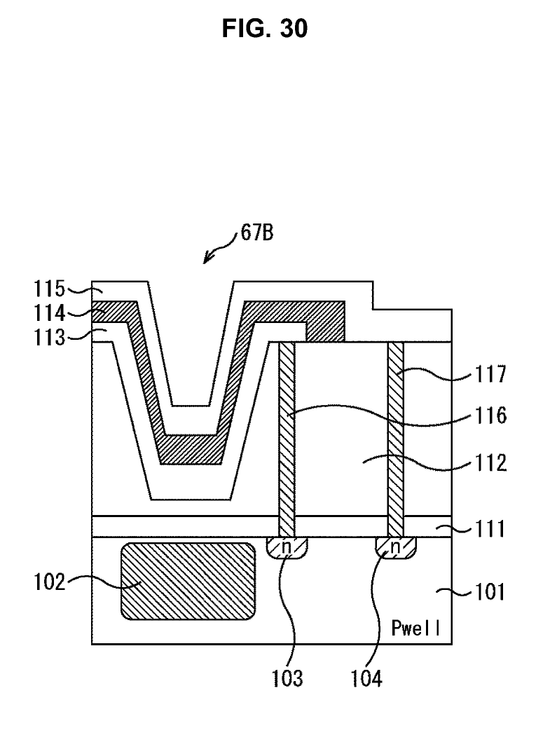

When the transparent electrode material is used in the lower electrode 113 and the upper electrode 115, the upper side of the photoelectric conversion layer 102 can be covered with the lower electrode 113, the capacity film 114, and the upper electrode 115 without providing an opening in the lower end, like a second charge storage unit 67B of FIG. 30. In the second charge storage unit 67B, a manufacturing process can be simplified and capacity efficiency can be improved, as compared with the second charge storage unit 67A of FIG. 29.

When the transparent electrode material is used in the lower electrode 113 and the upper electrode 115, as illustrated in FIG. 31, the lower electrode 113, the capacity film 114, and the upper electrode 115 can be embedded in the waveguide depending on the transmittance and the refractive index of the transparent electrode material. In a second charge storage unit 67C, a manufacturing process can be simplified, as compared with the second charge storage unit 67B of FIG. 30.

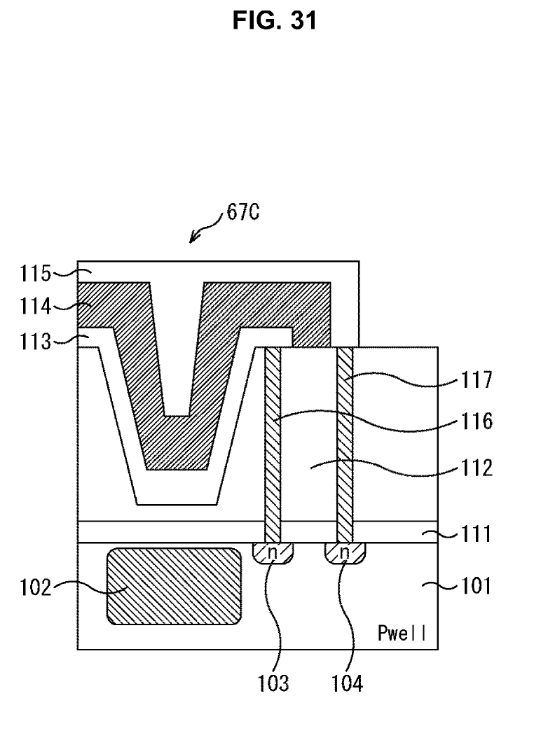

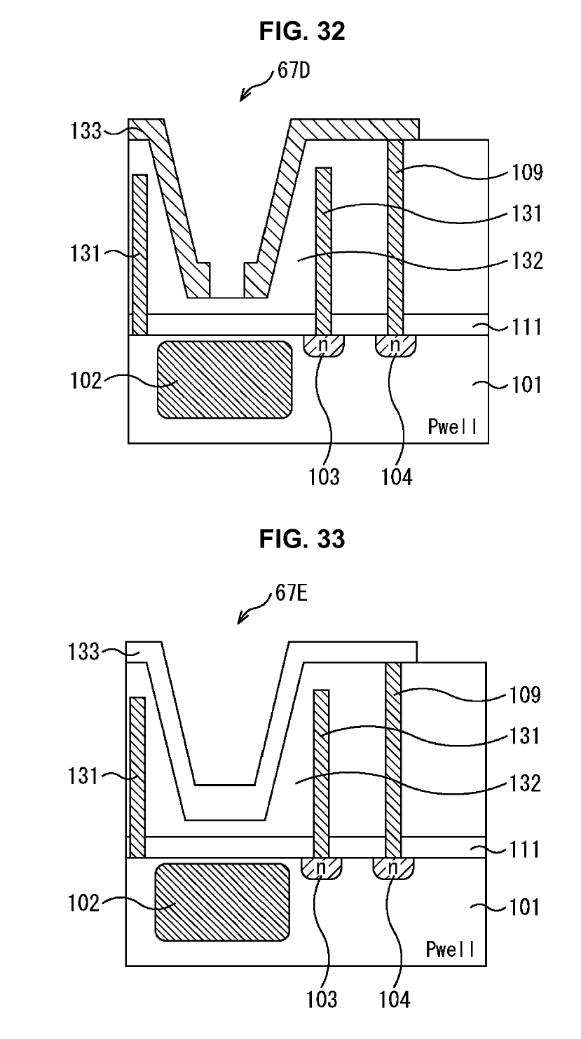

FIG. 32 is a schematic diagram illustrating another example of the cross-sectional structure of the second charge storage unit 67. In FIG. 32, structural elements corresponding to those in FIG. 29 are denoted with the same reference numerals.

In the example of FIG. 32, an interlayer capacity film 132 that functions as an interlayer film between the lower electrode 131 and the upper electrode 133 and a capacity film of a second charge storage unit 67D is formed on an upper layer of the reflection prevention film 111. For example, the interlayer capacity film 132 is formed of a high dielectric film (High-k) including titanium oxide, hafnium oxide, aluminum oxide, and zirconium oxide.

Similar to the interlayer film 112 of FIG. 29, in the interlayer capacity film 132, a groove having a shape in which a truncated cone is reversed is formed as a waveguide above the photoelectric conversion layer 102. The upper electrode 133 is formed along the sidewall of the waveguide. Openings that have almost the same shapes as an upper end and a lower end of the waveguide are formed in an upper end and a lower end of the upper electrode 133 and a peripheral portion of the opening of the upper end expands in a flange shape on the interlayer capacity film 132. The upper electrode 133 is formed of the same material as the upper electrode 115 of FIG. 29.

A cylindrical lower electrode 131 is formed to surround a peripheral portion of a top surface (light reception surface) of the photoelectric conversion layer 102 and a portion other than an upper end of the sidewall of the waveguide. The lower electrode 131 is formed of the same wiring material as a wiring line 109.

The lower electrode 131 is connected directly to the N-type semiconductor region 103 and the upper electrode 133 is connected to the N-type semiconductor region 104 through the wiring line 109.

Thereby, a capacitor (second charge storage unit 67D) including the lower electrode 131, the interlayer capacity film 132, and the upper electrode 133 is formed.

As such, the second charge storage unit 67D is formed on a path along which light is incident on the photoelectric conversion layer 102, so that an area of the photoelectric conversion layer 102 can be increased. As a result, a dynamic range can be suppressed from being narrowed due to provision of the second charge storage unit 67D.

The upper electrode 133 is formed along the sidewall of the waveguide so that the upper electrode 133 functions as the waveguide. As a result, light that is incident on the opening of the upper portion of the second charge storage unit 67D can be surely incident on the photoelectric conversion layer 102 and light reception sensitivity can be improved. In addition, optical noise components such as stray light and a mixed color can be suppressed.

As compared with the second charge storage units 67A to 67C described above, in the second charge storage unit 67D, because the layers of the lower electrode and the capacity film can be omitted, a manufacturing process can be simplified.

It is not necessary to form the upper electrode 133 to cover the entire sidewall of the waveguide and the upper electrode 133 may be formed to cover only a part of the sidewall. For example, in a sidewall portion of the waveguide, it is not necessary to form the upper electrode 133 in a cylindrical shape and the upper electrode 133 may be formed in a shape in which a part of a cylinder is notched.

Likewise, it is not necessary to form the lower electrode 131 to surround an entire peripheral portion of the light reception surface of the photoelectric conversion layer 102. For example, the lower electrode 131 may be formed to surround a part of the peripheral portion of the light reception surface of the photoelectric conversion layer 102.

A transparent electrode material such as indium tin oxide (ITO) or zinc oxide (ZnO) may be used in the upper electrode 133. In this case, it is preferable to set refractive indexes of formation materials of the interlayer capacity film 132 and the upper electrode 115, such that light incident on the opening of the upper portion of the second charge storage unit 67D is surely incident on the photoelectric conversion layer 102.

When the transparent electrode material is used in the upper electrode 133, the upper side of the photoelectric conversion layer 102 can be covered with the upper electrode 133 without providing an opening in the lower end of the upper electrode 133, like the second charge storage unit 67E of FIG. 33. In the second charge storage unit 67E, a manufacturing process can be simplified, as compared with the second charge storage unit 67D of FIG. 32.

### Second Embodiment

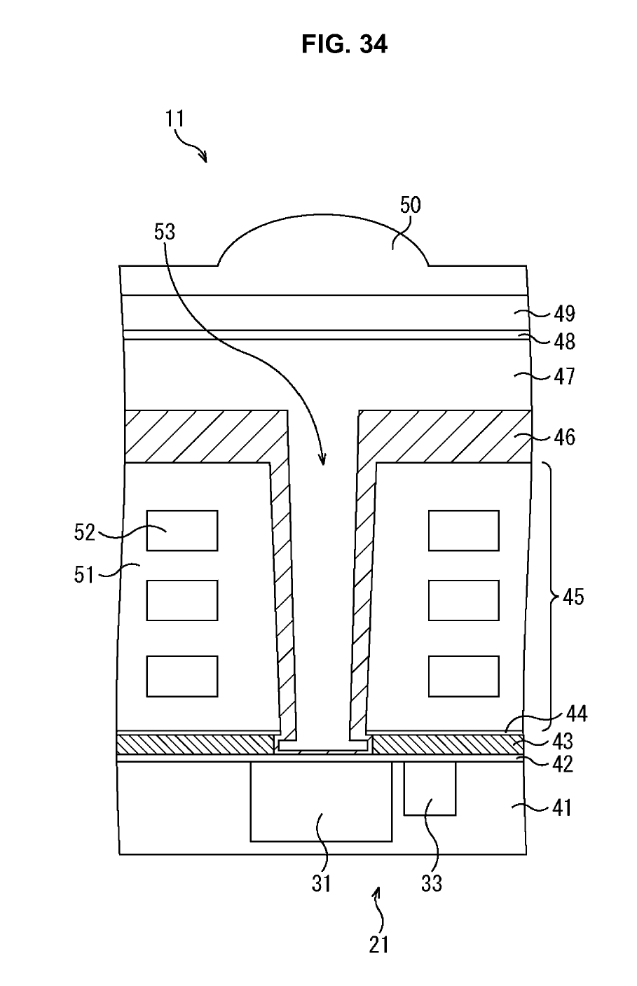

Next, an example of a cross-sectional structure of an image sensor 11 will be described with reference to FIG. 34.

FIG. 34 illustrates a cross-section of a peripheral portion of one pixel 21 of the image sensor 11. Light is radiated from the upper side of FIG. 34 to the image sensor 11. The image sensor 11 has a structure in which a base insulating film 42, a metal light shielding film 43, a reflection prevention film 44, a wiring layer 45, a passivation film 46, a light transmitting embedding film 47, a flattening film 48, a color filter layer 49, and an on-chip lens layer 50 are stacked with respect to a semiconductor substrate 41 in which a PD 31 and a memory unit 33 forming the pixel 21 are formed.

The semiconductor substrate 41 has a structure in which a second conductive well (P well) is formed with respect to a first conductive (for example, N-type) substrate and a first conductive impurity region (N-type region) forming the PD 31 is formed for each pixel 21 with respect to the P well. In the semiconductor substrate 41, the first conductive impurity region (N-type region) forming the memory unit 33 is formed at a position apart from the PD 31 by a predetermined interval, for each pixel 21 with respect to the P well.

The base insulating film 42 is an insulating film such as a silicon oxide film (SiO₂) and is formed directly on a surface of the semiconductor substrate 41.

The metal light shielding film 43 is a film that is formed of a light shielding metal such as silicide, tungsten (W), copper (Cu), aluminum (Al), cobalt (Co), and titanium (Ti) and is formed on an upper side (light radiation side) of the semiconductor substrate 41. The metal light shielding film 43 covers the semiconductor substrate 41, such that a location corresponding to the PD 31 is opened and the other locations are shielded from light. Thereby, the metal light shielding film 43 prevents electrons from being generated in the memory unit 33 and the vicinity of the memory unit 33 and prevents the electrons from moving to the memory unit 33.

The reflection prevention film 44 is a film that is formed of silicon nitride (Si₃N₄) and prevents light incident on the image sensor 11 from being reflected by the metal light shielding film 43. The image sensor 11 may adopt a structure in which the reflection prevention film 44 is not formed.

The wiring layer 45 is formed on an upper side (light radiation side) of the metal light shielding film 43 and is configured by arranging the wiring lines 52 connected to the pixel driving lines 16 of FIG. 1 to become a plurality of layers, in the interlayer insulating film 51.

In this case, in the metal light shielding film 43, the reflection prevention film 44, and the wiring layer 45, an opening portion 53 to provide an optical waveguide to transmit light incident from the side of the surface of the image sensor 11 to the PD 31 is formed. The opening portion 53 is formed in a tapered shape, such that an inner diameter thereof slightly decreases from the side of the surface of the image sensor 11 to the semiconductor substrate 41. As will be described below with reference to FIG. 36, the opening portion 53 is formed such that an inner diameter of an opening formed in the metal light shielding film 43 becomes larger than an inner diameter of an opening right above the metal light shielding film 43 (for example, inner diameter of an opening in a lower end face of the reflection prevention film 44) by a predetermined interval.

The passivation film 46 is formed to cover a surface of the wiring layer 45 and an inside surface and a bottom surface of the opening portion 53. For example, the passivation film 46 is configured using a light transmitting layer that is formed by a chemical vapor deposition (CVD) method or a sputtering method and is made of silicon nitride having a high refractive index. As such, a material having low permeability such as the silicon nitride is formed, so that moisture is prevented from being infiltrated from the opening of the optical waveguide to the interlayer insulating film 51 and element reliability can be raised.

The light transmitting embedding film 47 is formed to be embedded in the opening portion 53 in which the passivation film 46 is formed and to be stacked on a surface of the passivation film 46. For example, in the light transmitting embedding film 47, a material having high optical transmittance such as silicon carbon nitride (SiCN) silicon oxide nitride (SiON) silicon carbide (SiC), silicon oxide nitride (SiON), silicon nitride (SiN), an acrylic or fluorinated polymer, siloxane of an organosilicon polymer, and polyarylene (PAr) is used. From a viewpoint of an embedding property, it is preferable to use a resin (organic) material.

Therefore, in the opening portion 53, the passivation film 46 and the light transmitting embedding film 47 are formed to become a two-layered structure in which the light transmitting embedding film 47 is configured as a core material and the passivation film 46 surrounds outer circumference of a side of the light transmitting embedding film 47. In the light transmitting embedding film 47, a material having a refractive index lower than a refractive index of the passivation film 46 is used. By the difference of the refractive indexes, in the opening portion 53, an optical waveguide that efficiently transmits light incident on the image sensor 11 to the PD 31 is configured. The difference of the refractive indexes is not set between the light transmitting embedding film 47 and the passivation film 46, the two layers of the light transmitting embedding film 47 and the passivation film 46 may be configured as the core layer, and an optical waveguide may be configured by the difference of the refractive indexes with the interlayer insulating film 51 having the low refractive index as compared with the two layers.

The flattening film 48 is a film to flatten a surface to stack the color filter layer 49 with respect to the light transmitting embedding film 47. The color filter layer 49 has a structure in which a filter transmitting light of each color is arranged for each pixel 21, to make the PD 31 receive light of a predetermined color for each pixel 21. The on-chip lens layer 50 has a structure in which a small lens to condense light radiated to the image sensor 11 is formed for each pixel 21.

As such, the image sensor 11 is configured and the light that is radiated to the image sensor 11 is condensed by the lens formed in the on-chip lens layer 50, transmits the color filter layer 49, passes through the optical waveguide formed by the passivation film 46 and the light transmitting embedding film 47 in the opening portion 53, and is received by the PD 31.

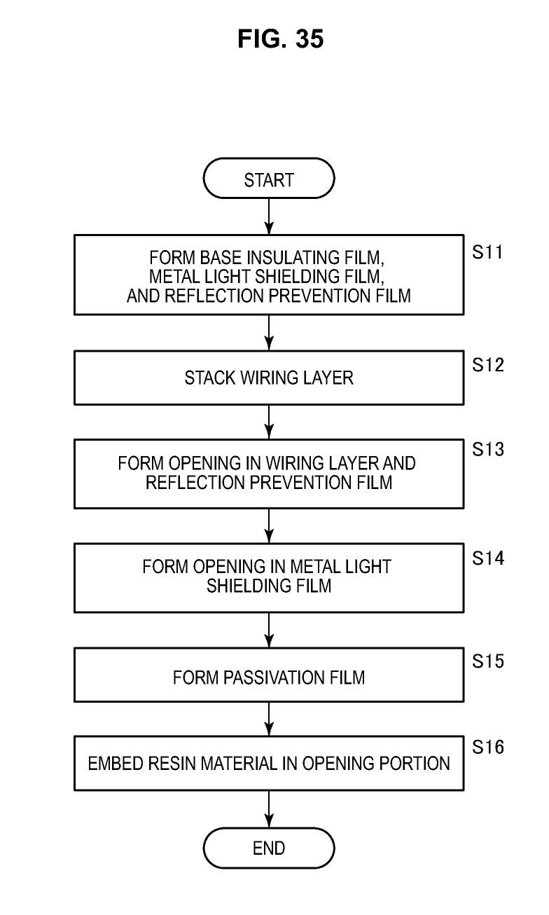

Next, a method of manufacturing the image sensor 11 will be described with reference to a flowchart of FIG. 35.

First, in step S11, the base insulating film 42, the metal light shielding film 43, and the reflection prevention film 44 are formed sequentially on the entire surface of the semiconductor substrate 41 in which the PD 31 and the memory unit 33 are formed, by ion-implanting impurities.

In step S12, the wiring layer 45 is stacked with respect to the reflection prevention film 44. That is, processing for forming the interlayer insulating film 51 with a predetermined thickness and forming the patterned wiring line 52 on the surface of the interlayer insulating film 51 is repeated many times and the wiring layer 45 in which the wiring lines 52 of the plurality of layers are arranged between the interlayer insulating films 51 is formed.

In steps S13 and S14, the opening portion 53 is formed.

First, in step S13, the metal light shielding film 43 is used as an etching stopper and an opening is formed by performing dry etching on the interlayer insulating film 51 of the wiring layer 45 and the reflection prevention film 44, at a position corresponding to a place where the PD 31 is formed.

Next, in step S14, a portion until the base insulating film 42 right above the PD 31 is opened by etching the metal light shielding film 43, by self-alignment using the opening formed in the interlayer insulating film 51 of the wiring layer 45 and the reflection prevention film 44, and the opening portion 53 is formed. At this time, overetching is performed such that the opening of the metal light shielding film 43 retreats more than a lower end of the opening formed in the interlayer insulating film 51 and the reflection prevention film 44.

As illustrated in FIG. 36, the opening portion 53 is formed such that an inner diameter of the opening formed in the metal light shielding film 43 becomes larger than an inner diameter of the opening right above the metal light shielding film 43 (for example, inner diameter of the wiring layer 45 or the reflection prevention film 44 in a lower end face). That is, when the metal light shielding film 43 is opened, processing is executed such that the opening of the metal light shielding film 43 expands in a radial direction more by a predetermined interval W than the opening right above the metal light shielding film 43. The opening of the metal light shielding film 43 is formed to be included in a region in which the PD 31 is formed.

In step S15, the passivation film 46 is formed to cover an inside surface of the opening portion 53. Then, in step S16, the light transmitting embedding film 47 is embedded in the opening portion 53 in which the passivation film 46 is formed. Thereby, the optical waveguide including the passivation film 46 and the light transmitting embedding film 47 is formed in the opening portion 53.

Then, the flattening film 48, the color filter layer 49, and the on-chip lens layer 50 are formed and the image sensor 11 is manufactured.

As described above, in the image sensor 11, after the interlayer insulating film 51 and the reflection prevention film 44 are opened (step S13), the metal light shielding film 43 is opened by performing etching by self-alignment using the opening (step S14). For this reason, the optical waveguide that transmits light to the PD 31 can be surely formed without generating a situation in which the position of the opening formed in the metal light shielding film 43 is not aligned with the position of the opening formed thereon.

After the interlayer insulating film 51 of the wiring layer 45, the reflection prevention film 44, and the metal light shielding film 43 are opened, the opening of the metal light shielding film 43 may be retreated by performing lateral etching additionally with respect to the metal light shielding film 43. The opening of the metal light shielding film 43 may be retreated by isotropic dry etching or wet etching.

In the image sensor 11, an optical distance is set between the optical waveguide of the upper side of the metal light shielding film 43 and the metal light shielding film 43, by processing for making the inner diameter of the opening formed in the metal light shielding film 43 become larger than the inner diameter of the opening right above the metal light shielding film 43 (step S14). That is, by setting the interval W illustrated in FIG. 36, leak light of the light having passed through the optical waveguide can be suppressed from being reflected or absorbed by the metal light shielding film 43. Thereby, loss of light that is incident on the image sensor 11 can be suppressed. As a result, a sensitivity property of the image sensor 11 can be improved and high sensitivity can be realized.

For example, loss of optical energy in the optical waveguide will be described with reference to FIG. 37.

FIG. 37 illustrates a result that is obtained by calculating an optical energy distribution of a depth direction (Z direction) right above the metal light shielding film 43 with respect to a structure model of the optical waveguide configured as illustrated in FIG. 34, using a finite difference time domain method (FDTD) method. FIG. 37 illustrates a refractive index right above the metal light shielding film 43 in the optical waveguide configured as illustrated in FIG. 34.

In FIG. 37, a horizontal axis shows a difference [nm] with a center of an optical waveguide in a YZ cross-section of the image sensor 11, as an observation position of an optical energy distribution. A left vertical axis shows a pointing vector Sz [a.u.] in which a physical amount showing a density of a flow of energy of an electromagnetic field is standardized and a right vertical axis shows a refractive index.

As described with reference to FIG. 34, the optical waveguide of the image sensor 11 is formed by using the light transmitting embedding film 47 as an optical waveguide core material and using the passivation film 46 as a waveguide sidewall to surround outer circumference of a side of the light transmitting embedding film 47. Therefore, if the refractive index of the light transmitting embedding film 47 is set to nc and the refractive index of the passivation film 46 is set to np, as illustrated in FIG. 37, a region that has the refractive index np higher than the refractive index nc is provided outside a region having the refractive index nc. A region that is closer to the outside than the passivation film 46 becomes a region in which light is shielded by the metal light shielding film 43. For example, the refractive index of the interlayer insulating film 51 is shown.

As shown by the pointing vector Sz of FIG. 37, an optical energy distribution right above the metal light shielding film 43 is calculated and optical energy corresponding to tailing is reflected or absorbed by the metal light shielding film 43 and is lost.

Therefore, the region in which the optical energy is lost by the metal light shielding film 43 is reduced, that is, the interval W is set by retreating the metal light shielding film 43 when the optical waveguide is formed, so that the optical energy can be suppressed from decreasing.

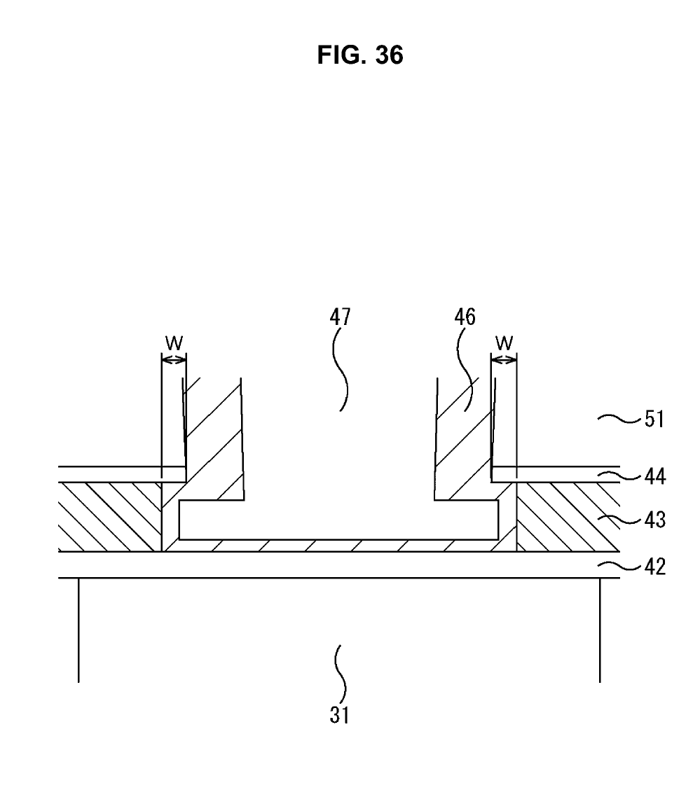

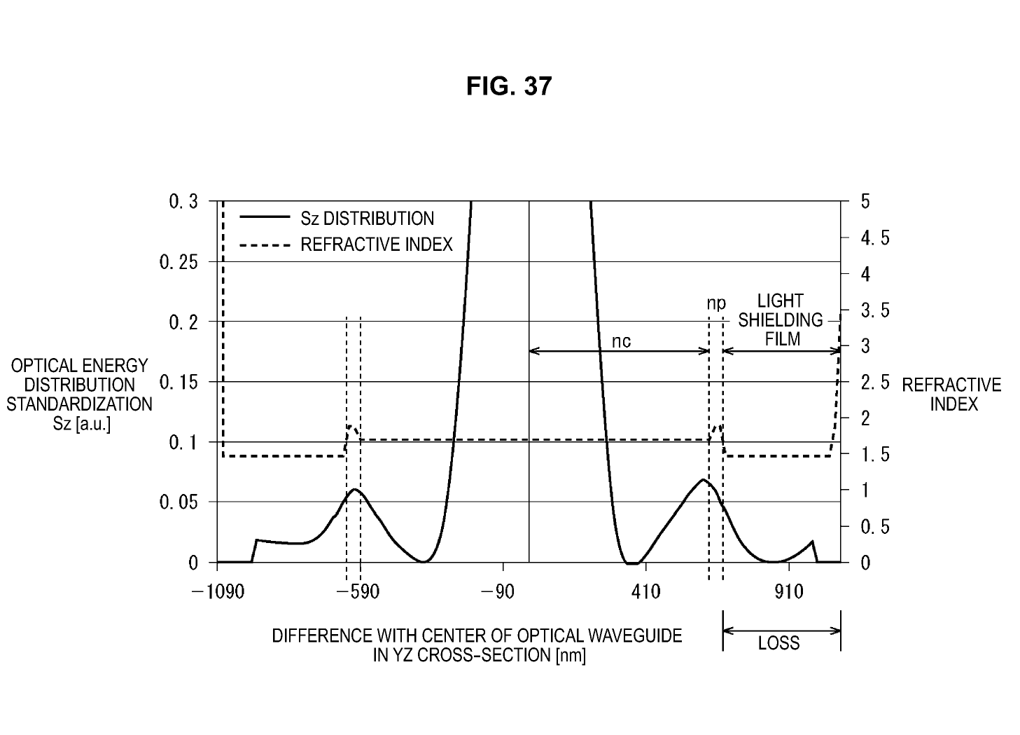

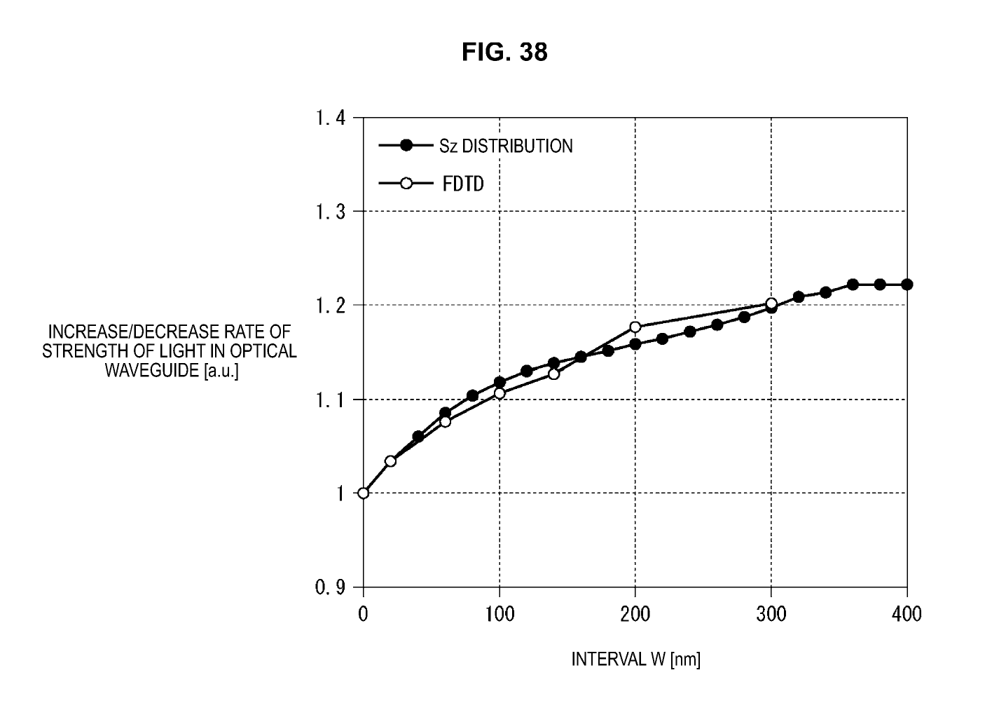

Next, a relation of the strength of the light in the optical waveguide and the interval W will be described with reference to FIG. 38.

In FIG. 38, a vertical axis shows a standardized value [a.u.] of an increase/decrease rate of the strength of the light in the optical waveguide and a horizontal axis shows an interval W of the inner diameter of the opening of the metal light shielding film 43 with respect to the inner diameter of the opening right above the metal light shielding film 43.

FIG. 38 illustrates a change () of the strength of the light calculated by integrating the distribution of the pointing vector Sz illustrated in FIG. 36 and a change (◯) of the strength of the light calculated by an FDTD method. When the strength of the light is calculated by integrating the distribution of the pointing vector Sz, an integration region is increased to correspond to an increase of the interval W (retreat amount of the metal light shielding film 43).

As illustrated in FIG. 38, the strengths of the light calculated by the two methods are improved according to the increase of the interval W retreating the opening of the metal light shielding film 43. Thereby, the variation of the sensitivity of the PD 31 may be called loss by the metal light shielding film 43. As such, the loss of the light that is incident on the image sensor 11 can be suppressed by setting the interval W. For this reason, the sensitivity of the image sensor 11 can be improved.

In the related art, a method of forming a silicon oxide film having a refractive index lower than a refractive index of a waveguide core material by an anisotropic process before forming a silicon nitride film becoming the waveguide core material, confining light in the optical waveguide by the difference of the refractive indexes, and suppressing the light having passed through the optical waveguide from leaking into the metal light shielding film has been used. However, in the method according to the related art to prevent the light leak by the metal light shielding film, because the silicon oxide film should be formed before the core material is embedded, the silicon oxide film is formed on the PD when the silicon oxide film is formed.

Therefore, in the structure according to the related art, the oxide film is additionally formed on the PD and the reflectance of the light increases. As a result, the sensitivity is deteriorated. In addition, it is concerned about ripples becoming worse. If an aspect ratio of the shape of the optical waveguide increases (optical waveguide having the height), coverage of the silicon oxide film becomes worse. For this reason, if a sidewall film having the thickness sufficient to suppress the light leak is formed, the opening of the optical waveguide may be embedded and it becomes difficult to obtain an effect of the original optical waveguide.

Meanwhile, in the image sensor 11, it is not necessary to additionally form a layer having a low refractive index to the optical waveguide, by adopting the structure of the optical waveguide illustrated in FIG. 34. Therefore, an extra film can be avoided from being formed on the PD 31. Thereby, in the image sensor 11, the reflectance can be decreased as compared with the structure according to the related art in which the extra film is formed and the deterioration of the sensitivity or generation of the ripple can be avoided. As such, because the image sensor 11 can avoid the sensitivity from being deteriorated, the image sensor 11 is effective to a structure in which an aspect ratio of the optical waveguide increases, like the CMOS image sensor, or a miniaturized structure. That is, the structure of the optical waveguide of the image sensor 11 is an important structure from a viewpoint of improvement of the sensitivity.

In the optical waveguide of the image sensor 11, a structure in which a dielectric medium having a refractive index lower than a refractive index of the light transmitting embedding film 47 is provided in a region obtained by forming the opening formed in the metal light shielding film 43 to expand in a radial direction more by a predetermined interval W than the opening right above the metal light shielding film 43 may be adopted.

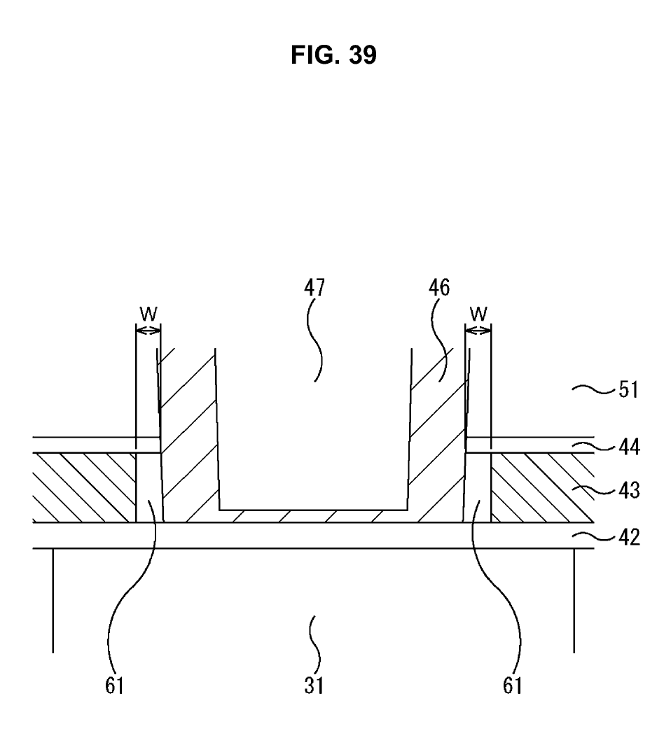

That is, as illustrated in FIG. 39, a dielectric medium 61 having a refractive index lower than a refractive index of the light transmitting embedding film 47 can be provided in a region obtained by forming the opening formed in the metal light shielding film 43 to expand. In addition, the region in which the dielectric medium 61 is provided may be configured as a hollow layer. By this structure, the difference of the refractive indexes of the interlayer insulating film 51 and the passivation film 46 can be increased and the light leak can be effectively suppressed.

The image sensor 11 described above can be applied to various electronic apparatuses such as an imaging system such as a digital still camera or a digital video camera, a mobile phone having an imaging function, and other apparatuses having an imaging function.

### Third Embodiment

### Example of Outer Appearance of Image Sensor 1

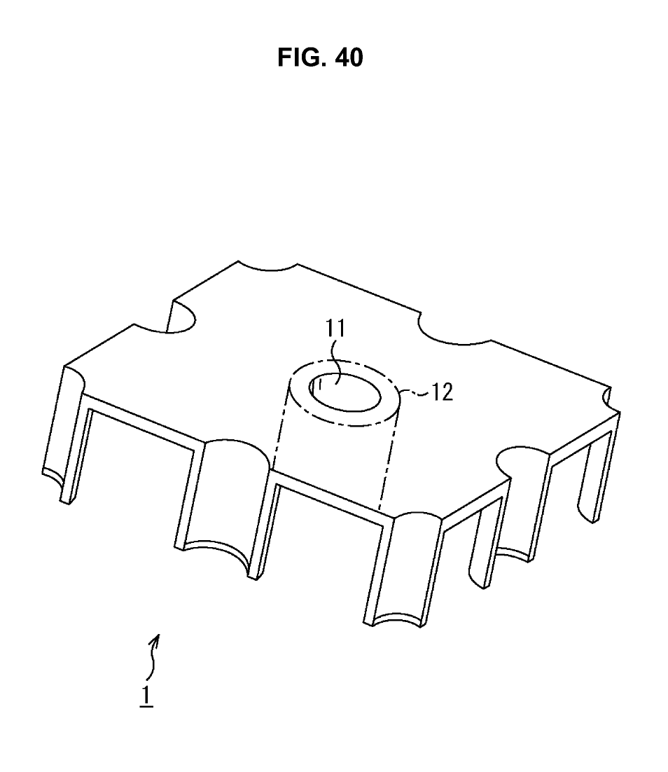

FIG. 40 is a perspective view of an image sensor 1 according to the present disclosure.

The image sensor 1 includes a plurality of pixel units that are arranged in a matrix and each of the pixel units includes a light receiving element that performs photoelectric conversion to convert incident light from the outside into pixel data of one pixel. That is, the image sensor 1 has pixel units by the number of pixels of an imaging image output from the image sensor 1.

As illustrated in FIG. 40, in the image sensor 1, a waveguide 11 to improve condensing efficiency of light incident on a pixel unit and a condensing tube 12 to prevent light leaked from the waveguide 11 from being incident on an adjacent pixel unit are provided for each pixel unit.

In FIG. 40, only any one of the plurality of pixel units arranged in a matrix is illustrated and a wiring line in the pixel unit is omitted, to simplify the drawing.

As the image sensor 1, a solid-state image sensor of a charge coupled device (CCD) type or a complementary metal oxide semiconductor (CMOS) type can be adopted.

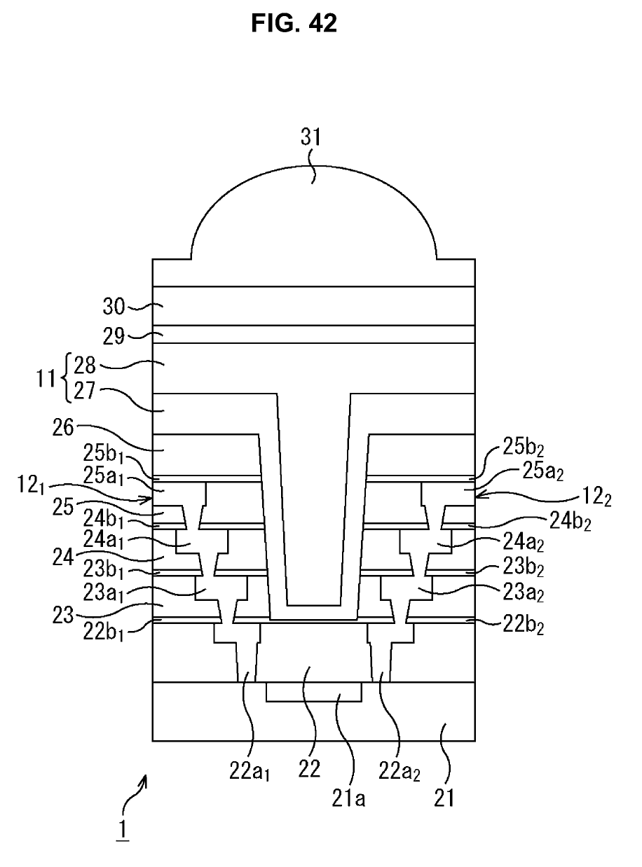

Hereinafter, first and second embodiments of the image sensor 1 that is provided with the waveguide 11 and the condensing tube 12 will be described with reference to FIGS. 42 to 46.

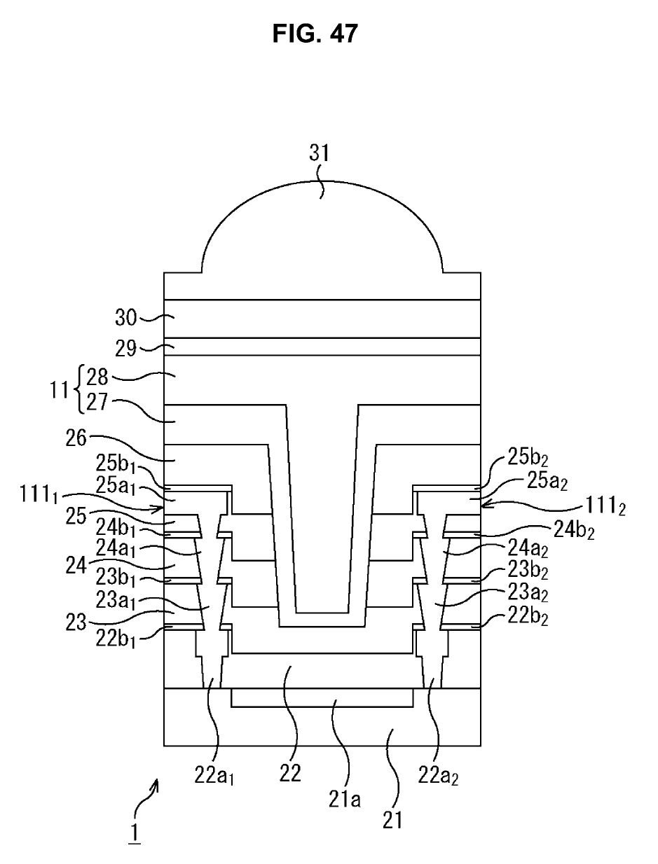

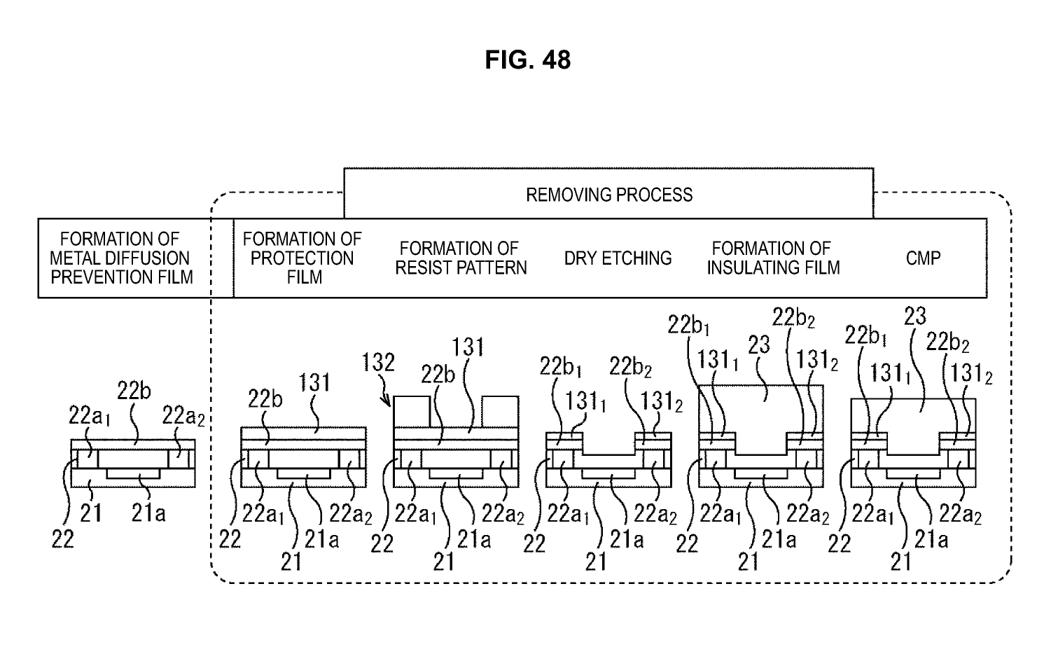

In the image sensor 1, a material having a refractive index equal to a refractive index of a material for forming the waveguide 11 and a material having a refractive index higher than the refractive index of the material for forming the waveguide 11 are removed to suppress light from being leaked from the waveguide 11 through the materials. In the image sensor 1, a metal diffusion prevention film (for example, SiN, SiC, or SiCN) is removed. This will be described as a third embodiment with reference to FIGS. 47 and 48.

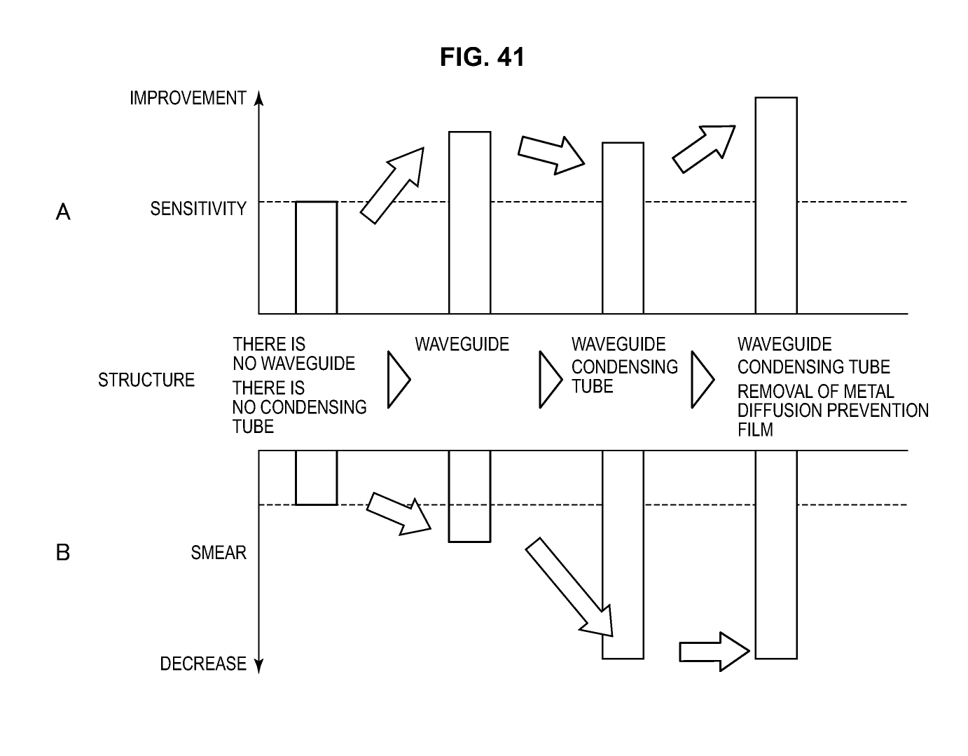

Next, FIGS. 41A and 41B illustrate an example of an aspect where light reception sensitivity of the image sensor 1 is improved by arranging the waveguide 11 and the condensing tube 12 and removing the metal diffusion prevention film and an example of an aspect where smear of an image imaged by the image sensor 11 is decreased, respectively.

FIG. 41A illustrates an example of an aspect where light reception sensitivity of the image sensor 1 is improved.

FIG. 41B illustrates an example of an aspect where smear of an image imaged by the image sensor 11 is improved (decreased). FIG. 41B illustrates only the aspect where the smear is improved. However, in actuality, in addition to the smear, a mixed color, a false color, spectrum abnormality, and a change of a sensitivity ratio are improved.

As such, the smear is improved, so that a signal/noise (S/N) ratio of an imaging image output from the image sensor 1 is improved.

When the waveguide 11 is provided in the image sensor 1, as illustrated in FIG. 41A, condensing efficiency of the image sensor 1 is improved as compared with the case in which the waveguide 11 and the condensing tube 12 are not provided in the image sensor 1. For this reason, light reception sensitivity of the image sensor 1 is also improved. In this case, as illustrated in FIG. 41B, the smear of the image that is imaged by the image sensor 1 is slightly improved.

When the waveguide 11 and the condensing tube 12 are provided in the image sensor 1, as illustrated in FIG. 41A, light reception sensitivity of the image sensor 1 slightly decreases as compared with the case in which only the waveguide 11 is provided in the image sensor 1. However, in this case, as illustrated in FIG. 41B, the smear is greatly decreased by providing the condensing tube 12.

When the waveguide 11 and the condensing tube 12 are provided in the image sensor 11 and the metal diffusion prevention film connected to the waveguide 11 is removed, (most of) light confined in the waveguide 11 is not leaked from the waveguide 11 through the metal diffusion prevention film.

Therefore, the condensing efficiency of the waveguide 11 is improved and as illustrated in FIG. 41A, light reception sensitivity of the image sensor 1 is greatly improved. In this case, as illustrated in FIG. 41B, improvement of the smear is maintained.

### First Embodiment

### Cross-Sectional View of Image Sensor 1

FIG. 42 is a cross-sectional view of an image sensor 1 according to a first embodiment.

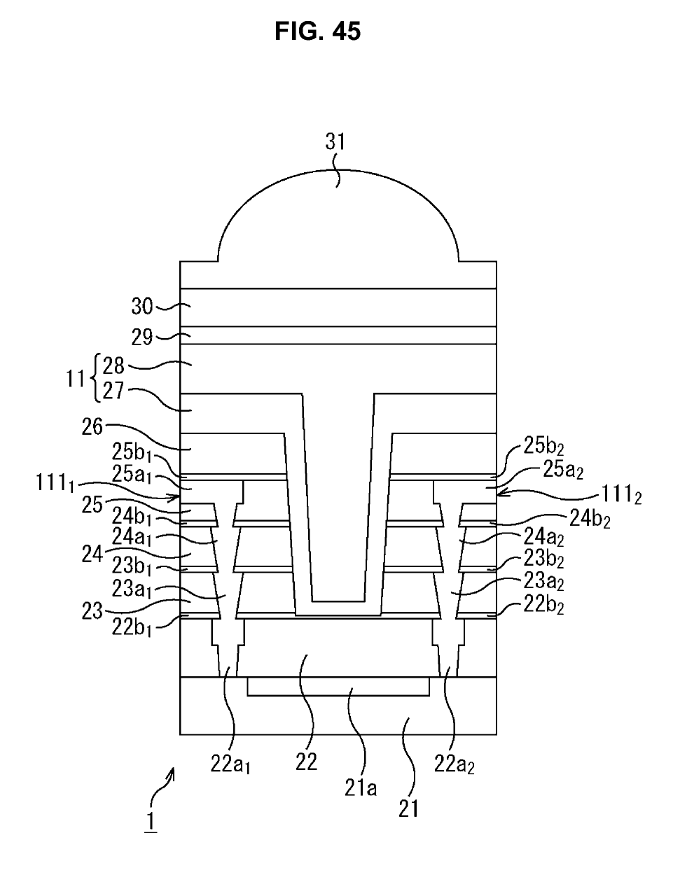

In FIG. 42, one pixel unit is illustrated as the image sensor 1. Therefore, one pixel unit is called the image sensor 1 hereinafter. This is applicable to FIGS. 45 and 47 described below.

The image sensor 1 illustrated in FIG. 42 mainly includes a substrate 21 having a light receiving element 21a, interlayer insulating films 22 to 26, a first refractive layer 27 and a second refractive layer 28 to form the waveguide 11, a flattening film 29, a color filter 30, and a microlens 31.

In FIG. 42, the waveguide 11 is formed using the two materials of the first refractive layer 27 and the second refractive layer 28. However, the present disclosure is not limited thereto. Any structure in which light incident on the waveguide 11 is confined and the light is guided to the light receiving element 21a may be used.

That is, the waveguide 11 may be formed by stacking three or more different materials and may be formed using one material.

Any material that forms the waveguide 11 is a material that has a refractive index higher than a refractive index of the interlayer insulating films 22 to 26.

The light receiving element 21a that receives incident light guided from the waveguide 11 is provided on the substrate 21. The light receiving element 21a performs photoelectric conversion to convert the received incident light into pixel data of one pixel and outputs the pixel data. On the substrate 21, the plurality of interlayer insulating films 22 to 26 are overlapped and formed.

The interlayer insulating film 22 is formed of a material (for example, SiO₂ having a refractive index of 1.4) having a refractive index lower than refractive indexes of the first refractive layer 27 (for example, SiN having a refractive index of 1.9) and the second refractive index 28 (for example, siloxane resin having a refractive index of 1.65) included in the waveguide 11. This is applicable to the interlayer insulating films 23 to 26.

In the interlayer insulating film 22, light shielding metals 22a1 and 22a2 that are formed to penetrate the interlayer insulating film 22 in a vertical direction in FIG. 42 are provided.

Similar to the interlayer insulating film 22, in the interlayer insulating film 23, light shielding metals 23a1 and 23a2 are provided. The light shielding metals 23a1 and 23a2 are connected to the light shielding metals 22a1 and 22a2 of the interlayer insulating film 22, respectively. This is applicable to the interlayer insulating films 24 and 25.

That is, in the interlayer insulating film 24, light shielding metals 24a1 and 24a2 that are connected the light shielding metals 23a1 and 23a2 of the interlayer insulating film 23 are provided. In the interlayer insulating film 25, light shielding metals 25a1 and 25a2 that are connected the light shielding metals 24a1 and 24a2 of the interlayer insulating film 24 are provided.

The light shielding metals 22a1 to 25a1 function as a light shielding wall 121 that forms a portion of the condensing tube 12. The light shielding metals 22a2 to 25a2 function as a light shielding wall 122 that forms the other portion of the condensing tube 12.

As illustrated in FIG. 40, the condensing tube 12 is configured to surround the waveguide 11 and has a columnar shape. The condensing tube 12 may have any shape, as long as the condensing tube 12 is configured to surround the waveguide 11. For example, the condensing tube 12 may have a quadrangular prismatic shape and an octagonal prismatic shape in addition to the columnar shape. When the shape of the condensing tube 12 is the columnar shape, a bottom of a column may be elliptical.

Inn the image sensor 1 illustrated in FIG. 40, the condensing tube 12 is provided. However, instead of the condensing tube 12, a light shielding structure may be formed by the light shielding wall 121 and the light shielding wall 122. That is, in the image sensor 1, the light shielding structure is not limited to only the condensing tube 12.

In FIG. 42, the light shielding wall 121 has a stack structure in which the four light shielding metals 22a1 to 25a1 are overlapped. However, the number of light shielding metals is not limited to four. That is, the light shielding wall 121 is configured using the light shielding metals that penetrate at least two layers or more interlayer insulating films. This is applicable to the light shielding wall 122.

In the light shielding wall 121, the light shielding metals 22a1 to 25a1 may be configured using any material of W, Cu, Al, Ta, TaN, Ti, or TiN or may be configured using a combination of at least two or more materials of W, Cu, Al, Ta, TaN, Ti, or TiN.

In the light shielding wall 121, the light shielding metal 22a1 of the lowermost layer among the light shielding metals 22a1 to 25a1 can be configured using any material of W, Ti, and TiN. The light shielding metal 22a1 of the lowermost layer may be configured using a combination of at least two or more materials of W, Ti, and TiN. This is applicable to the light shielding wall 122.

The light shielding walls 121 and 122 may be configured using any light shielding material and may be configured using a material different from the metal. However, in the first embodiment, the light shielding walls 121 and 122 use the metal as the light shielding material.

When the light shielding walls 121 and 122 are configured using a conductive material (for example, metal), the image sensor 1 of FIG. 42 can use the light shielding walls 121 and 122 as the wiring lines.

The image sensor 1 of FIG. 42 does not use the light shielding walls 121 and 122 as the wiring lines and may use the light shielding walls 121 and 122 exclusively for light shielding. In this case, the light shielding walls 121 and 122 are not electrically connected to a circuit unit to control the light receiving element 21a and are connected to the substrate 21 functioning as a ground (reference potential point), according to necessity.

The ground is not limited to the substrate 21. Therefore, wiring metals may be connected to the light shielding walls 121 and 122, the connected wiring metals may be drawn, and the light shielding walls 121 and 122 may be connected to another ground different from the substrate 21.

In addition, it can be known from experiments performed by the inventors that the thickness (width of a horizontal direction in FIG. 42) of the light shielding walls 121 and 122 is preferably almost 60 nm or more to shield light leaked from the waveguide 11 in the horizontal direction of FIG. 42.

On a surface (upper surface of FIG. 42) of the interlayer insulating film 22, metal diffusion prevention films 22b1 and 22b2 to prevent diffusion of wiring metals configured using Cu are provided. The metal diffusion prevention films 22b1 and 22b2 are configured using SiN, SiC, or SiN. For this reason, the refractive indexes of the metal diffusion prevention films 22b1 and 22b2 are about 1.9 to 2.3 and become refractive indexes that are equal to or higher than 1.9 to be the refractive index of the first refractive layer 27.

On the surface of each of the interlayer insulating films 23 to 25, the same metal diffusion prevention film as the interlayer insulating film 22 is provided.

That is, the metal diffusion prevention films 23b1 and 23b2 are provided on the surface of the interlayer insulating film 23 and the metal diffusion prevention films 24b1 and 24b2 are provided on the surface of the interlayer insulating film 24. The metal diffusion prevention films 25b1 and 25b2 are provided on the surface of the interlayer insulating film 25.

Instead of the metal diffusion prevention film, the first refractive layer 27 of the waveguide 11 is provided on the surface of the interlayer insulating film 26.

The first refractive layer 27 is made of a material having a refractive index higher than a refractive index of the second refractive layer 28, adheres to a concave surface of the first refractive layer 27 and a convex surface of the second refractive layer 28, and forms the waveguide 11.

The waveguide 11 confines (energy of) the light incident on the second refractive layer 28 in the second refractive layer 28 by the difference of the refractive indexes of the first refractive layer 27 and the second refractive layer 28 and confines the light incident on the first refractive layer 27 in the first refractive layer 27 by the difference of the refractive indexes of the first refractive layer 27 and the interlayer insulating films 23 to 26.

That is, the waveguide 11 guides the light incident on the waveguide 11 to the light reception surface of the light receiving element 21a while suppressing the incident light from leaking from the waveguide 11, thereby improving condensing efficiency with respect to the light receiving element 21a.

For this reason, the waveguide 11 can efficiently guide the incident light to the light receiving element 21a. The light that leaks from the waveguide 11 in a horizontal direction of FIG. 42 is shielded by the light shielding walls 121 and 122. The light shielding walls 121 and 122 directly shield the light leaked from the waveguide 11 and the light incident on the interlayer insulating films 22 to 26 and suppress the light from being incident on the adjacent pixel unit.

The light shielding walls 121 and 122 absorb most of the light leaked from the waveguide 11 in the horizontal direction of FIG. 42 without reflecting the light and suppress the light reflected from the light shielding walls 121 and 122 from being incident on the light receiving element 21a.

The light shielding walls 121 and 122 are formed to penetrate two or more interlayer insulating films 22 to 25 including the interlayer insulating film 22 closer to the substrate 21 than (a leading end of a convex portion of) the waveguide 11.

In this case, the light receiving element 21a is arranged in the condensing tube 12 in which the waveguide 11 exists. Outside the condensing tube 12 in which the waveguide 11 does not exist, a circuit unit (not illustrated in the drawings) that includes at least elements of a transistor, a capacitor, and a well tap having reset, selection, amplification, and transmission functions is provided. The circuit unit controls the light receiving element 21a.

The capacitor can have a metal-isolation-semiconductor (MIS) structure or a metal-isolation-metal (MIM) structure. The capacitor can be formed using a high dielectric material (high-k material).

The flattening film 29 is formed on the second refractive layer 28. On the flattening film 29, the color filter 30 is formed.

The color filter 30 transmits any one of components of R, G, and B of light incident from the outside through the microlens 31.

The microlens 31 is a condensing lens made of an acrylic material and has a convex shape at the upper side of FIG. 42. The light that is incident on the microlens 31 is incident on the second refractive layer 28 through the microlens 31, the color filter 30, and the flattening film 29.

Because the incident light guided to the waveguide 11 having relatively superior condensing efficiency is incident on the light receiving element 21a, condensing efficiency of the light that is incident on the light receiving element 21a can be improved.

Because the light leaked from the waveguide 11 is shielded by the condensing tube 12, the light does not reach the circuit unit existing outside the condensing tube 12 or another pixel unit adjacent to the pixel unit illustrated in FIG. 42 as the image sensor 1.

For this reason, the capacitor that is included in the circuit unit can be prevented from storing the charges, by receiving the light leaked from the waveguide 11. Thereby, the circuit unit can be prevented from being erroneously operated, due to the light leaked from the waveguide 11.

Because the light leaked from the waveguide 11 is not incident on another pixel to be adjacent, the smear of the pixel that corresponds to the pixel data output from another pixel unit can be decreased.

The light shielding metal 22a1 that is the lowermost layer of the light shielding wall 121 can be provided to be closer to the waveguide 11 by the predetermined width (for example, 50 nm) than a boundary of the element separation region provided between the light receiving elements 21a of the plurality of pixel units and the light receiving element 21a. This is applicable to the light shielding metal 22a2.

### [Method of Forming Light Shielding Walls 121 and 122]

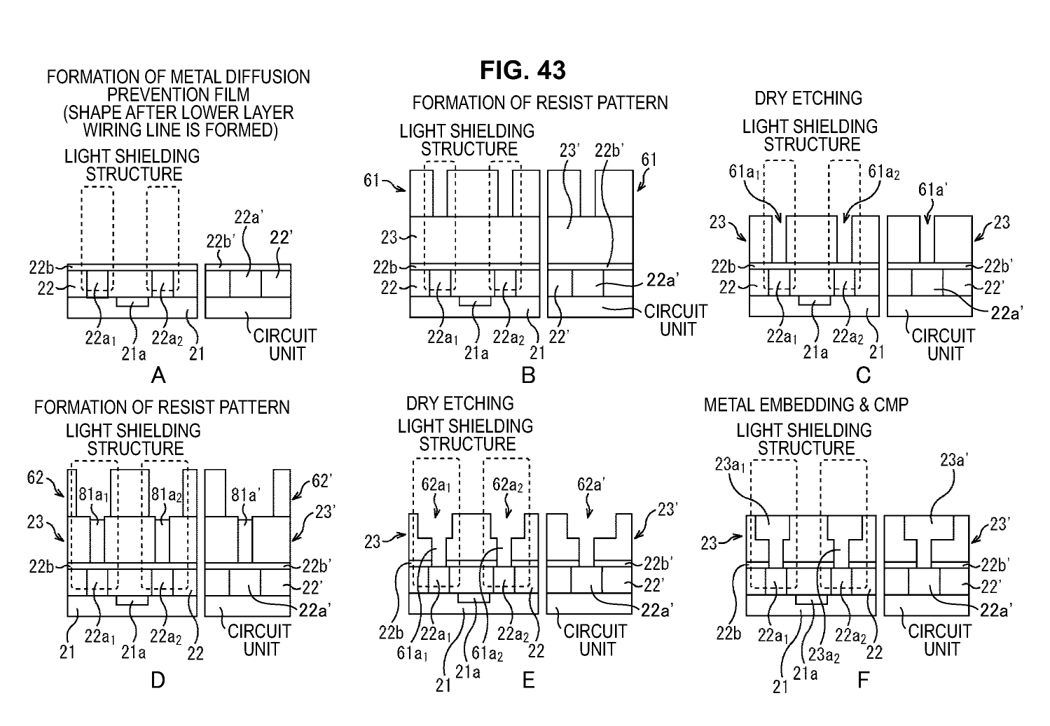

Next, FIGS. 43A, 43B, 43C, 43D, 43E, and 43F illustrate an example of a method of forming the light shielding walls 121 and 122.

The light shielding walls 121 and 122 are formed by a dedicated device.

First, in the substrate 21 having the light receiving element 21a, as illustrated at the left side of FIG. 43A, the metal diffusion prevention film 22b (the metal diffusion prevention films 22b1 and 22b2 in FIG. 42) is formed on the interlayer insulating film 22 provided with the light shielding metals 22a1 and 22a2, using a deposition method such as a chemical vapor deposition (CVD) method.

In this case, the same processing is executed in parallel with respect to a circuit unit illustrated at the right side of FIG. 43A. This is applicable to FIGS. 43B to 43F to be described below. An interlayer insulating film 22′, a wiring metal 22a′, and a metal diffusion prevention film 22b′ of the circuit unit that is illustrated at the right side of FIG. 43A correspond to the interlayer insulating film 22, the light shielding metals 22a1 and 22a2, and the metal diffusion prevention film 22b in the substrate 21.

That is, in the case of FIG. 43A, the metal diffusion prevention film 22b is formed on the interlayer insulating film 22, using the deposition method. At the same time, the metal diffusion prevention film 22b′ is formed on the interlayer insulating film 22′ provided with the wiring metal 22a′.

In FIG. 43A, the metal diffusion prevention film 22b and the metal diffusion prevention film 22b′ are formed as separated metal diffusion prevention films. However, the metal diffusion prevention film 22b and the metal diffusion prevention film 22b′ may be formed as the same metal diffusion prevention film. When the metal diffusion prevention film 22b and the metal diffusion prevention film 22b′ are formed as the same metal diffusion prevention film, the interlayer insulating film 22 and the interlayer insulating film 22′ are also formed as the same interlayer insulating film.

When the metal diffusion prevention film 22b and the metal diffusion prevention film 22b′ are formed as the same metal diffusion prevention film, the metal diffusion prevention film can be formed quickly, as compared with the case in which the metal diffusion prevention film 22b and the metal diffusion prevention film 22b′ are formed as the separated metal diffusion prevention films.

This is applicable to interlayer insulating films 23 and 23′ described with reference to FIG. 43B, resist patterns 61 and 61′ described with reference to FIG. 43B, and resist patterns 62 and 62′ described with reference to FIG. 43D.

After the metal diffusion prevention films 22b and 22b′ are formed, the interlayer insulating film 23 illustrated at the left side of FIG. 43B is formed on the metal diffusion prevention film 22b, using the deposition method such as the CVD method. In addition, the resist pattern 61 illustrated at the left side of FIG. 43B is formed on the interlayer insulating film 23, using a photolithography technique to form patterns.

The same processing is executed in parallel with respect to the circuit unit illustrated at the right side of FIG. 43B. The interlayer insulating film 23′ and the resist pattern 61′ that are illustrated at the right side of FIG. 43B correspond to the interlayer insulating film 23 and the resist pattern 61 illustrated at the left side of FIG. 43B.

That is, in the case of FIG. 43B, the interlayer insulating film 23 is formed on the metal diffusion prevention film 22b, using the deposition method such as the CVD method. At the same time, the interlayer insulating film 23′ is formed on the metal diffusion prevention film 22b′.

The resist pattern 61 is formed on the interlayer insulating film 23, using the photolithography technique. At the same time, the resist pattern 61′ is formed on the interlayer insulating film 23′.

In this case, the resist pattern 61 shows a pattern of via holes 61a1 and 61a2 (left side of FIG. 43C) that are formed in the interlayer insulating film 23. The resist pattern 61′ shows a pattern of a via hole 61a′ (right side of FIG. 43C) that is formed in the interlayer insulating film 23′.

In FIGS. 43B to 43F, the via holes 61a1 and 61a2 and the via hole 61a′ are illustrated to have the same shape. However, the shapes of the via holes 61a1 and 61a2 and the via hole 61a′ are different from each other, in actuality.

This is because the via holes 61a1 and 61a2 are used to embed the light shielding metals 23a1 and 23a2 and the via hole 61a′ is used to embed the wiring metal 23a′ of the circuit unit.

Therefore, the via holes 61a1 and 61a2 have a shape of a groove extending in a normal direction of FIGS. 43A to 43E and the via hole 61a′ has a shape of a hole. In the same manner, trenches 62a1 and 62a2 and a trench 62a′ that are illustrated in FIG. 43E have different shapes depending on the use.

After the resist patterns 61 and 61′ are formed, the via holes 61a1 and 61a2 illustrated at the left side of FIG. 43C are formed in the interlayer insulating film 23 with the pattern of the via hole shown by the resist pattern 61, using a dry etching technique.

The same processing is executed in parallel with respect to the circuit unit. The via hole 61a′ that is illustrated at the right side of FIG. 43C corresponds to the via holes 61a1 and 61a2 illustrated at the left side of FIG. 43C.

That is, in the case of FIG. 43C, the via holes 61a1 and 61a2 are formed in the interlayer insulating film 23 with the pattern of the via hole shown by the resist pattern 61, using the dry etching technique. At the same time, the via hole 61a′ is formed in the interlayer insulating film 23′ with the pattern of the via hole shown by the resist pattern 61′, using the dry etching technique.

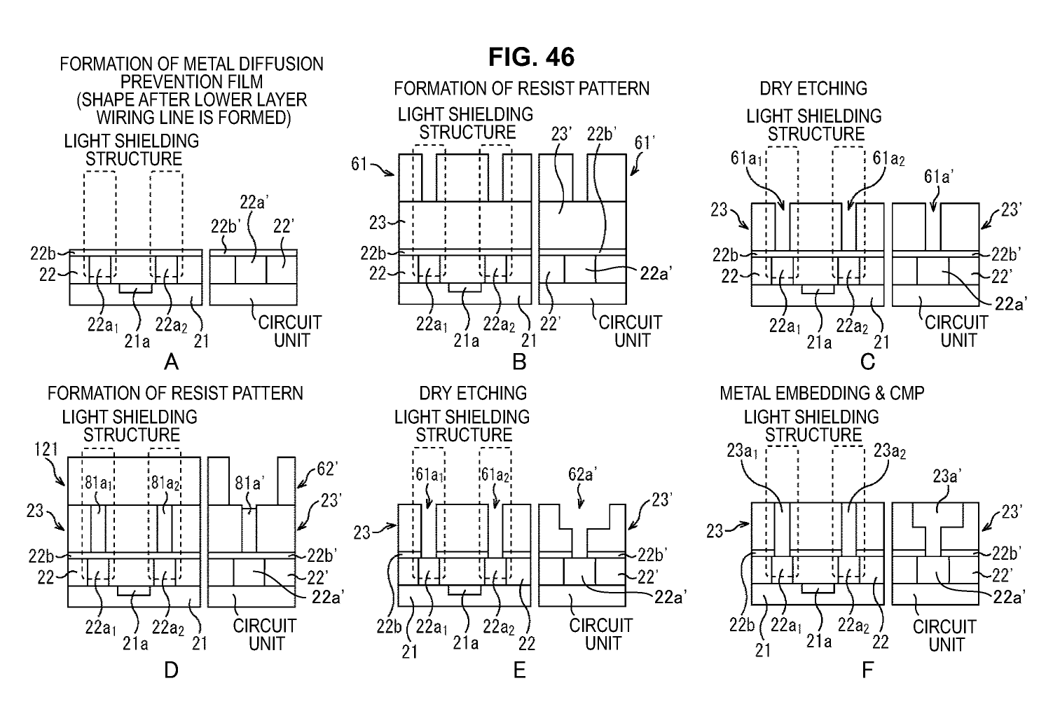

After resins 81a1, 81a2, and 81a′ illustrated in FIG. 43D are applied to the formed via holes 61a1, 61a2, and 61a′, ashing to remove the resist patterns 61 and 61′ is performed and the interlayer insulating films 23 and 23′ after the ashing are cleaned. This is applicable to FIGS. 46A, 46B, 46C, 46D, 46E, and 46F to be described below.

The resist pattern 62 that is illustrated at the left side of FIG. 43D is formed on the interlayer insulating film 23 after the cleaning, using the photolithography technique.

The same processing is executed in parallel with respect to a circuit unit illustrated at the right side of FIG. 43D. The resist pattern 62′ that is illustrated at the right side of FIG. 43D corresponds to the resist pattern 62 illustrated at the left side of FIG. 43D.

That is, in the case of FIG. 43D, the resist pattern 62 is formed on the interlayer insulating film 23, using the photolithography technique. At the same time, the resist pattern 62′ is formed on the interlayer insulating film 23′.

The resist pattern 62 shows a pattern of the trenches 62a1 and 62a2 that are formed in the interlayer insulating film 23. The resist pattern 62′ shows a pattern of the trench 62a′ that is formed in the interlayer insulating film 23′.

After the resist patterns 62 and 62′ are formed, trenches 62a1 and 62a2 illustrated at the left side of FIG. 43E are formed on the via holes 61a1 and 61a2 of the interlayer insulating film 23 with a pattern of the trench shown by the resist pattern 62, using the dry etching technique. The resins 81a1 and 81a2 and the metal diffusion prevention film (a part of the metal diffusion prevention film 22b) formed under the resins 81a1 and 81a2 are removed at any timing after cleaning the interlayer insulating film 23. This is applicable to the resin 81a′.

The same processing is executed in parallel with respect to a circuit unit illustrated at the right side of FIG. 43E. The trench 62a′ that is illustrated at the right side of FIG. 43E corresponds to the trenches 62a1 and 62a2 illustrated at the left side of FIG. 43E.

That is, in the case of FIG. 43E, the trenches 62a1 and 62a2 are formed on the via holes 61a1 and 61a2 of the interlayer insulating film 23 with the pattern of the trench shown by the resist pattern 62, using the dry etching technique. At the same time, the trench 62a′ is formed on the via hole 61′ of the interlayer insulating film 23′ with the pattern of the trench shown by the resist pattern 62′, using the dry etching technique.

After the trenches 62a1, 62a2, and 62a′ are formed, the resist patterns 62 and 62′ are removed by the ashing. This is applicable to FIGS. 46A, 46B, 46C, 46D, 46E, and 46F to be described below.

After the trenches 62a1, 62a2, and 62a′ are formed, as illustrated at the left side of FIG. 43F, the light shielding metal 23a1 is embedded in the via hole 61a1 and the trench 62a1 of the interlayer insulating film 23 and the light shielding metal 23a2 is embedded in the via hole 61a2 and the trench 62a2 of the interlayer insulating film 23.

The same processing is executed in parallel with respect to a circuit unit illustrated at the right side of FIG. 43F. The wiring metal 23a′ that is illustrated at the right side of FIG. 43F corresponds to the light shielding metals 23a1 and 23a2 illustrated at the left side of FIG. 43F.

That is, in the case of FIG. 43F, the light shielding metal 23a1 is embedded in the via hole 61a1 and the trench 62a1 of the interlayer insulating film 23 and the light shielding metal 23a2 is embedded in the via hole 61a2 and the trench 62a2 of the interlayer insulating film 23. At the same time, the wiring metal 23a′ is embedded in the via hole 61a′ and the trench 62a′ of the interlayer insulating film 23′.

The surface (upper surface of FIG. 43F) of the interlayer insulating film 23 in which the light shielding metals 23a1 and 23a2 are embedded and the surface (upper surface of FIG. 43F) of the interlayer insulating film 23′ in which the wiring metal 23a′ is embedded are polished by chemical mechanical polishing (CMP) and are flattened.

Then, in the same manner as the case illustrated in FIG. 43A, the metal diffusion prevention films (the metal diffusion prevention films 23b1 and 23b2 in FIG. 42) are formed on the interlayer insulating film 23 provided with the light shielding metals 23a1 and 23a2. At the same time, the metal diffusion prevention film is formed on the interlayer insulating film 23′ provided with the wiring metal 23a′. Hereafter, the light shielding walls 121 and 122 are formed by repeating the same processing.

In FIG. 43A, 43B, 43C, 43D, 43E, and 43F, the method of forming the trenches 62a1, 62a2, and 62a′ after forming the via holes 61a1, 61a2, and 61a′ is adopted as the method of forming the light shielding walls 121 and 122. However, the method of forming the light shielding walls 121 and 122 is not limited thereto.

For example, a method of forming the via holes 61a1, 61a2, and 61a′ after forming the trenches 62a1, 62a2, and 62a′ can be adopted as the method of forming the light shielding walls 121 and 122.

### [Method of Manufacturing Image Sensor 1 of FIG. 42]

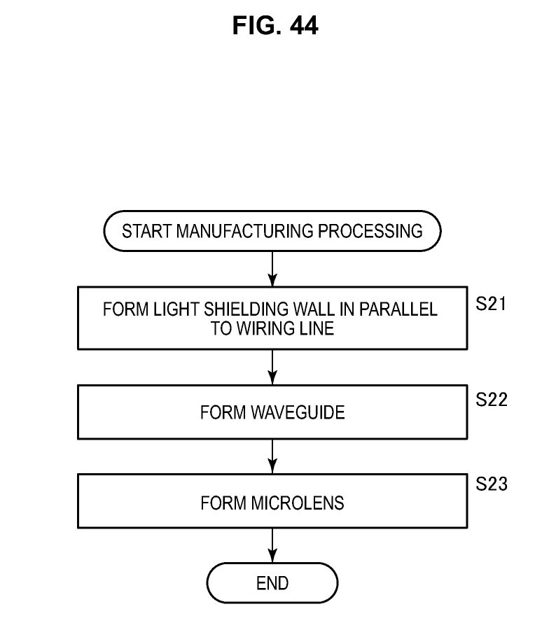

Next, processing for manufacturing the image sensor 1 of FIG. 42 will be described with reference with a flowchart of FIG. 44.

The processing for manufacturing the image sensor 1 of FIG. 42 is executed by one or more dedicated devices to manufacture the image sensor 1 of FIG. 42.

In step S21, the light shielding walls 121 and 122 are formed in the interlayer insulating films 22 to 25, in parallel to the wiring line of the circuit unit.

That is, in the substrate 21, the interlayer insulating film 23 is overlapped and formed on the metal diffusion prevention film 22b of the formed interlayer insulating film 22, using the deposition method.

At the same time, in the circuit unit (refer to FIGS. 43A, 43B, 43C, 43D, 43E, and 43F), the interlayer insulating film 23′ is overlapped and formed on the metal diffusion prevention film 22b′ of the formed interlayer insulating film 22′, using the deposition method.

The interlayer insulating film 22 and the interlayer insulating film 22′ can be formed as the same interlayer insulating film. This is applicable to the interlayer insulating film 23 and the interlayer insulating film 23′.

When the interlayer insulating film 22 and the interlayer insulating film 22′ are formed as the same interlayer insulating film, the metal diffusion prevention film 22b and the metal diffusion prevention film 22b′ can be formed as the same metal diffusion prevention film.

A first groove to embed the light shielding metal 23a1 and a second groove to embed the light shielding metal 23a2 are formed in the formed interlayer insulating film 23, using the dry etching technique.

The first groove includes the via hole 61a1 and the trench 62a1, penetrates the interlayer insulating film 23, and reaches the light shielding metal 22a1 embedded in the interlayer insulating film 22.

The second groove includes the via hole 61a2 and the trench 62a2, penetrates the interlayer insulating film 23, and reaches the light shielding metal 22a2 embedded in the interlayer insulating film 22.

At the same time as formation of the first groove and the second groove, in the circuit unit, a hole to embed the wiring metal 23a′ is formed in the formed interlayer insulating film 23′, using the dry etching technique.

The hole includes the via hole 61a′ and the trench 62a′, penetrates the interlayer insulating film 23′, and reaches the light shielding metal 22a′ embedded in the interlayer insulating film 22′.

At the same time as embedding the light shielding metal 23a1 in the first groove and embedding the light shielding metal 23a2 in the second groove, the wiring metal 23a′ is embedded in the hole.

Then, the surface of the interlayer insulating film 23 in which the light shielding metals 23a1 and 23a2 are embedded and the surface of the interlayer insulating film 23′ in which the wiring metal 23a′ is embedded are polished by the CMP and are flattened.

The metal diffusion prevention films are formed on the flattened interlayer insulating films 23 and 23′ and new interlayer insulating films are overlapped and formed on the interlayer insulating films 23 and 23′ provided with the metal diffusion prevention films. Hereinafter, the same processing is repeated.

Thereby, the light shielding walls 121 and 122 are formed in the stack portion including the plurality of interlayer insulating films (for example, the interlayer insulating films 22 to 25). In the circuit unit, the wiring line of the circuit unit is formed using the wiring metals.

In step S22, the waveguide 11 that is surrounded with the light shielding walls 121 and 122 is formed in the stack portion after the light shielding walls 121 and 122 are formed. That is, the waveguide 11 including the first refractive layer 27 and the second refractive layer 28 is formed in the stack portion by adhering the first refractive layer 27 to the second refractive layer 28.

In step S23, the flattening film 29, the color filter 30, and the microlens 31 are formed in the stack portion provided with the waveguide 11 to manufacture the image sensor 1 and the manufacturing processing ends.

As described above, according to the manufacturing processing, the waveguide 11 is provided and the light shielding walls 121 and 122 to shield the light leaked from the waveguide 11 are formed. For this reason, because condensing efficiency is improved by the waveguide 11, light reception sensitivity of the light receiving element 21a can be improved.

Because the light leaked from the waveguide 11 can be shielded by the light shielding walls 121 and 122, the smear can be improved.

Because most of the light leaked from the waveguide 11 is absorbed by the light shielding walls 121 and 122 without being reflected by the light shielding walls 121 and 122, light reflected from the light shielding walls 121 and 122 can be suppressed from being incident on the light receiving element 21a.

Therefore, an S/N ratio of the imaging image that is output from the image sensor 1 can be improved.

In step S21 of the manufacturing processing, the wiring line of the circuit unit and the light shielding walls 121 and 122 are formed in parallel. For this reason, as compared with the case in which a process (step) of forming the light shielding walls 121 and 122 is executed, separately from the wiring line of the circuit unit, the image sensor 1 can e manufactured more quickly.

### Second Embodiment

### Another Cross-Sectional View of Image Sensor 1

FIG. 45 is a cross-sectional view of an image sensor 1 according to a second embodiment.

In the image sensor 1 of FIG. 45, because the same structural elements as those of the image sensor 1 according to the first embodiment illustrated in FIG. 42 are denoted with the same reference numerals, explanation thereof is appropriately omitted.

That is, the image sensor 1 illustrated in FIG. 45 is the same as the image sensor 1 illustrated in FIG. 42, except that light shielding walls 1111 and 1112 are provided, instead of the light shielding walls 121 and 122 of FIG. 42.

Similar to the light shielding wall 121 of FIG. 42, the light shielding wall 1111 is configured using light shielding metals 22a1 to 25a1. However, the light shielding wall 1111 is formed in a linear shape in a vertical direction of FIG. 45, different from the light shielding wall 121 of FIG. 42. This is applicable to the light shielding wall 1112.

Because the light shielding walls 1111 and 1112 are formed in a linear shape in the vertical direction of FIG. 45, a light reception surface of the light receiving element 21a can be expanded, as compared with the case of using the light shielding walls 121 and 122 of FIG. 42.

### [Method of Forming Light Shielding Walls 1111 and 1112]

Next, FIGS. 46A, 46B, 46C, 46D, 46E, and 46F illustrate an example of a method of forming the light shielding walls 1111 and 1112.

FIGS. 46A to 46C of FIGS. 46A, 46B, 46C, 46D, 46E, and 46F illustrate the same structures as those of FIGS. 43A to 43C.

That is, in the method of forming the light shielding walls 1111 and 1112, processing executed after the via holes 61a1, 61a2, and 62a are formed is different from that in the method of forming the light shielding walls 121 and 122.

In FIGS. 46A to 46C, the same processing as the processing described with reference to FIGS. 43A to 43C is executed. Thereby, as illustrated in FIG. 46C, the via holes 61a1 and 61a2 are formed in the interlayer insulating film 23 and the via hole 61a′ is formed in the interlayer insulating film 23′.

After resins 81a1, 81a2, and 81a′ illustrated in FIG. 46D are applied to the formed via holes 61a1, 61a2, and 61a′, ashing to remove the resist patterns 61 and 61′ is performed and the interlayer insulating films 23 and 23′ after the ashing are cleaned.

Then, the trenches are formed after the resins 81a1, 81a2, and 81a′ are removed. However, when the trenches are formed, in the interlayer insulating film 23 illustrated at the left side of FIG. 46D, a resist pattern 121 that has no pattern is formed.

The structure illustrated in FIG. 46D is the same as the structure illustrated in FIG. 43D, except that the resist pattern 121 is formed, instead of the resist pattern 62 illustrated in FIG. 43D.

That is, in the case of FIG. 46D, the resist pattern 121 is formed on the interlayer insulating film 23, using the photolithography technique. At the same time, the resist pattern 62′ is formed on the interlayer insulating film 23′.

At the left side of FIG. 46D, the resist pattern 121 that has no pattern is formed on the interlayer insulating film 23. This is because the same processing is executed simultaneously with respect to both the substrate 21 and the circuit unit, to perform formation of the light shielding walls 1111 and 1112 and formation of the wiring line of the circuit unit in parallel.

After the resist patterns 121 and 62′ are formed, the trench 62a′ illustrated at the right side of FIG. 46E is formed in the circuit unit, using the dry etching technique. However, a trench is not formed in the interlayer insulating film 23 illustrated at the left side of FIG. 46D.

After the trench 62a′ is formed in the interlayer insulating film 23′ of the circuit unit, ashing to remove the resist patterns 121 and 62′ is performed. As illustrated in FIG. 46F, the light shielding metal 23a1 is embedded in the via hole 61a1 of the interlayer insulating film 23 and the light shielding metal 23a2 is embedded in the via hole 61a2 of the interlayer insulating film 23. At the same time, the wiring metal 23a′ is embedded in the via hole 61a′ and the trench 62a′ of the interlayer insulating film 23′.

The surface (upper surface of FIG. 46F) of the interlayer insulating film 23 in which the light shielding metals 23a1 and 23a2 are embedded and the surface (upper surface of FIG. 46F) of the interlayer insulating film 23′ in which the wiring metal 23a′ is embedded are polished by the CMP and are flattened.

Then, in the same manner as the case illustrated in FIG. 46A, the metal diffusion prevention films (the metal diffusion prevention films 23b1 and 23b2 in FIG. 45) are formed on the interlayer insulating film 23 provided with the light shielding metals 23a1 and 23a2. At the same time, the metal diffusion prevention film is formed on the interlayer insulating film 23′ provided with the wiring metal 23a′. Hereafter, the light shielding walls 1111 and 1112 are formed by repeating the same processing.

### Third Embodiment

### Another Cross-Sectional View of Image Sensor 1

FIG. 47 is a cross-sectional view of an image sensor 1 according to a third embodiment.

The image sensor 1 of FIG. 47 is different from the image sensor 1 of FIG. 45 in that the metal diffusion prevention films 22b1 to 25b1 between the waveguide 11 and the light shielding film 1111 and the metal diffusion prevention films 22b2 to 25b2 between the waveguide 11 and the light shielding wall 1112 are removed.

That is, in the image sensor 1 of FIG. 47, both a material having a refractive index equal to a refractive index of the first refractive layer 27 and a material having a refractive index higher than the refractive index of the first refractive layer 27 do not contact the surface of the first refractive layer 27 in a horizontal direction of FIG. 47.

In the waveguide 11, the refractive index of the first refractive layer 27 is higher than the refractive index of the second refractive layer 28.

Any material other than the material having the refractive index equal to the refractive index of the first refractive layer 27 and the material having the refractive index higher than the refractive index of the first refractive layer 27 may contact the surface of the first refractive layer 27 in the horizontal direction of FIG. 47.

In this case, the shapes of the interlayer insulating films 22 to 26 of FIG. 47 are different from the shapes of the interlayer insulating films 22 to 26 of FIG. 45. This is because a part of the interlayer insulating films is removed when a removing process for removing the metal diffusion prevention films is executed. The removing process will be described in detail below with reference to FIG. 48.

In FIG. 47, both the material having the refractive index equal to the refractive index of the first refractive layer 27 and the material having the refractive index higher than the refractive index of the first refractive layer 27 do not contact the surface of the first refractive layer 27 in the horizontal direction of FIG. 47.

For this reason, components of the light leaked from the waveguide 11 can be decreased, as compared with the case in which the metal diffusion prevention film is connected to the surface of the first refractive layer 27 in the horizontal direction of FIG. 47.

In FIG. 47, the image sensor 1 that is obtained by removing the metal diffusion prevention films 22b1 to 25b1 between the waveguide 11 and the light shielding film 1111 and the metal diffusion prevention films 22b2 to 25b2 between the waveguide 11 and the light shielding wall 1112 in the image sensor 1 according to the second embodiment illustrated in FIG. 45 has been described. However, the metal diffusion prevention film may be removed in the image sensor 1 according to the first embodiment illustrated in FIG. 42.

### [Removal of Metal Diffusion Prevention Film]

Next, FIG. 48 illustrates an example of a removing process for removing the metal diffusion prevention film, when the image sensor 1 of FIG. 47 is manufactured.

That is, when the image sensor 1 of FIG. 47 is manufactured, the removing process for removing the metal diffusion prevention film may be added between the process for forming the metal diffusion prevention film illustrated in FIG. 46A and the process for forming the resist pattern illustrated in FIG. 46b, in the manufacturing process described in FIGS. 46A, 46B, 46C, 46D, 46E, and 46F.

The removing process includes a protection film formation process, a resist pattern formation process, a dry etching process, an insulating film formation process, and a CMP process, as illustrated in FIG. 48.

That is, in the protection film formation process of FIG. 48, a protection film 131 to protect the metal diffusion prevention film 22b is formed in the metal diffusion prevention film 22b formed on the interlayer insulating film 22, using the deposition method such as the CVD method.

In the resist pattern formation process of FIG. 48, a resist pattern 132 used to remove the metal diffusion prevention film 22b is formed on the protection film 131, using the photolithography technique to form a pattern.

Next, in the dry etching process of FIG. 48, a part of the protection film 131 and a part of the metal diffusion prevention film 22b are removed with a pattern shown by the resist pattern 132, using the dry etching technique.

Thereby, the protection film 131 becomes protection films 1311 and 1322 from which the part of the protection film 131 has been removed and the metal diffusion prevention film 22b becomes metal diffusion prevention films 22b1 and 22b2 from which the part of the metal diffusion prevention film 22b has been removed.

Then, the ashing to remove the resist pattern 132 is performed and the interlayer insulating film 22 after the ashing is cleaned. Because the metal diffusion prevention films 22b1 and 22b2 are protected by the protection films 1311 and 1312, the metal diffusion prevention films 22b1 and 22b2 can be prevented from being partially removed, when the ashing is performed.

In the insulating film formation process of FIG. 48, the interlayer insulating film 23 is formed on the interlayer insulating film 22 and the protection films 1311 and 1312, using the deposition method such as the CVD method.

In the CMP process of FIG. 48, the surface (upper surface of FIG. 48) of the interlayer insulating film 23 is polished by the CMP and is flattened. Then, the removing process ends and the resist pattern formation process illustrated in FIG. 46B is executed.

In the manufacturing process described in FIGS. 43A, 43B, 43C, 43D, 43E, and 43F, when the removing process for removing the metal diffusion prevention film is added, the removing process is added between the metal diffusion prevention film formation process illustrated in FIG. 43A and the resist pattern formation process illustrated in FIG. 43B.

When the metal diffusion prevention film is removed using the removing process descried in FIG. 48, the protection films 1311 and 1312 are formed on the metal diffusion prevention films 22b1 and 22b2. However, in the image sensor 1 of FIG. 47, the metal diffusion prevention films 22b1 and 22b2 and the protection films 1311 and 1312 are simply illustrated as the metal diffusion prevention films 22b1 and 22b2.

### Modification

In the first to third embodiments, the wiring metal is used for the wiring line. However, the material used for the wiring line is not limited to the metal and any conductive material may be used. That is, a carbon nanotube may be adopted as the material used for the wiring line.

### 6. Reference Example

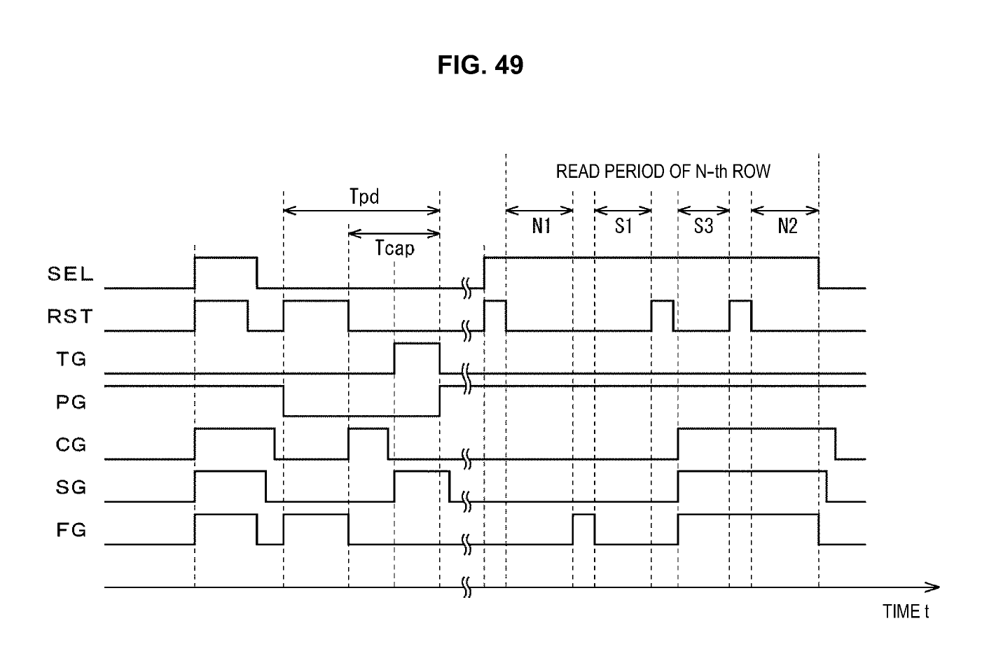

In the embodiments described above, the two charge storage units 66 and 67 are provided in the unit pixel and the second charge storage unit 67 is configured using the capacitor having the larger capacity value per unit area than the first charge storage unit 66. However, even though the two charge storage units 66 and 67 have the same capacity value per unit area, an effect of extending the dynamic range can be obtained. This will be described below with reference to FIG. 49.

In the exposure period of the photodiode 61, in the period set with the predetermined ratio with respect to the exposure period of the photodiode 61, the second transmission gate unit 63 enters a conducive state, so that the photocharges of the predetermined amount or more overflown from the photodiode 61 are discharged.

In this case, an exposure period in the photodiode 61 is defined as Tpd and a storage period of the photocharges overflown from the photodiode 61 in the second charge storage unit 67 is defined as Tcap. The unit pixel is operated according to a timing chart illustrated in FIG. 49 and the exposure period Tcap in the second charge storage unit 67 is limited. By this operation, information of the high illuminance side can be compressed, the capacity value of the second charge storage unit 67 can be almost equalized to the capacity value of the first charge storage unit 66, and at least a dynamic range can be extended.

After noise components at low illuminance and signal components are read, the FD unit 71 is reset and the photocharges that are stored in the second charge storage unit 67 and are overflown from the photodiode 61 are read as signals at high illuminance. Different from the other embodiments, the photocharges that are stored by the first charge storage unit 66 are not included in the signals at high illuminance to reset the FD unit 71.

A voltage signal based on the photocharges transmitted to the FD unit 71 when the signal is read is defined as S1, a voltage signal based on the reset level before the photocharges are transmitted to the FD unit 71 is defined as N1, and a first difference is defined as SN1. A voltage signal based on the photocharges that are stored in the FD unit 71, the first charge storage unit 66, and the second charge storage unit 67 when the FD unit 71 is reset immediately before reading is defined as S3. A voltage signal of a reset level of the FD unit 71, the first charge storage unit 66, and the second charge storage unit 67 or a level corresponding to the reset level is defined as N2, a third difference is defined as SN3, gain is defined as G, and an operation value of the third difference SN3 is defined as SN3′. In this case, the following operations are enabled.

$$SN 1 = S 1 - N 1$$

$$SN 3 = S 3 - N 2$$

$$\begin{matrix}G = SN 1 / SN 3 \\ = ( Cfd + Csg + Ccap ) / Cfd\end{matrix}$$

$$SN {3}^{′} = G \times SN 3 \times Tpd / Tcap$$

When the predetermined threshold value that is set in advance in a state in which the first difference SN1 is not yet saturated in a photoresponsive characteristic and the photoresponsive characteristic is in a linear area is defined as Vt and the pixel signal of the processing object pixel is defined as SN, the pixel signal SN is output as follows.

In the case of SN1<Vt, SN=SN1 (SN1 is substituted for SN)

In the case of Vt≦SN1, SN=SN3′ (SN3′ is substituted for SN)

### 7. Modification

### 7-1. Example of Storing Photocharge by Only Photodiode 61

In the embodiments and the modifications described above, the photocharges overflown from the photodiode 61 at high illuminance are stored in the first storage charge unit 66 through the overflow path of the first transmission gate unit 62 and are stored in the second charge storage unit 67 through the overflow path of the third transmission gate unit 64. That is, in this embodiment, the photocharges overflown from the photodiode 61 at high illuminance are stored in both the photodiode 61 and the first and second charge storage units 66 and 67.

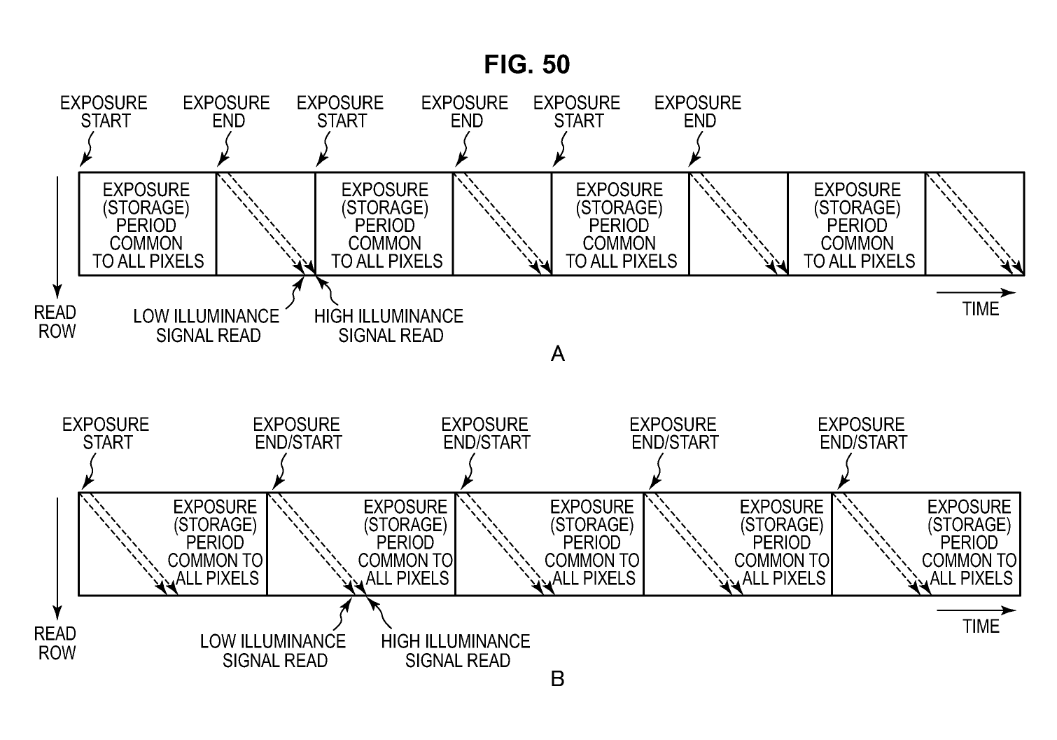

However, in the pixel structure described above, exposure may not be performed during a read period of the photocharges, as be clear from FIG. 50A illustrating an operation. Therefore, a pixel structure in which the photocharges are stored by only the photodiode 61 is suggested as a modification.

Even in this case, the photocharges read from the photodiode 61 are stored by selectively using the first charge storage unit 66 and the second charge storage unit 67, according to the present disclosure. That is, after the photocharges are read from the photodiode 61, the photocharges overflown from the first charge storage unit 66 are stored in the second charge storage unit 67. For this reason, it is necessary to form the overflow path between the first charge storage unit 66 and the second charge storage unit 67.

As such, the pixel structure in which the photocharges are stored by only the photodiode 61 is adopted. As a result, as illustrated in FIG. 50B illustrating an operation, because exposure can be performed during a read period of the photocharges, a seamless operation can be realized continuously during the exposure period when a moving image is imaged. However, because the photocharges are stored by only the photodiode 61, a dynamic range is limited by a saturation charge amount of the photodiode 61. For this reason, the dynamic range may not be greatly extended.

However, the photocharges are stored by selectively using the first charge storage unit 66 and the second charge storage unit 67 according to the present disclosure, so that a total area of the charge storage units to store the photocharges can be decreased. Therefore, because the area of the photodiode 61 can be increased by an amount corresponding to a decrease in the total area, the dynamic range can be indirectly extended.

### 7-2. Modification of Unit Pixel to which Structure of Second Charge Storage Unit is Applied

The structure of the second charge storage unit 67 that has been described with reference to FIGS. 29 to 33 is not limited to the unit pixel described above and can be applied to a unit pixel including a capacitor to store the charges generated by the photodiode 61.

For example, the structure of the second charge storage unit 67 can be applied to a unit pixel in which the first charge storage unit 66 is omitted.

For example, the structure of the second charge storage unit 67 can be applied to a unit pixel of a back-surface-type solid-state image sensor such as a back-surface-type contact image sensor (CIS) as well as the surface-type solid-state image sensor.

For example, the structure of the second charge storage unit 67 can be applied to a unit pixel of a solid-state image sensor having adopted a rolling shutter function as well as the solid-state image sensor having adopted the global shutter function.

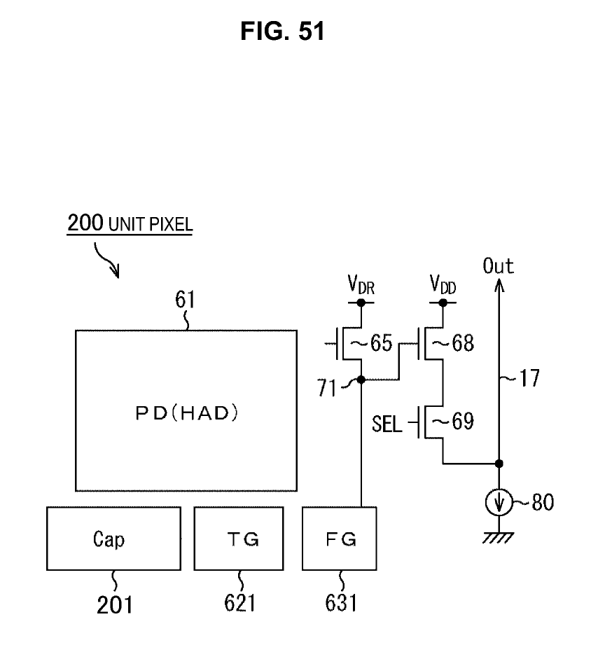

FIG. 51 is a schematic diagram illustrating a pixel structure in the case in which a charge storage unit (Cap) 201 having the same structure as the second charge storage unit 67 is included in a unit pixel 200 of a solid-state image sensor having adopted a rolling shutter function. In FIG. 51, structural elements that correspond to those in FIG. 9 are denoted with the same reference numerals.

In the unit pixel 200, the photocharges overflown from the photodiode 61 during the exposure period are transmitted to the charge storage unit 201 and are stored. The photocharges that are stored in the photodiode 61 and the charge storage unit 201 are transmitted to the FD unit 71 through a gate electrode 621 and a gate electrode 631 and a voltage of the FD unit 71 is output as a signal level to the vertical signal line 17. Thereby, a dynamic range of an image can be extended.

### 7-3. Other Modifications

In the embodiments described above, the case in which the present disclosure is applied to the CMOS image sensor in which the unit pixels are arranged in a matrix has been described. However, the present disclosure is not limited to application with respect to the CMOS image sensor. That is, the present disclosure can be applied to all solid-state imaging devices of an X-Y address system obtained by arranging unit pixels in a matrix.

The present disclosure is not limited to application with respect to a solid-state imaging device that detects a distribution of an amount of incident light of visible light and images the distribution as an image and can be applied to all solid-state imaging devices that image a distribution of an incident amount of infrared rays, X-rays, or particles as an image.

The solid-state imaging device may be formed as a single chip and may be formed as a module having an imaging function in which an imaging unit, a signal processing unit, and an optical system are collected and packaged.

All pixels in the present disclosure mean all of pixels of portions appearing in an image, except for dummy pixels. In the present disclosure, if a time difference or image distortion is small enough not to cause a problem, high-speed scanning is enabled for every rows (dozens of rows), instead of a simultaneous operation with respect to all pixels. In the present disclosure, the global shutter operation is not limited to all pixels appearing in an image and the global shutter operation may be applied to a plurality of rows determined in advance.

The conductive type of the device structure in the unit pixel described above is only exemplary and a relation of the N type and the P type may be reversed. A magnitude relation of the potentials of the individual units may be reversed depending on whether a large number of carriers moving in unit pixels are holes or electrons.

### 8. Electronic Apparatus

The present disclosure is not limited to application with respect to the solid-state imaging device and can be applied to all electronic apparatuses using the solid-state imaging device in an image capture unit (photoelectric converting unit), such as an imaging apparatus such as a digital still camera or a video camera, a mobile terminal apparatus having an imaging function such as a mobile phone, and a copying machine using the solid-state imaging device in an image reading unit. The module that is mounted to the electronic apparatus, that is, a camera module may be used as an imaging apparatus.

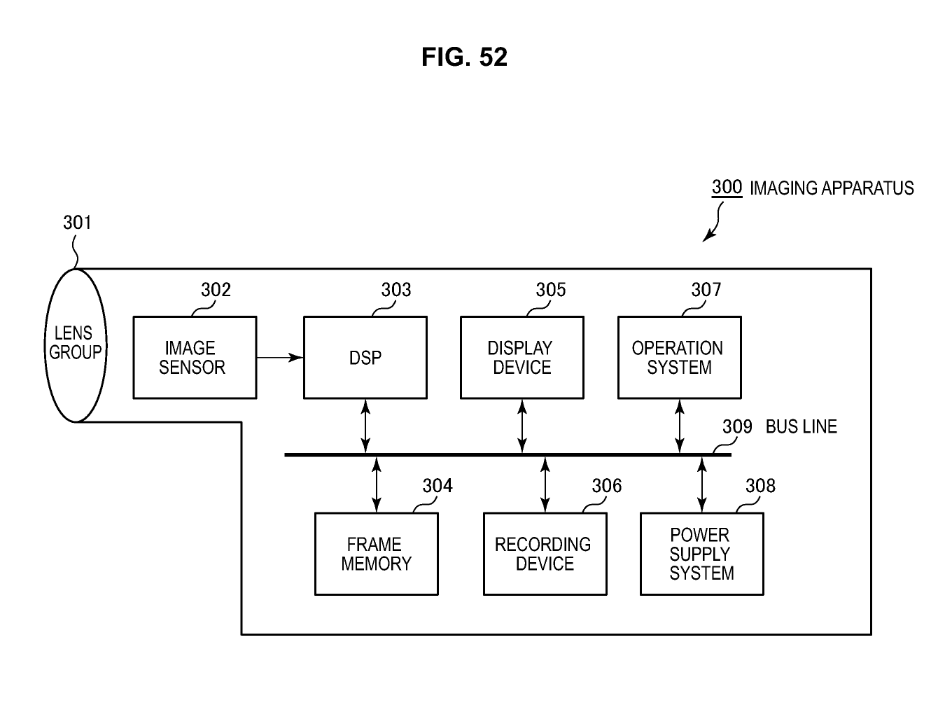

FIG. 52 is a block diagram illustrating an example of a structure of an electronic apparatus according to the present disclosure, for example, an imaging apparatus.

As illustrated in FIG. 52, an imaging apparatus 300 according to the present disclosure has an optical system including a lens group 301, an image sensor (imaging device) 302, a DSP circuit 303, a frame memory 304, a display device 305, a recording device 306, an operation system 307, and a power supply system 308. The DSP circuit 303, the frame memory 304, the display device 305, the recording device 306, the operation system 307, and the power supply system 308 are mutually connected through a bus line 309.

The lens group 301 takes incident light (image light) from an object and forms an image on an imaging surface of the image sensor 302. The image sensor 302 converts an amount of the incident light forming an image on the imaging surface by the lens group 301 into an electric signal in a pixel unit and outputs the electric signal as a pixel signal.

The display device 305 is configured using a panel-type display device such as a liquid crystal display device or an organic electroluminescence (EL) display device and displays a moving image or a still image imaged by the image sensor 302. The recording device 306 records the moving image or the still image imaged by the image sensor 302 on a recording medium such as a video tape or a digital versatile disk (DVD).

The operation system 307 outputs an operation command with respect to various functions of the imaging apparatus, according to an operation from a user. The power supply system 308 appropriately supplies various powers becoming operation powers of the DSP circuit 303, the frame memory 304, the display device 305, the recording device 306, and the operation system 307 to power supply objects.

The imaging apparatus that has the structure described above can be used as an imaging apparatus such as a video camera, a digital still camera, and a camera module for a mobile apparatus such as a mobile phone. In the imaging apparatus, the solid-state imaging device such as the CMOS image sensor 10 according to the embodiments described above is used as the image sensor 302 and the following functions and effects can be obtained.

That is, the CMOS image sensor 10 according to the embodiments described above can realize imaging of an image having no distortion by the global exposure. Therefore, the CMOS image sensor 10 can be used for imaging of an object moving at a high speed in which image distortion may not be allowed or sensing in which synchronism of an imaging image is necessary and can be realized as a preferred imaging device.

As compared with the related art in which the global exposure is realized, the CMOS image sensor 10 according to the embodiments described above can secure more saturation charge amount, that is, increase a capacity value of a capacitor to store photocharges, without deteriorating quality of an imaging image at dark or low illuminance. If more saturation charge amount can be secured, the unit pixel size can be decreased by an increase in the saturation charge amount. As a result, the number of pixels can be increased. Therefore, image quality of an imaging image can be improved.

The present disclosure is not limited to the above description. The pixel structure, for example, the overflow path or the conductive layer of the surface layer of the embedded MOS capacitor is not limited. The circuit diagrams and the timing charts may be various changed.

It should be understood by those skilled in the art that various modifications, combinations, sub-combinations and alterations may occur depending on design requirements and other factors insofar as they are in the scope of the appended claims or the equivalents thereof.

The present disclosure contains subject matter related to that disclosed in Japanese Priority Patent Application JP 2012-031518 filed in the Japan Patent Office on Feb. 16, 2012, Japanese Priority Patent Application JP 2012-070767 filed in the Japan Patent Office on Mar. 27, 2012, and Japanese Priority Patent Application JP 2012-127668 filed in the Japan Patent Office on Jun. 5, 2012, the entire contents of which are hereby incorporated by reference.

What is claimed is:

1. A solid-state imaging device comprising:
a pixel array unit in which a plurality of unit pixels each having a photoelectric converting unit to generate and store photocharges according to an amount of received light and a charge storage unit to store the photocharges are arranged on a semiconductor substrate,
wherein the charge storage unit is formed on a path along which light is incident on the photoelectric converting unit.

2. The solid-state imaging device according to claim 1,
wherein at least a part of a first electrode of the charge storage unit is formed along at least a part of a sidewall of a waveguide to guide light to the photoelectric converting unit.

3. The solid-state imaging device according to claim 2,
wherein at least a part of a second electrode facing the first electrode and at least a part of a capacity film provided between the first electrode and the second electrode are formed along at least the part of the sidewall of the waveguide.

4. The solid-state imaging device according to claim 3,
wherein each of the first and second electrodes is formed of a transparent electrode material.

5. The solid-state imaging device according to claim 4,
wherein the waveguide is embedded by the first electrode, the second electrode, and the capacity film.

6. The solid-state imaging device according to claim 2,
wherein a second electrode facing the first electrode is formed to surround at least a part of a peripheral portion of a light reception surface of the photoelectric converting unit and at least the part of the sidewall of the waveguide, and an interlayer film between the first electrode and the second electrode is formed as a capacity film of the charge storage unit.

7. The solid-state imaging device according to claim 6,
wherein the first electrode is formed of a transparent electrode material.

8. The solid-state imaging device according to claim 1,
wherein the charge storage unit stores charges overflown from the photoelectric converting unit during an exposure period.

9. The solid-state imaging device according to claim 8,
wherein each of the unit pixels further includes a charge storage unit composed of an embedded MOS capacitor, and
collective exposure of the plurality of unit pixels is enabled and the charges stored in the photoelectric converting unit during the exposure period are stored in the two charge storage units after the exposure period.

10. An electronic apparatus comprising:
a solid-state imaging device that includes a pixel array unit in which a plurality of unit pixels each having a photoelectric converting unit to generate and store photocharges according to an amount of received light and a charge storage unit to store the photocharges are arranged on a semiconductor substrate, the charge storage unit being formed on a path along which light is incident on the photoelectric converting unit; and
a signal processing unit that executes signal processing with respect to a signal output from each of the unit pixels.

11. The electronic apparatus according to claim 10,
wherein at least a part of a first electrode of the charge storage unit is formed along at least a part of a sidewall of a waveguide to guide light to the photoelectric converting unit.

12. An image sensor comprising:
a semiconductor substrate that is provided with a light receiving unit to generate charges according to received light;
a light shielding film that is formed on a side on which light is radiated with respect to the semiconductor substrate;
a wiring layer that is formed on a side on which light is radiated with respect to the light shielding film; and
an opening portion that is formed in the light shielding film and the wiring layer to provide an optical waveguide to transmit light to the light receiving unit,
wherein the opening portion is formed in a manner that an opening formed in the light shielding film to be larger in a radial direction by a predetermined interval than an opening right above the light shielding film.

13. The image sensor according to claim 12,
wherein the opening portion is formed by executing processing for forming an opening in the wiring layer by self-alignment using the light shielding film as a stopper film and additionally executing processing for forming an opening in the light shielding film.

14. The image sensor according to claim 12,
wherein the opening portion is formed by executing processing for forming openings in the wiring layer and the light shielding film and additionally executing processing for expanding the opening of the light shielding film.

15. The image sensor according to claim 12,
wherein the optical waveguide is formed by forming a passivation film on a side of an opening formed in the wiring layer, and embedding a core material having a refractive index lower than a refractive index of the passivation film in the opening portion in which the passivation film is formed.

16. The image sensor according to claim 15,
wherein a dielectric medium having a refractive index lower than the refractive index of the core material is provided in a region that is obtained by forming the opening formed in the light shielding film to be larger in a radial direction by a predetermined interval than the opening right above the light shielding film.

17. The image sensor according to claim 15,
wherein a hollow layer is provided in a region that is obtained by forming the opening formed in the light shielding film to be larger in a radial direction by a predetermined interval than the opening right above the light shielding film.

18. A method of manufacturing an image sensor, comprising:
forming a light shielding film on a side on which light is radiated with respect to a semiconductor substrate provided with a light receiving unit to generate charges according to received light;
forming a wiring layer on side on which light is radiated with respect to the light shielding film; and
forming an opening portion in the light shielding film and the wiring layer to provide an optical waveguide to transmit light to the light receiving unit,
wherein the opening portion is formed in a manner that an opening formed in the light shielding film is to be larger in a radial direction by a predetermined interval than an opening right above the light shielding film.

19. An electronic apparatus comprising:
an image sensor,
the image sensor includes
a semiconductor substrate that is provided with a light receiving unit to generate charges according to received light,
a light shielding film that is formed on a side on which light is radiated with respect to the semiconductor substrate,
a wiring layer that is formed on a side on which light is radiated with respect to the light shielding film, and
an opening portion that is formed in the light shielding film and the wiring layer to provide an optical waveguide to transmit light to the light receiving unit,
wherein the opening portion is formed in a manner that an opening formed in the light shielding film to be larger in a radial direction by a predetermined interval than an opening right above the light shielding film.

20. An image sensor comprising:
a light receiving element that performs photoelectric conversion to convert incident light into pixel data;
a waveguide that guides light from a condensing unit to the light receiving element; and
a light shielding wall that shields at least light leaked from the waveguide.

21. The image sensor according to claim 20,
wherein the waveguide is not in contact with a material having a refractive index equal to a refractive index of a material for forming the waveguide and a material having a refractive index higher than the refractive index of the material for forming the waveguide.

22. The image sensor according to claim 21, further comprising:
a plurality of layers,
wherein the light shielding wall is formed to penetrate at least two or more layers among the plurality of layers.

23. The image sensor according to claim 22,
wherein the light shielding wall is formed to penetrate the two or more layers including layers closer to the light receiving element than the waveguide.

24. The image sensor according to claim 23,
wherein the light shielding wall is formed of a metal.

25. The image sensor according to claim 24,
wherein the waveguide is formed of a material having a refractive index higher than a refractive index of the layers.

26. The image sensor according to claim 25,
wherein the light shielding wall is used exclusively for light shielding.

27. The image sensor according to claim 26,
wherein the light shielding wall is connected to a ground.

28. The image sensor according to claim 27,
wherein the light shielding wall forms a condensing tube that surrounds the waveguide.

29. The image sensor according to claim 28, further comprising:
a circuit unit that is arranged outside the condensing tube where the waveguide does not exist,
wherein the light receiving element is arranged inside the condensing tube where the waveguide exists.

30. The image sensor according to claim 29, further comprising:
a plurality of pixel units that are arranged in a matrix,
wherein each of the pixel units includes
the waveguide,
the condensing tube,
the light receiving element, and
the circuit unit.

31. The image sensor according to claim 30,
wherein a lowermost portion of the light shielding wall is provided to be closer to the waveguide than a boundary of a separation region provided between the light receiving elements of the plurality of pixel units and the light receiving element.

32. A method of manufacturing an image sensor which includes a light receiving element that performs photoelectric conversion to convert incident light into pixel data, a waveguide that guides light from a condensing unit to the light receiving element, and a light shielding wall that shields at least light leaked from the waveguide, the method comprising:
embedding a light shielding material in a groove penetrating a second layer overlapped and formed on a first layer in which the light shielding material is embedded and reaching the light shielding material embedded in the first layer, thereby forming the light shielding wall; and
forming the waveguide in a plurality of layers in which the light shielding wall is formed.

33. The method according to claim 32, further comprising:
removing a material having a refractive index equal to a refractive index of a material for forming the waveguide and a material having a refractive index higher than the refractive index of the material for forming the waveguide, among materials contacting the waveguide when the waveguide is formed.

34. The method according to claim 32,
wherein, in the light shielding wall forming step, in parallel to embedding of the light shielding material with respect to the groove, a wiring line of a circuit unit to control the light receiving element is formed by embedding a conductive material in a hole penetrating a fourth layer overlapped and formed on a third layer in which the conductive material is embedded and reaching the conductive material embedded in the third layer.

35. An electronic apparatus in which an image sensor is embedded,
wherein the image sensor includes
a light receiving element that performs photoelectric conversion to convert incident light into pixel data,
a waveguide that guides light from a condensing unit to the light receiving element, and
a light shielding wall that shields at least light leaked from the waveguide.
